(19) United States
(12) Patent Application Publication
(10) Pub. No.: US 2022/0344508 A1
(43) Pub. Date: Oct. 27, 2022

(54) SEMICONDUCTOR DEVICE AND METHOD

(71) Applicant: Taiwan Semiconductor Manufacturing Co., Ltd., Hsinchu (TW)

(72) Inventors: Chih-Sheng Huang, New Taipei (TW); Chih-Chiang Chang, Zhubei (TW); Ming-Hua Yu, Hsinchu (TW); Yee-Chia Yeo, Hsinchu (TW)

(21) Appl. No.: 17/582,563

(22) Filed: Jan. 24, 2022

Related U.S. Application Data
(60) Provisional application No. 63/178,091, filed on Apr. 22, 2021.
(60) Provisional application No. 63/180,864, filed on Apr. 28, 2021.

(51) Int. Cl. H01L 29/78; H01L 29/45; H01L 29/66; H01L 29/40

(52) U.S. Cl. CPC H01L 29/7851; H01L 29/456; H01L 29/66795; H01L 29/401

(57) ABSTRACT

A method includes forming a first semiconductor fin on a substrate, forming a source/drain region in the first semiconductor fin, depositing a capping layer on the source/drain region, where the capping layer includes a first boron concentration higher than a second boron concentration of the source/drain region, etching an opening through the capping layer, the opening exposing the source/drain region, forming a silicide layer on the exposed source/drain region and forming a source/drain contact on the silicide layer.

### PRIORITY CLAIM AND CROSS-REFERENCE

This patent application claims priority to U.S. Provisional Application No. 63/178,091, filed on Apr. 22, 2021 and entitled “Boron-Rich Capping (BRC) Applied on FinFET structure to retard MD OD Dry-Etching,” which application is hereby incorporated by reference herein as if reproduced in its entirety. This patent application also claims priority to U.S. Provisional Application No. 63/180,864, filed on Apr. 28, 2021 and entitled “Boron-Rich Capping (BRC) Applied on Nano-Sheet Structure to Retard MD OD Dry-Etching,” which application is hereby incorporated by reference herein as if reproduced in its entirety.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a FinFET in a three-dimensional view, in accordance with some embodiments.

FIGS. 2, 3, 4, 5, 6, 7, 8A, 8B, 9A, 9B, 10A, 10B, 10C, 10D, 11A, 11B, 11C, 11D, 11E, 11F, 12A, 12B, 12C, 12D, 13A, 13B, 14A, 14B, 15A, 15B, 16A, 16B, 17A, 17B, 18A, 18B, 19A, 19B, 20A, 20B, 20C, 21A, 21B, 22A, 22B, 23A, 23B, 24A, 24B, 24C, and 24D are cross-sectional views of intermediate stages in the manufacturing of FinFETs, in accordance with some embodiments.

FIG. 25 illustrates an example of a nanostructure field-effect transistor (nano-FET) in a three-dimensional view, in accordance with some embodiments.

FIGS. 26, 27, 28, 29A-C, 30A-C, 31A-C, 32A-C, 33A-C, 34A-C, 35A-C, 36A-C, 37A-C, 38A-C, 39A-C, 40A-D, 41A-C, 42A-C, 43A-C, 44A-C, 45A-C, 46A-C, and 47A-D are views of intermediate stages in the manufacturing of nano-FETs, in accordance with some embodiments.

### DETAILED DESCRIPTION

The following disclosure provides many different embodiments or examples, for implementing different features. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments include methods applied to, but not limited to the formation of a boron-rich capping layer over top surfaces and sidewalls of an epitaxial source/drain region. The boron-rich capping layer acts as a sacrificial layer and retards epitaxial source/drain region loss during a fluorine based etching process used to form source/drain contact openings in an inter-layer dielectric (ILD) over the source/drain region. Advantageous features of one or more embodiments disclosed herein may include the boron-rich capping layer acting as a dopant donor to slightly dope a channel region which results in lower channel resistance and improved electrical performance. In addition, the use of the boron-rich capping layer results in decreased epitaxial source/drain region loss during the fluorine based etching process allowing the source/drain region to retain a larger volume of high percentage germanium epitaxial material. This may result in a lower resistance between the source/drain region and subsequently formed source/drain contacts that physically contact this high percentage germanium epitaxial material. Further, the decreased epitaxial source/drain region loss during the fluorine based etching process results in the source/drain region having a higher raised height, which may also reduce defects and improve processing windows.

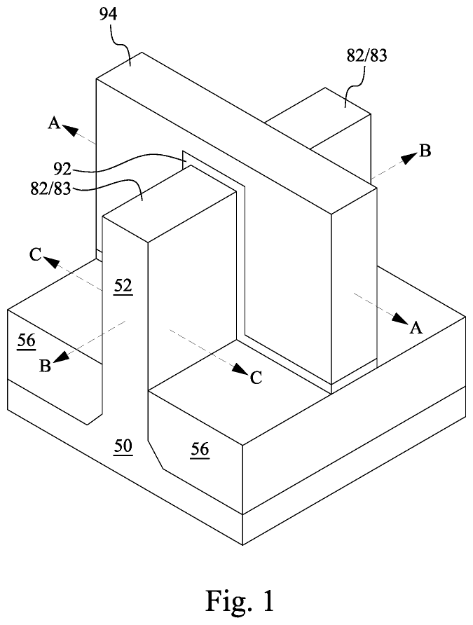

FIG. 1 illustrates an example of a FinFET in a three-dimensional view, in accordance with some embodiments. The FinFET comprises a fin 52 on a substrate 50 (e.g., a semiconductor substrate). Isolation regions 56 are disposed in the substrate 50, and the fin 52 protrudes above and from between neighboring isolation regions 56. Although the isolation regions 56 are described/illustrated as being separate from the substrate 50, as used herein the term “substrate” may be used to refer to just the semiconductor substrate or a semiconductor substrate inclusive of isolation regions. Additionally, although the fin 52 is illustrated as a single, continuous material as the substrate 50, the fin 52 and/or the substrate 50 may comprise a single material or a plurality of materials. In this context, the fin 52 refers to the portion extending between the neighboring isolation regions 56.

A gate dielectric layer 92 is along sidewalls and over a top surface of the fin 52, and a gate electrode 94 is over the gate dielectric layer 92. Source/drain regions 82/83 are disposed in opposite sides of the fin 52 with respect to the gate dielectric layer 92 and gate electrode 94. FIG. 1 further illustrates reference cross-sections that are used in later figures. Cross-section A-A is along a longitudinal axis of the gate electrode 94 and in a direction, for example, perpendicular to the direction of current flow between the source/drain regions 82/83 of the FinFET. Cross-section B-B is perpendicular to cross-section A-A and is along a longitudinal axis of the fin 52 and in a direction of, for example, a current flow between the source/drain regions 82/83 of the FinFET. Cross-section C-C is parallel to cross-section A-A and extends through a source/drain region of the FinFET. Subsequent figures refer to these reference cross-sections for clarity.

Some embodiments discussed herein are discussed in the context of FinFETs formed using a gate-last process. In other embodiments, a gate-first process may be used.

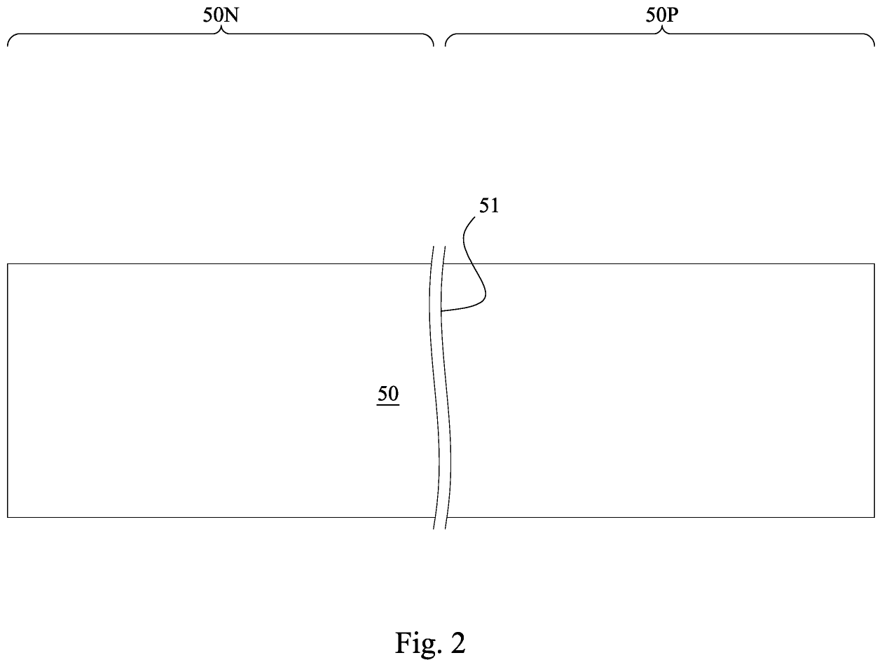

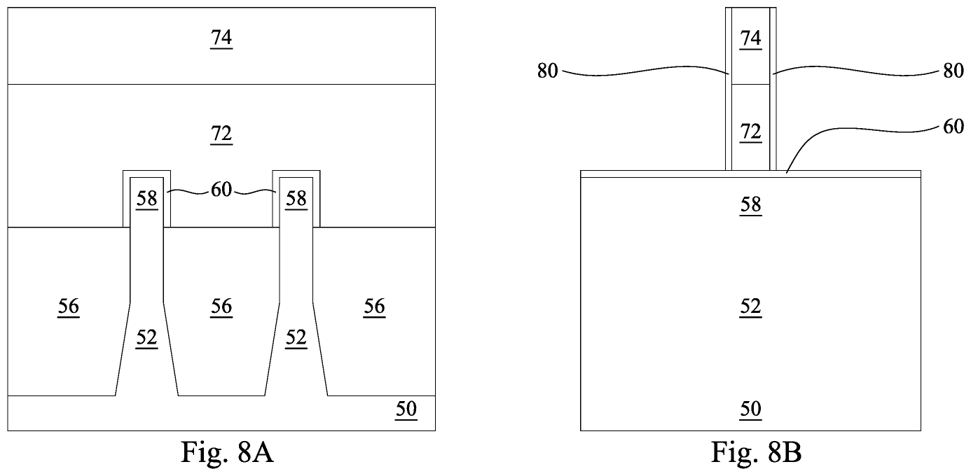

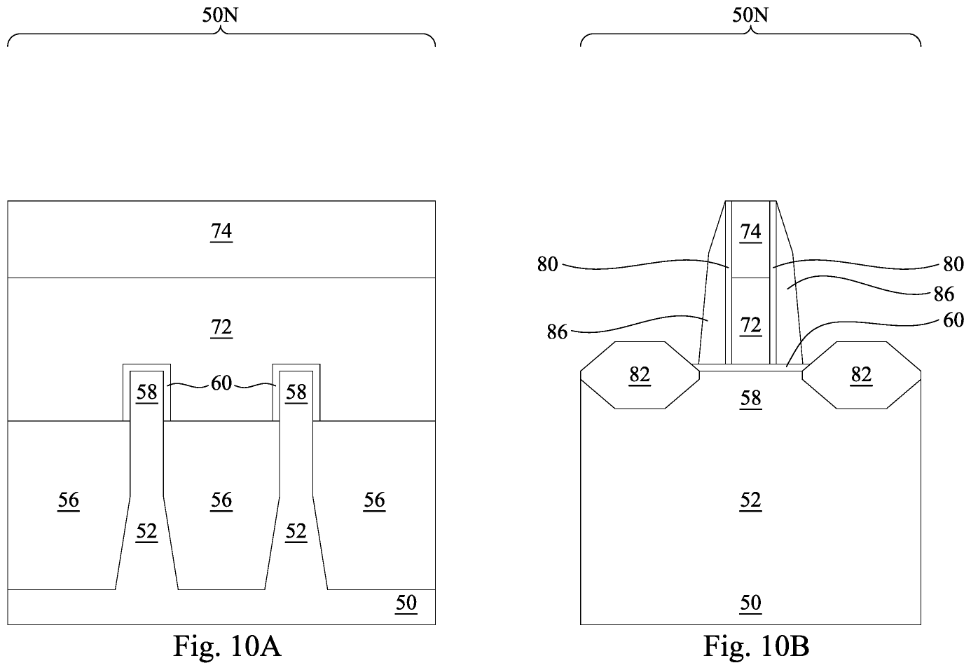

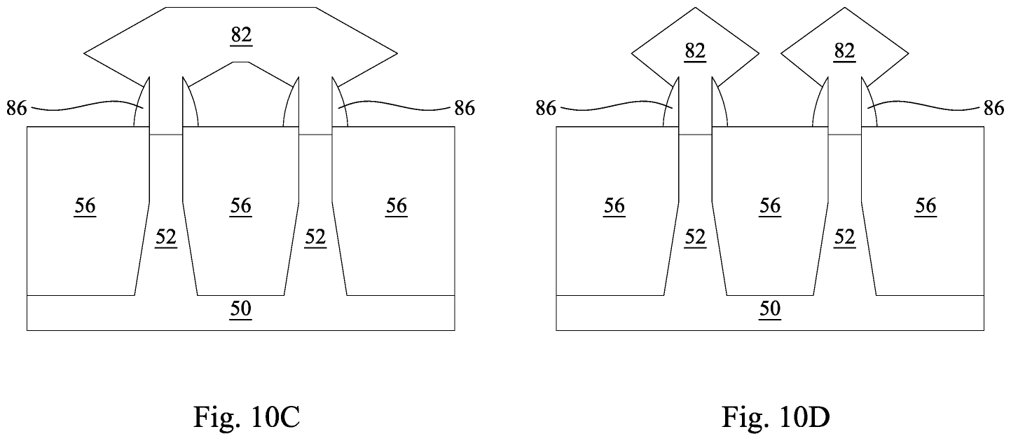

FIGS. 2 through 24D are cross-sectional views of intermediate stages in the manufacturing of FinFETs, in accordance with some embodiments. FIGS. 2 through 7 illustrate reference cross-section A-A illustrated in FIG. 1, except for multiple fins/FinFETs. FIGS. 8A, 9A, 10A, 11A, 12A, 13A, 14A, 15A, 16A, 17A, 18A, 19A, 20A, 21A, 22A, 23A, and 24A are illustrated along reference cross-section A-A illustrated in FIG. 1, and FIGS. 8B, 9B, 10B, 11B, 12B, 13B, 14B, 14C, 15B, 16B, 17B, 18B, 19B, 20B, 21B, 22B, 23B, and 24B are illustrated along a similar cross-section B-B illustrated in FIG. 1, except for multiple fins/FinFETs. FIGS. 10C, 10D, 11C, 11D, 11E, 11F, 12C, 12D, 24C, and 24D are illustrated along reference cross-section C-C illustrated in FIG. 1, except for multiple fins/FinFETs.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type FinFETs. The p-type region 50P can be for forming p-type devices, such as PMOS transistors, e.g., p-type FinFETs. The n-type region 50N may be physically separated from the p-type region 50P (as illustrated by divider 51), and any number of device features (e.g., other active devices, doped regions, isolation structures, etc.) may be disposed between the n-type region 50N and the p-type region 50P.

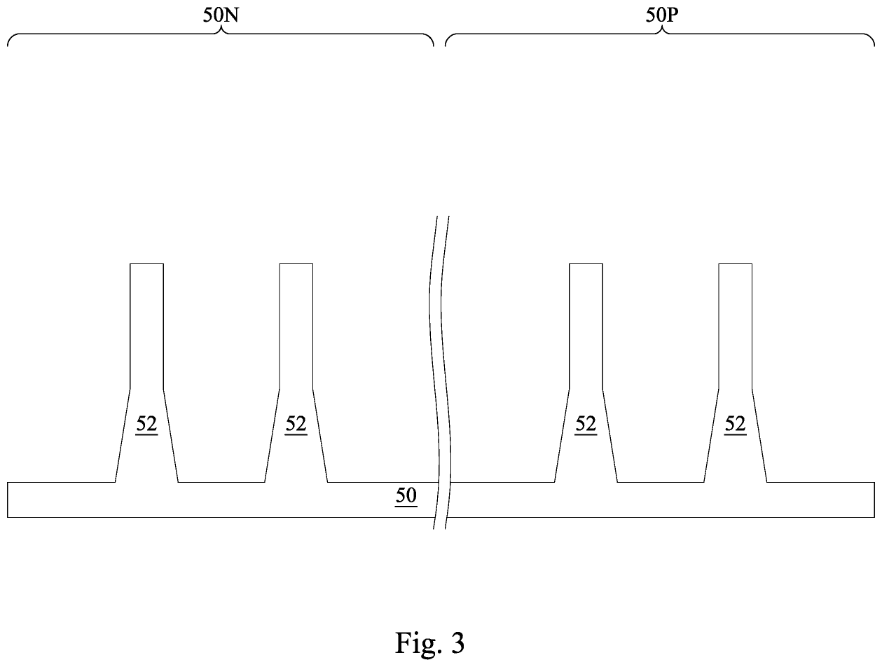

In FIG. 3, fins 52 are formed in the substrate 50. The fins 52 are semiconductor strips. In some embodiments, the fins 52 may be formed in the substrate 50 by etching trenches in the substrate 50. The etching may be any acceptable etch process, such as a reactive ion etch (RIE), neutral beam etch (NBE), the like, or a combination thereof. The etch may be anisotropic.

The fins may be patterned by any suitable method. For example, the fins 52 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. In some embodiments, the mask (or other layer) may remain on the fins 52.

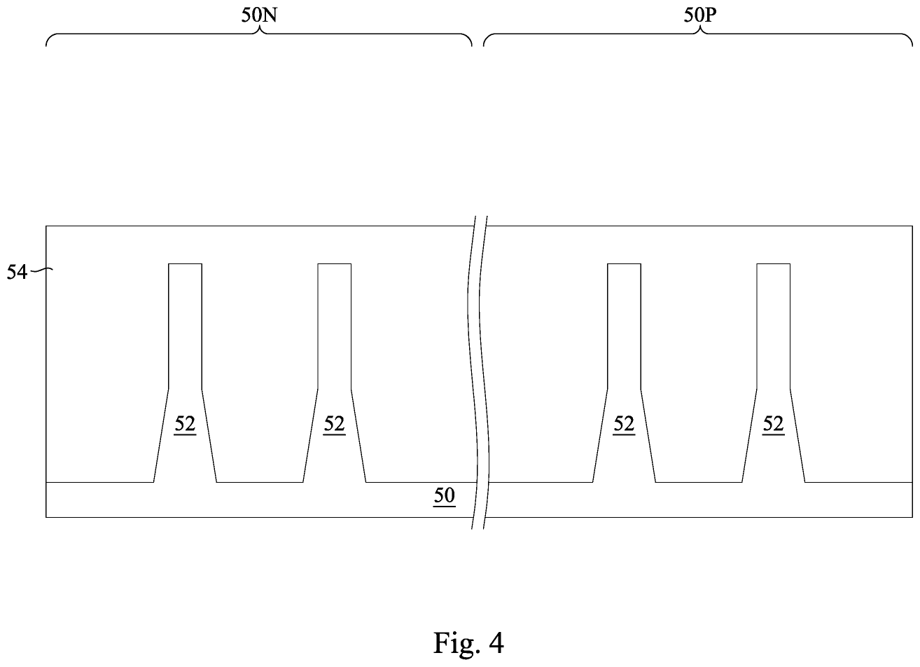

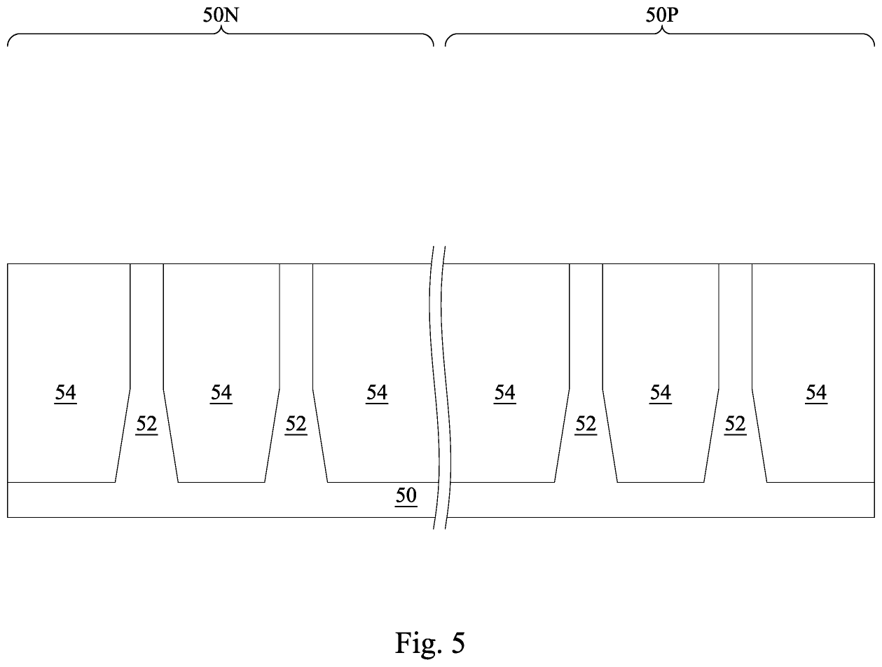

In FIG. 4, an insulation material 54 is formed over the substrate 50 and between neighboring fins 52. The insulation material 54 may be an oxide, such as silicon oxide, a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material 54 is silicon oxide formed by a FCVD process. An anneal process may be performed once the insulation material is formed. In an embodiment, the insulation material 54 is formed such that excess insulation material 54 covers the fins 52. Although the insulation material 54 is illustrated as a single layer, some embodiments may utilize multiple layers. For example, in some embodiments a liner (not shown) may first be formed along a surface of the substrate 50 and the fins 52. Thereafter, a fill material, such as those discussed above may be formed over the liner.

In FIG. 5, a removal process is applied to the insulation material 54 to remove excess insulation material 54 over the fins 52. In some embodiments, a planarization process such as a chemical mechanical polish (CMP), an etch-back process, combinations thereof, or the like may be utilized. The planarization process exposes the fins 52 such that top surfaces of the fins 52 and the insulation material 54 are level after the planarization process is complete. In embodiments in which a mask remains on the fins 52, the planarization process may expose the mask or remove the mask such that top surfaces of the mask or the fins 52, respectively, and the insulation material 54 are level after the planarization process is complete.

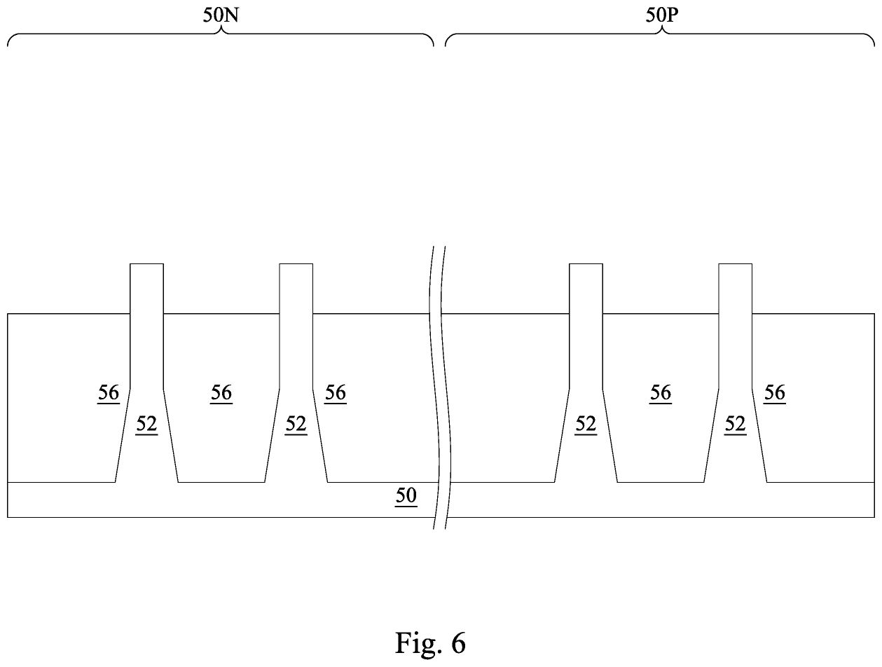

In FIG. 6, the insulation material 54 is recessed to form Shallow Trench Isolation (STI) regions 56. The insulation material 54 is recessed such that upper portions of fins 52 in the n-type region 50N and in the p-type region 50P protrude from between neighboring STI regions 56. Further, the top surfaces of the STI regions 56 may have a flat surface as illustrated, a convex surface, a concave surface (such as dishing), or a combination thereof. The top surfaces of the STI regions 56 may be formed flat, convex, and/or concave by an appropriate etch. The STI regions 56 may be recessed using an acceptable etching process, such as one that is selective to the material of the insulation material 54 (e.g., etches the material of the insulation material 54 at a faster rate than the material of the fins 52). For example, an oxide removal using, for example, dilute hydrofluoric (dHF) acid may be used.

The process described with respect to FIGS. 2 through 6 is just one example of how the fins 52 may be formed. In some embodiments, the fins may be formed by an epitaxial growth process. For example, a dielectric layer can be formed over a top surface of the substrate 50, and trenches can be etched through the dielectric layer to expose the underlying substrate 50. Homoepitaxial structures can be epitaxially grown in the trenches, and the dielectric layer can be recessed such that the homoepitaxial structures protrude from the dielectric layer to form fins. Additionally, in some embodiments, heteroepitaxial structures can be used for the fins 52. For example, the fins 52 in FIG. 5 can be recessed, and a material different from the fins 52 may be epitaxially grown over the recessed fins 52. In such embodiments, the fins 52 comprise the recessed material as well as the epitaxially grown material disposed over the recessed material. In an even further embodiment, a dielectric layer can be formed over a top surface of the substrate 50, and trenches can be etched through the dielectric layer. Heteroepitaxial structures can then be epitaxially grown in the trenches using a material different from the substrate 50, and the dielectric layer can be recessed such that the heteroepitaxial structures protrude from the dielectric layer to form the fins 52. In some embodiments where homoepitaxial or heteroepitaxial structures are epitaxially grown, the epitaxially grown materials may be in situ doped during growth, which may obviate prior and subsequent implantations although in situ and implantation doping may be used together.

Still further, it may be advantageous to epitaxially grow a material in n-type region 50N (e.g., an NMOS region) different from the material in p-type region 50P (e.g., a PMOS region). In various embodiments, upper portions of the fins 52 may be formed from silicon-germanium (SiₓGe₁₋ₓ, where x can be in the range of 0 to 1), silicon carbide, pure or substantially pure germanium, a III-V compound semiconductor, a II-VI compound semiconductor, or the like. For example, the available materials for forming III-V compound semiconductor include, but are not limited to, indium arsenide, aluminum arsenide, gallium arsenide, indium phosphide, gallium nitride, indium gallium arsenide, indium aluminum arsenide, gallium antimonide, aluminum antimonide, aluminum phosphide, gallium phosphide, and the like.

Further in FIG. 6, appropriate wells (not shown) may be formed in the fins 52 and/or the substrate 50. In some embodiments, a P well may be formed in the n-type region 50N, and an N well may be formed in the p-type region 50P. In some embodiments, a P well or an N well are formed in both the n-type region 50N and the p-type region 50P.

In the embodiments with different well types, the different implant steps for the n-type region 50N and the p-type region 50P may be achieved using a photoresist and/or other masks (not shown). For example, a photoresist may be formed over the fins 52 and the STI regions 56 in the n-type region 50N. The photoresist is patterned to expose the p-type region 50P of the substrate 50. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration of equal to or less than 10¹⁸ cm⁻³, such as between about 10¹⁶ cm⁻³ and about 10¹⁸ cm⁻³. After the implant, the photoresist is removed, such as by an acceptable ashing process.

Following the implanting of the p-type region 50P, a photoresist is formed over the fins 52 and the STI regions 56 in the p-type region 50P. The photoresist is patterned to expose the n-type region 50N of the substrate 50. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration of equal to or less than 10¹⁸ cm⁻³, such as between about 10¹⁶ cm⁻³ and about 10¹⁸ cm⁻³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

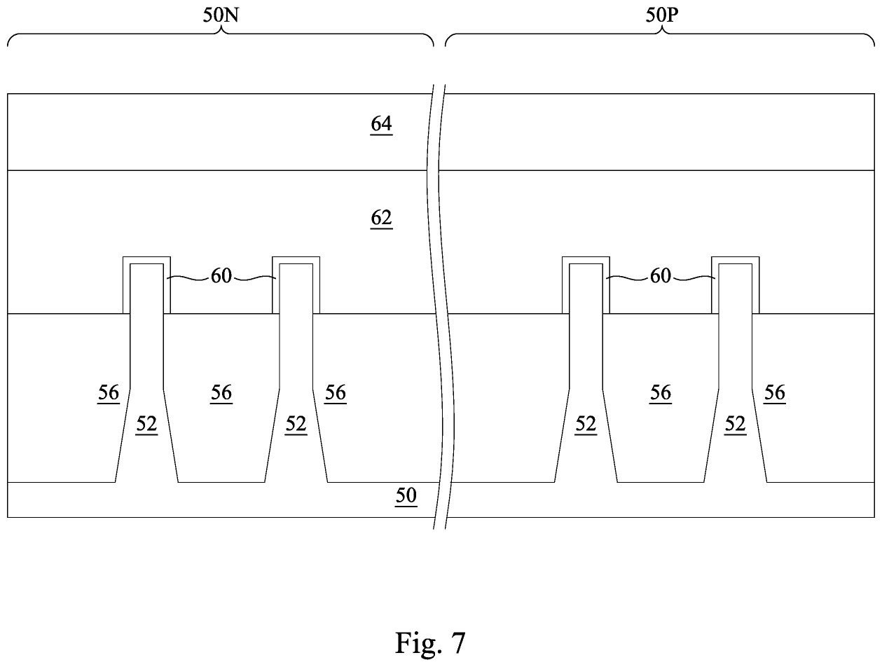

In FIG. 7, a dummy dielectric layer 60 is formed on the fins 52. The dummy dielectric layer 60 may be, for example, silicon oxide, silicon nitride, a combination thereof, or the like, and may be deposited or thermally grown according to acceptable techniques. A dummy gate layer 62 is formed over the dummy dielectric layer 60, and a mask layer 64 is formed over the dummy gate layer 62. The dummy gate layer 62 may be deposited over the dummy dielectric layer 60 and then planarized, such as by a CMP. The mask layer 64 may be deposited over the dummy gate layer 62. The dummy gate layer 62 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 62 may be deposited by physical vapor deposition (PVD), CVD, sputter deposition, or other techniques for depositing the selected material. The dummy gate layer 62 may be made of other materials that have a high etching selectivity from the etching of isolation regions, e.g., the STI regions 56 and/or the dummy dielectric layer 60. The mask layer 64 may include one or more layers of, for example, silicon nitride, silicon oxynitride, or the like. In this example, a single dummy gate layer 62 and a single mask layer 64 are formed across the n-type region 50N and the p-type region 50P. It is noted that the dummy dielectric layer 60 is shown covering only the fins 52 for illustrative purposes only. In some embodiments, the dummy dielectric layer 60 may be deposited such that the dummy dielectric layer 60 covers the STI regions 56, extending over the STI regions and between the dummy gate layer 62 and the STI regions 56.

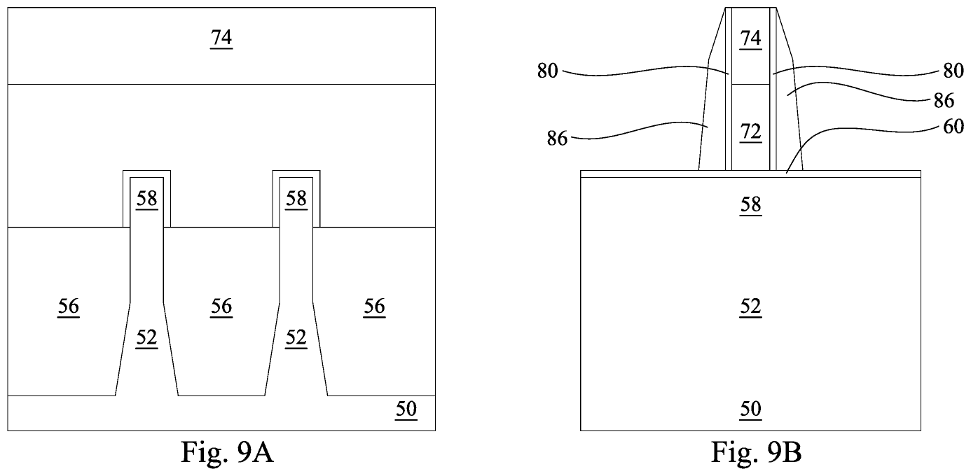

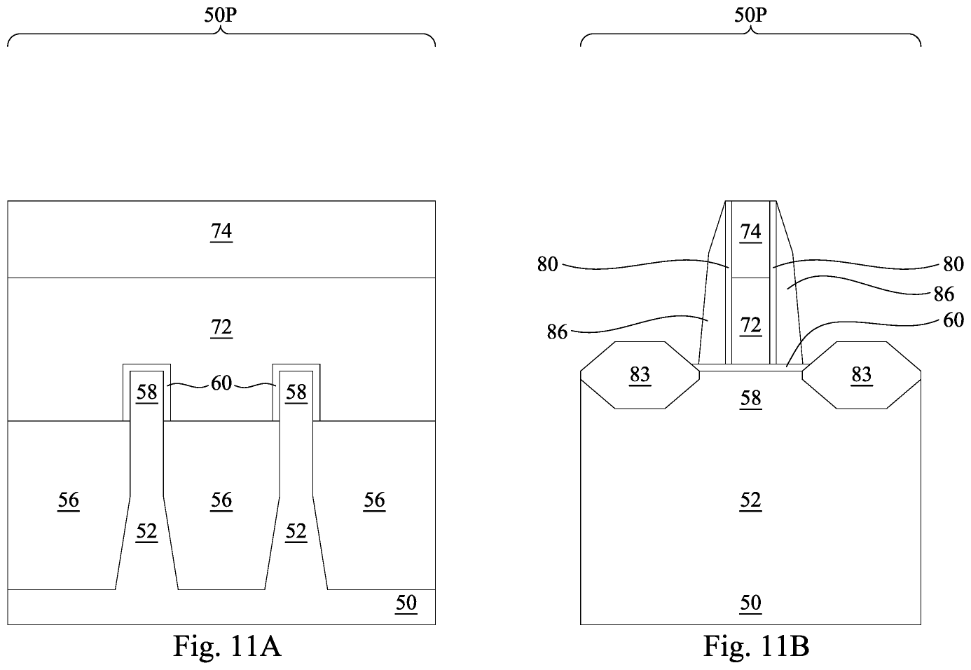

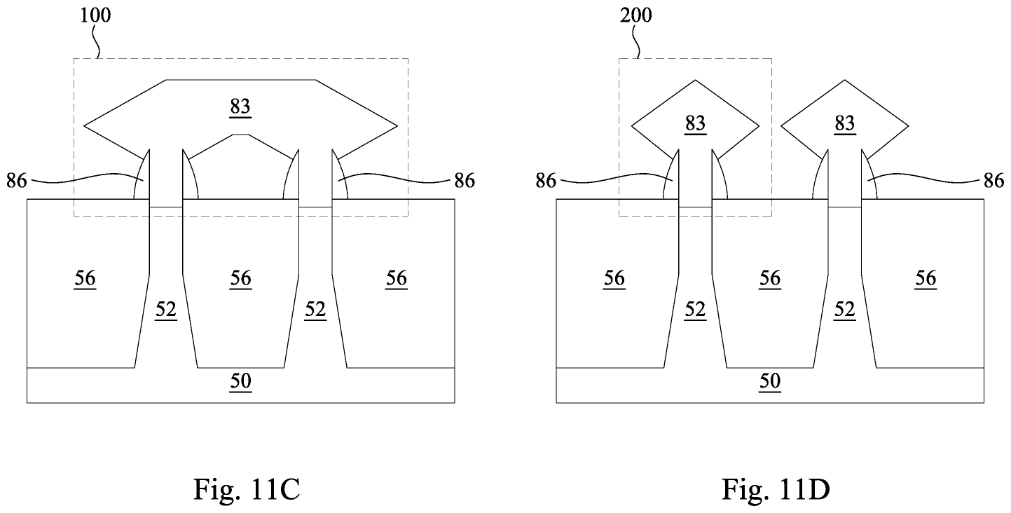

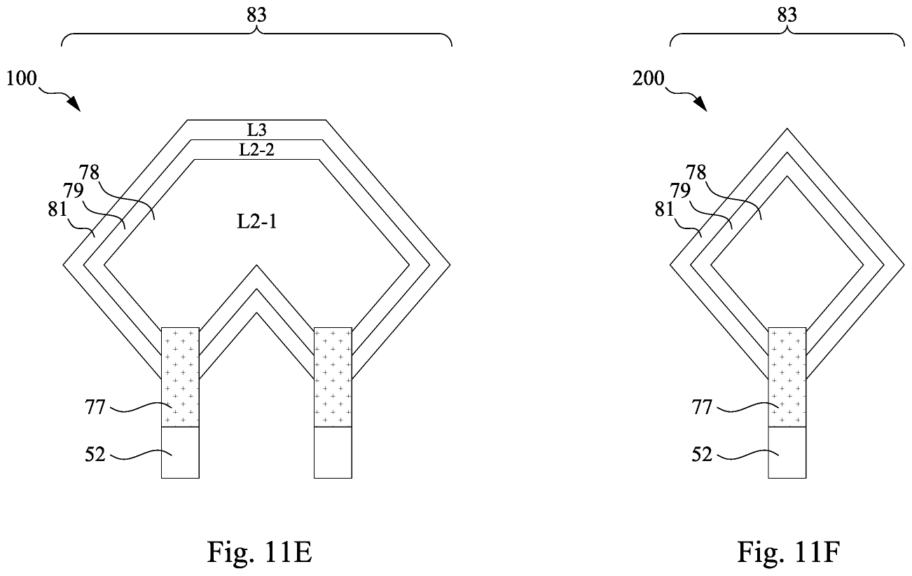

FIGS. 8A through 24D illustrate various additional steps in the manufacturing of embodiment devices. FIGS. 8A through 9B illustrate features in either of the n-type region 50N and the p-type region 50P. For example, the structures illustrated in FIGS. 8A through 9B may be applicable to both the n-type region 50N and the p-type region 50P. Differences (if any) in the structures of the n-type region 50N and the p-type region 50P are described in the text accompanying each figure. FIGS. 10A, 10B, 10C, 10D, 13A, 13B, 15A, 15B, 17A, 17B, 19A, 19B, 20C, 21A, 21B, 23A, and 23B may be applicable to the n-type region 50N. FIGS. 11A, 11B, 11C, 11D, 11E, 11F, 12A, 12B, 12C, 12D, 14A, 14B, 16A, 16B, 18A, 18B, 20A, 20B, 20C, 22A, 22B, 24A, 24B, 24C, and 24D may be applicable to the p-type region 50P.

In FIGS. 8A and 8B, the mask layer 64 (see FIG. 7) may be patterned using acceptable photolithography and etching techniques to form masks 74. The pattern of the masks 74 then may be transferred to the dummy gate layer 62. In some embodiments (not illustrated), the pattern of the masks 74 may also be transferred to the dummy dielectric layer 60 by an acceptable etching technique to form dummy gates 72. The dummy gates 72 cover respective channel regions 58 of the fins 52. The pattern of the masks 74 may be used to physically separate each of the dummy gates 72 from adjacent dummy gates. The dummy gates 72 may also have a lengthwise direction substantially perpendicular to the lengthwise direction of respective epitaxial fins 52.

Further in FIGS. 8A and 8B, gate seal spacers 80 can be formed on exposed surfaces of the dummy gates 72, the masks 74, and/or the fins 52. A thermal oxidation or a deposition followed by an anisotropic etch may form the gate seal spacers 80. The gate seal spacers 80 may be formed of silicon oxide, silicon nitride, silicon oxynitride, or the like.

After the formation of the gate seal spacers 80, implants for lightly doped source/drain (LDD) regions (not explicitly illustrated) may be performed. In the embodiments with different device types, similar to the implants discussed above in FIG. 6, a mask, such as a photoresist, may be formed over the n-type region 50N, while exposing the p-type region 50P, and appropriate type (e.g., p-type) impurities may be implanted into the exposed fins 52 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 52 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities of from about 10¹⁵ cm⁻³ to about 10¹⁹ cm⁻³. An anneal may be used to repair implant damage and to activate the implanted impurities.

In FIGS. 9A and 9B, gate spacers 86 are formed on the gate seal spacers 80 along sidewalls of the dummy gates 72 and the masks 74. The gate spacers 86 may be formed by conformally depositing an insulating material and subsequently anisotropically etching the insulating material. The insulating material of the gate spacers 86 may be silicon oxide, silicon nitride, silicon oxynitride, silicon carbonitride, a combination thereof, or the like.

It is noted that the above disclosure generally describes a process of forming spacers and LDD regions. Other processes and sequences may be used. For example, fewer or additional spacers may be utilized, different sequence of steps may be utilized (e.g., the gate seal spacers 80 may not be etched prior to forming the gate spacers 86, yielding “L-shaped” gate seal spacers, spacers may be formed and removed, and/or the like. Furthermore, the n-type and p-type devices may be formed using a different structures and steps. For example, LDD regions for n-type devices may be formed prior to forming the gate seal spacers 80 while the LDD regions for p-type devices may be formed after forming the gate seal spacers 80.

The structures illustrated in FIGS. 10A through 10D may be applicable to the n-type region 50N. In FIGS. 10A and 10B epitaxial source/drain regions 82 are formed in the fins 52. The epitaxial source/drain regions 82 are formed in the fins 52 such that each dummy gate 72 is disposed between respective neighboring pairs of the epitaxial source/drain regions 82. In some embodiments the epitaxial source/drain regions 82 may extend into, and may also penetrate through, the fins 52. In some embodiments, the gate spacers 86 are used to separate the epitaxial source/drain regions 82 from the dummy gates 72 by an appropriate lateral distance so that the epitaxial source/drain regions 82 do not short out subsequently formed gates of the resulting FinFETs. A material of the epitaxial source/drain regions 82 may be selected to exert stress in the respective channel regions 58, thereby improving performance.

The epitaxial source/drain regions 82 in the n-type region 50N may be formed by masking the p-type region 50P and etching source/drain regions of the fins 52 in the n-type region 50N to form recesses in the fins 52. Then, the epitaxial source/drain regions 82 in the n-type region 50N are epitaxially grown in the recesses. The epitaxial source/drain regions 82 may include any acceptable material, such as appropriate for n-type FinFETs. For example, if the fin 52 is silicon, the epitaxial source/drain regions 82 in the n-type region 50N may include materials exerting a tensile strain in the channel region 58, such as silicon, silicon carbide, phosphorous doped silicon carbide, silicon phosphide, or the like. The epitaxial source/drain regions 82 in the n-type region 50N may have surfaces raised from respective surfaces of the fins 52 and may have facets.

The epitaxial source/drain regions 82 and/or the fins 52 may be implanted with dopants to form source/drain regions, similar to the process previously discussed for forming lightly-doped source/drain regions, followed by an anneal. The source/drain regions may have an impurity concentration of between about 10¹⁹ cm⁻³ and about 10²¹ cm⁻³. The n-type impurities for source/drain regions may be any of the impurities previously discussed. In some embodiments, the epitaxial source/drain regions 82 may be in situ doped during growth.

As a result of the epitaxy processes used to form the epitaxial source/drain regions 82 in the n-type region 50N, upper surfaces of the epitaxial source/drain regions have facets which expand laterally outward beyond sidewalls of the fins 52. In some embodiments, these facets cause adjacent source/drain regions 82 of a same FinFET to merge as illustrated by FIG. 10C. In other embodiments, adjacent source/drain regions 82 remain separated after the epitaxy process is completed as illustrated by FIG. 10D. In the embodiments illustrated in FIGS. 10C and 10D, gate spacers 86 are formed covering a portion of the sidewalls of the fins 52 that extend above the STI regions 56 thereby blocking the epitaxial growth. In some other embodiments, the spacer etch used to form the gate spacers 86 may be adjusted to remove the spacer material to allow the epitaxially grown region to extend to the surface of the STI region 56.

The structures illustrated in FIGS. 11A through 11F may be applicable to the p-type region 50P. In FIGS. 11A and 11B epitaxial source/drain regions 83 are formed in the fins 52. The epitaxial source/drain regions 83 are formed in the fins 52 such that each dummy gate 72 is disposed between respective neighboring pairs of the epitaxial source/drain regions 83. In some embodiments the epitaxial source/drain regions 83 may extend into, and may also penetrate through, the fins 52. In some embodiments, the gate spacers 86 are used to separate the epitaxial source/drain regions 83 from the dummy gates 72 by an appropriate lateral distance so that the epitaxial source/drain regions 83 do not short out subsequently formed gates of the resulting FinFETs. A material of the epitaxial source/drain regions 83 may be selected to exert stress in the respective channel regions 58, thereby improving performance.

The epitaxial source/drain regions 83 in the p-type region 50P may be formed by masking the n-type region 50N and etching source/drain regions of the fins 52 in the p-type region 50P to form recesses in the fins 52. Then, the epitaxial source/drain regions 83 in the p-type region 50P are epitaxially grown in the recesses. The epitaxial source/drain regions 83 may include any acceptable material, such as appropriate for p-type FinFETs. For example, if the fin 52 is silicon, the epitaxial source/drain regions 83 in the p-type region 50P may comprise materials exerting a compressive strain in the channel region 58, such as silicon-germanium, boron doped silicon-germanium, germanium, germanium tin, or the like. The epitaxial source/drain regions 83 in the p-type region 50P may have surfaces raised from respective surfaces of the fins 52 and may have facets.

As a result of the epitaxy processes used to form the epitaxial source/drain regions 83 in the p-type region 50P, upper surfaces of the epitaxial source/drain regions have facets which expand laterally outward beyond sidewalls of the fins 52. In some embodiments, these facets cause adjacent source/drain regions 83 of a same FinFET to merge as illustrated by FIGS. 11C and 11E. In other embodiments, adjacent source/drain regions 83 remain separated after the epitaxy process is completed as illustrated by FIGS. 11D and 11F.

FIGS. 11C and 11E illustrate example processes for depositing the (sub) layers in merged epitaxial source/drain regions 83, in accordance with an embodiment. FIG. 11E shows a region 100 of the merged epitaxial source/drain regions 83 of FIG. 11C. FIGS. 11D and 11F illustrate example processes for depositing the (sub) layers in epitaxial source/drain regions 83 that remain separated from adjacent epitaxial source/drain regions 83 after the epitaxy processes are completed, in accordance with an embodiment. FIG. 11F shows a region 200 of the epitaxial source/drain regions 83 of FIG. 11D.

In FIGS. 11E and 11F, a first epitaxy layer 77 (which is also referred to as first epitaxy layer L1) is deposited in the recesses in the fins 52 through an epitaxy process. The deposition of the first epitaxy layer 77 may be performed using Reduced Pressure Chemical Vapor Deposition (RPCVD), Plasma Enhanced Chemical Vapor Deposition (PECVD), or the like. In accordance with some embodiments, the first epitaxy layer 77 may comprise SiGeB, or the like. After the deposition of the first epitaxy layer 77, a second epitaxy layer 78 (which is also referred to as second epitaxy layer L2-1), a third epitaxy layer 79 (which is also referred to as third epitaxy layer L2-2), and a fourth epitaxy layer 81 (which is also referred to as fourth epitaxy layer L3 or a first capping layer) are deposited through epitaxy processes. The deposition processes may be performed using RPCVD, PECVD, or the like. In accordance with some embodiments, the second epitaxy layer 78, the third epitaxy layer 79, and the fourth epitaxy layer 81 may comprise SiGeB, or the like. In an embodiment, each of the first epitaxy layer 77, the second epitaxy layer 78, the third epitaxy layer 79, and the fourth epitaxy layer 81 may have a boron concentration in the range from about 1×10²⁰/cm³ to about 2×10²¹/cm³. In an embodiment, each of the first epitaxy layer 77, the second epitaxy layer 78, the third epitaxy layer 79, and the fourth epitaxy layer 81 may have a germanium atomic percentage that is in a range from about 0 percent to about 70 percent. In an embodiment, during the epitaxy processes to deposit the first epitaxy layer 77, the second epitaxy layer 78, the third epitaxy layer 79, and the fourth epitaxy layer 81, the process reactants used may comprise silane, dichlorosilane, germane, borane, hydrochloric acid, dichlorogermane, combinations thereof, or the like. In an embodiment, during the epitaxy processes to deposit the first epitaxy layer 77, the second epitaxy layer 78, the third epitaxy layer 79, and the fourth epitaxy layer 81, the process temperatures used may be in a range from 550° C. to 850° C. In an embodiment, during the epitaxy processes to deposit the first epitaxy layer 77, the second epitaxy layer 78, the third epitaxy layer 79, and the fourth epitaxy layer 81, the process pressures used may be in a range from 20 torr to 300 torr.

In the embodiments illustrated in FIGS. 11C and 11D, gate spacers 86 are formed covering a portion of the sidewalls of the fins 52 that extend above the STI regions 56 thereby blocking the epitaxial growth. In some other embodiments, the spacer etch used to form the gate spacers 86 may be adjusted to remove the spacer material to allow the epitaxially grown region to extend to the surface of the STI region 56.

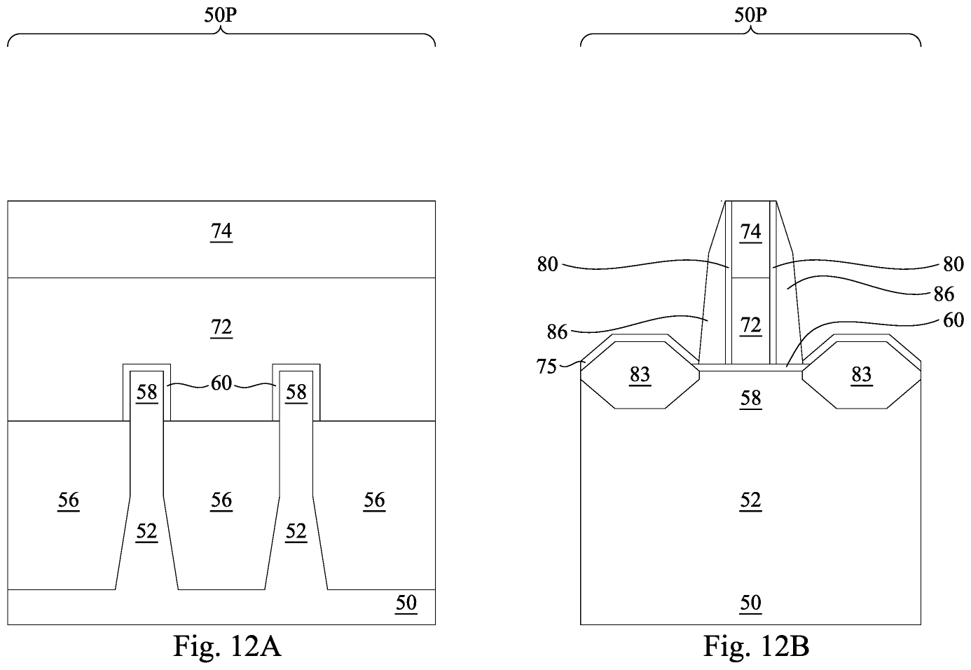

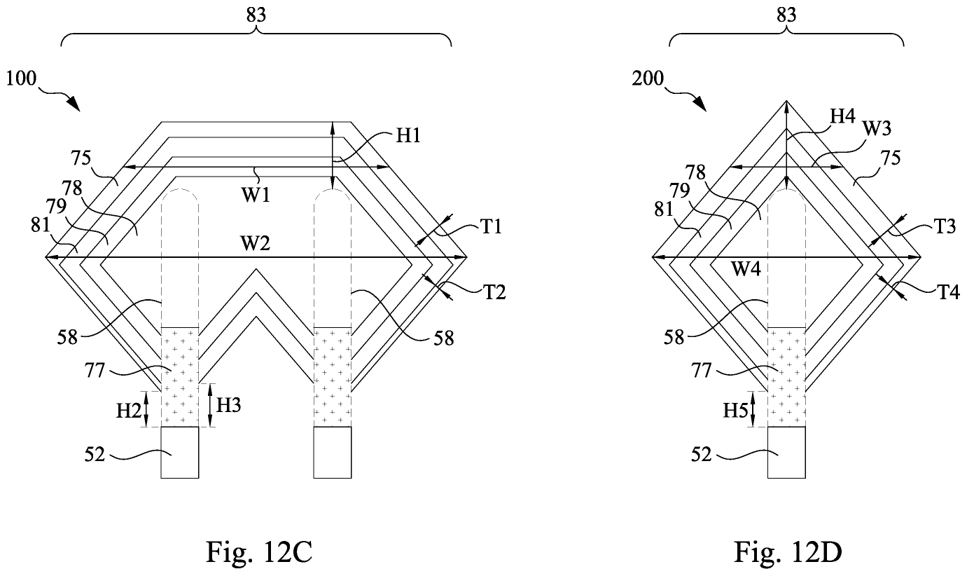

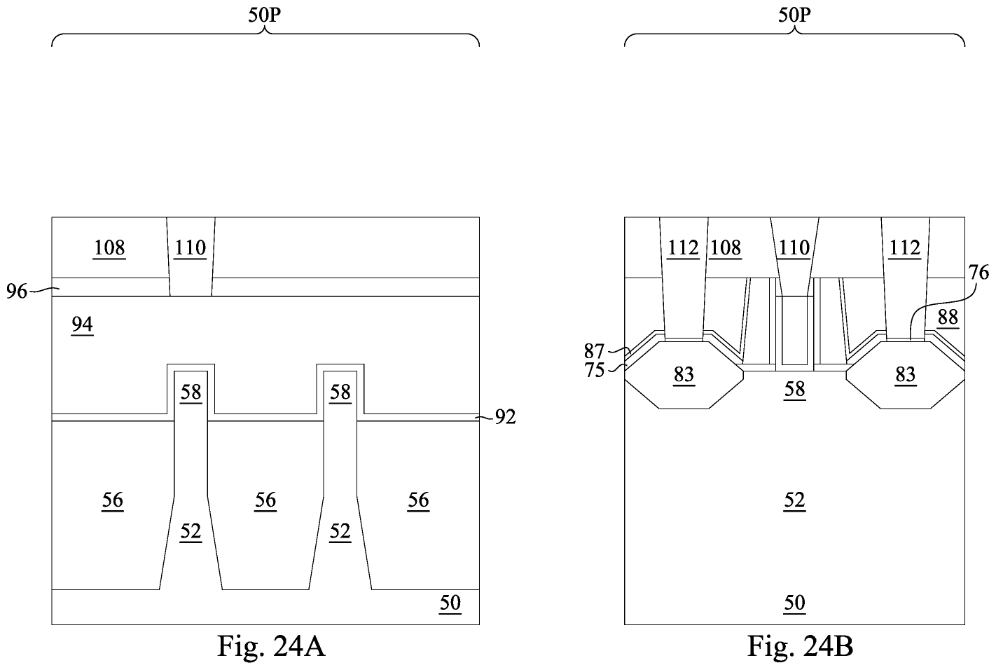

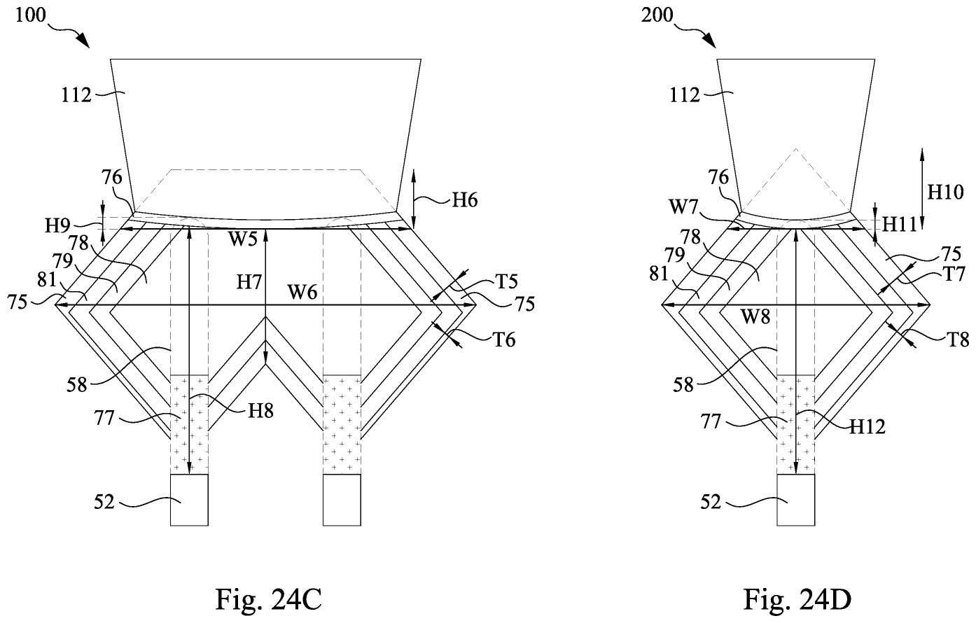

The structures illustrated in FIGS. 12A through 12D may be applicable to the p-type region 50P. In FIGS. 12A through 12D, a second capping layer 75 is selectively deposited over top surfaces and sidewalls of the epitaxial source/drain regions 83 illustrated in FIGS. 11A through 11F. The selective deposition of the second capping layer 75 may be performed using a suitable process, such as CVD, PVD, or the like while simultaneously flowing an etching gas, such as hydrochloric acid, or the like. The second capping layer 75 may be a boron containing layer, such as, a substantially pure boron layer. In an embodiment, the second capping layer 75 may comprise crystalline boron, amorphous boron, combinations thereof, or the like. In accordance with some embodiments, the second capping layer 75 may have a boron concentration in the range from about 3×10²¹/cm³ to about 1×10²²/cm³. Advantages can be achieved as a result of the formation of the second capping layer 75 having a boron concentration in a range from 3×10²¹/cm³ to about 1×10²²/cm³. For example, the second capping layer 75 having a boron concentration outside a range from 3×10²¹/cm³ to about 1×10²²/cm³ would lead to a reduction in the ability to retard epitaxial source/drain region 83 loss during a subsequent fluorine based etching process used to form source/drain contact openings (shown subsequently in FIGS. 24A through 24D). In an embodiment, the second capping layer 75 may have a higher boron concentration than the boron concentration of the epitaxial source/drain regions 83 (e.g., higher than any of the first epitaxy layer 77, the second epitaxy layer 78, the third epitaxy layer 79, and the fourth epitaxy layer 81). In an embodiment, during the deposition of the second capping layer 75, the process reactants used may comprise borane, diborane, boron trichloride, combinations thereof, or the like. Further, an etchant, such as hydrochloric acid, may be simultaneously supplied with the process reactants to aid in the selective deposition of the second capping layer on the epitaxial source/drain regions 83. The etchant will retard the formation of the second capping layer 75 on surfaces of the STI region 56 and the gate spacers 86, which are formed of dielectric materials. In an embodiment, during the deposition of the second capping layer 75, the process temperatures may be in a range from 500° C. to 700° C. In an embodiment, during the deposition of the second capping layer 75, the process pressures may be in a range from 20 torr to 60 torr.

In some embodiments, boron atoms may diffuse from the second capping layer 75 (which acts as a boron dopant donor) to the channel regions 58 through the epitaxial source/drain regions 83. In accordance with some embodiments, after the diffusion of the boron atoms, the channel regions 58 may have a boron concentration in the range from about 1×10¹⁵/cm³ to about 1×10¹⁸/cm³. In an embodiment, after the diffusion of the boron atoms, the channel regions 58 may have a boron concentration that is lower than 1×10¹⁸/cm³.

FIG. 12C shows the region 100 of the merged epitaxial source/drain regions 83 after the deposition of the second capping layer 75. The channel regions 58 are shown in ghost. In an embodiment, a first height H1 between a top surface of the second capping layer 75 and a topmost point of the channel regions 58 is in a range from −5 nm to 15 nm. In an embodiment, a second height H2 of an outermost sidewall of the merged epitaxial source/drain regions 83 between a bottomost point of the second capping layer 75 and a bottommost point of the channel regions 58 is in a range from 5 nm to 25 nm. In an embodiment, the second height H2 is larger than 10 nm. In an embodiment, a third height H3 of an innermost sidewall of the merged epitaxial source/drain regions 83 between a bottomost point of the fourth epitaxy layer 81 and a bottomost surface of the channel regions 58 is in a range from 5 nm to 25 nm. In an embodiment, a first width W1 from a first point on a first outer sidewall of the second capping layer 75 to a second point on a second outer sidewall of the second capping layer 75 is in a range from 20 nm to 60 nm, where the first point and the second point are lower than a top surface of the second capping layer 75 by a vertical distance of 5 nm. In an embodiment, a second width W2 between outermost points of the second capping layer 75 is in a range from 40 nm to 70 nm. In an embodiment, a first portion of the second capping layer 75 has a first thickness T1 that is in a range from 0.5 nm to 2 nm, where the first portion of the second capping layer 75 extends from a top surface of the second capping layer 75 to an outermost point of the second capping layer. In an embodiment, a second portion of the second capping layer 75 has a second thickness T2 that may be up to 2 nm, where the second portion extends from a bottommost portion of the second capping layer 75 to an outermost point of the second capping layer 75. In an embodiment, the first thickness T1 is larger than the second thickness T2. The first thickness T1 being larger than the second thickness T2 would lead to an increased ability of the first portion of the second capping layer 75 to retard epitaxial source/drain region 83 loss during a subsequent fluorine based etching process used to form source/drain contact openings (shown subsequently in FIGS. 24A through 24D).

FIG. 12D shows the region 200 of the epitaxial source/drain region 83 which is separate from adjacent epitaxial source/drain regions, after the deposition of the second capping layer 75. The channel region 58 are shown in ghost. In an embodiment, a fourth height H4 between a topmost point of the second capping layer 75 and a topmost point of the channel region 58 is in a range from −5 nm to 10 nm. In an embodiment, a fifth height H5 of a sidewall of the epitaxial source/drain region 83 between a bottommost point of the second capping layer 75 and a bottommost point of the channel region 58 is in a range from 5 nm to 25 nm. In an embodiment, the fifth height H5 is larger than 10 nm. In an embodiment, a third width W3 from a first point on a first outer sidewall of the second capping layer 75 to a second point on a second outer sidewall of the second capping layer 75 is in a range from 5 nm to 25 nm, where the first point and the second point are lower than a topmost point of the second capping layer 75 by a vertical distance of 5 nm. In an embodiment, a fourth width W4 between outermost points of the second capping layer 75 is in a range from 25 nm to 45 nm. In an embodiment, a first portion of the second capping layer 75 has a third thickness T3 that is in a range from 0.5 nm to 2 nm, where the first portion of the second capping layer 75 extends from a topmost point of the second capping layer 75 to an outermost point of the second capping layer 75. In an embodiment, a second portion of the second capping layer 75 has a fourth thickness T4 that may be up to 2 nm, where the second portion extends from a bottommost portion of the second capping layer 75 to an outermost point of the second capping layer 75. In an embodiment, the third thickness T3 is larger than the fourth thickness T4. The third thickness T3 being larger than the fourth thickness T4 would lead to an increased ability of the first portion of the second capping layer 75 to retard epitaxial source/drain region 83 loss during a subsequent fluorine based etching process used to form source/drain contact openings (shown subsequently in FIGS. 24A through 24D).

Advantages can be achieved as a result of the formation of the second capping layer 75 over top surfaces and sidewalls of the epitaxial source/drain regions 83. These advantages may include the second capping layer 75 acting as a sacrificial layer and retarding epitaxial source/drain region loss during a fluorine based etching process used to form openings for source/drain contacts 112 (shown subsequently in FIGS. 24A through 24D) in a first inter-layer dielectric (ILD) 88 and a second ILD 108 (shown subsequently in FIGS. 24A through 24D). The second capping layer 75 may act as a dopant donor to slightly dope the channel regions 58 which results in lower channel resistance and improved electrical performance. In addition, the use of the second capping layer 75 allows the epitaxial source/drain regions 83 to retain a larger volume of high percentage germanium epitaxial material even after source/drain contact formation. This may result in a lower resistance between the source/drain region and the subsequently formed source/drain contacts 112 (shown subsequently in FIGS. 24A through 24D) that physically contact this high percentage germanium epitaxial material. Further, the decreased epitaxial source/drain region loss during the fluorine based etching process due to the use of the second capping layer 75 results in the epitaxial source/drain regions 83 having a higher raised height.

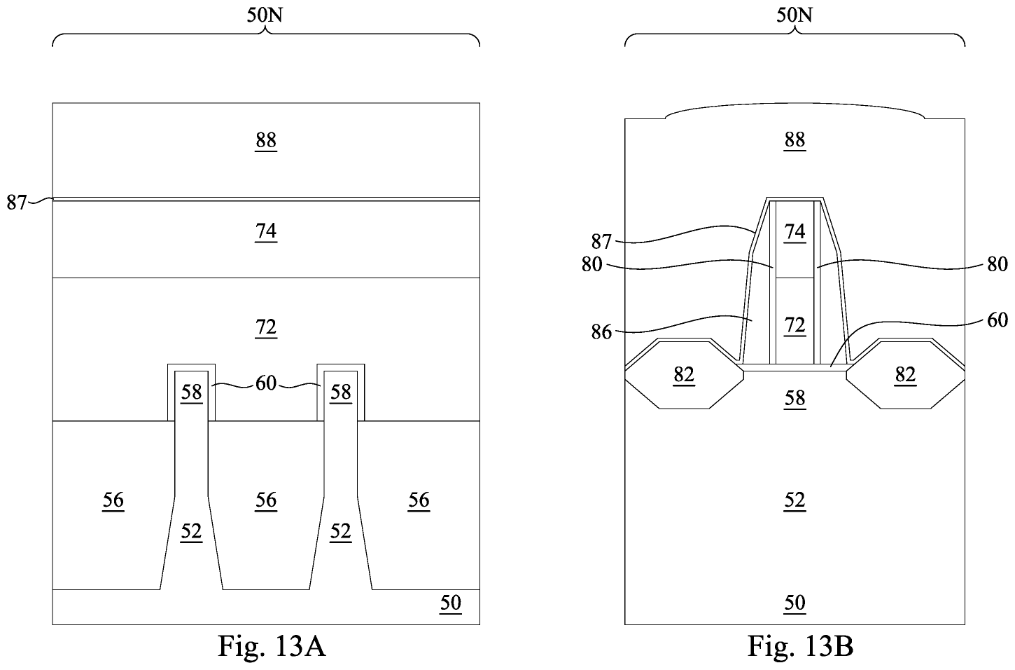

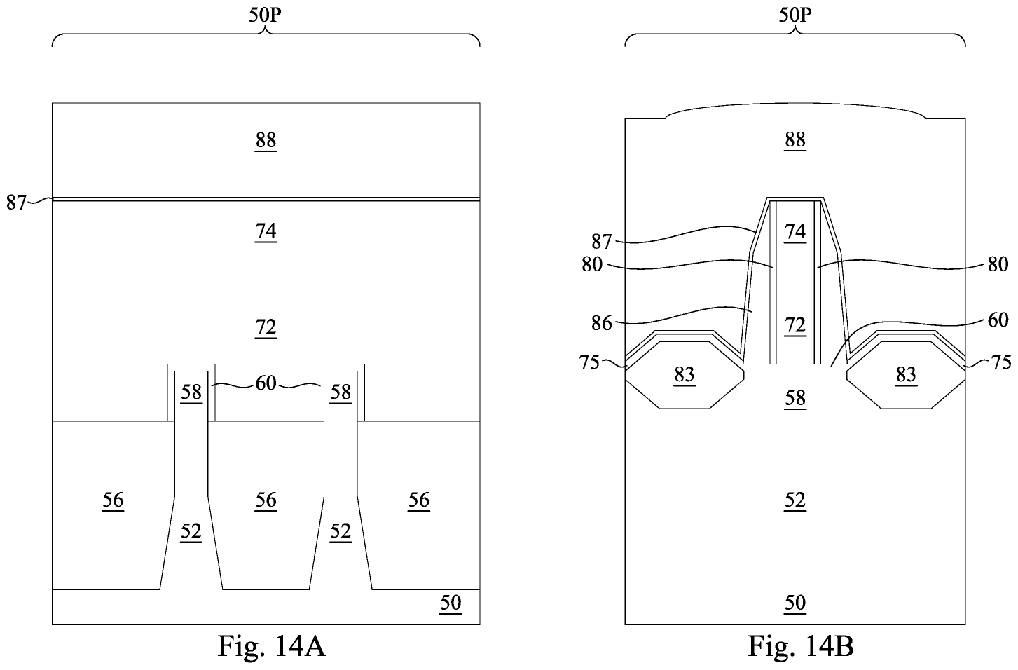

In FIGS. 13A and 13B, a first interlayer dielectric (ILD) 88 is deposited over the structure illustrated in FIGS. 10A and 10B (e.g., the n-type region 50N), and in FIGS. 14A and 14B, the first interlayer dielectric (ILD) 88 is deposited over the structure illustrated in FIGS. 11A and 11B (e.g., p-type region 50P). The first ILD 88 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In an embodiment, the first ILD 88 may comprise silicon oxide. In FIGS. 13A and 13B, a contact etch stop layer (CESL) 87 is disposed between the first ILD 88 and the epitaxial source/drain regions 82, the masks 74, and the gate spacers 86, according to some embodiments. In FIGS. 14A and 14B, the contact etch stop layer (CESL) 87 is disposed between the first ILD 88 and the second capping layer 75, according to some embodiments. The CESL 87 may comprise a dielectric material, such as, silicon nitride, silicon oxide, silicon oxynitride, or the like, having a lower etch rate than the material of the overlying first ILD 88. In an embodiment in which the first ILD comprises silicon oxide, the second capping layer 75 may be oxidized to form an oxide (e.g., boron oxide) during the deposition of the first ILD 88.

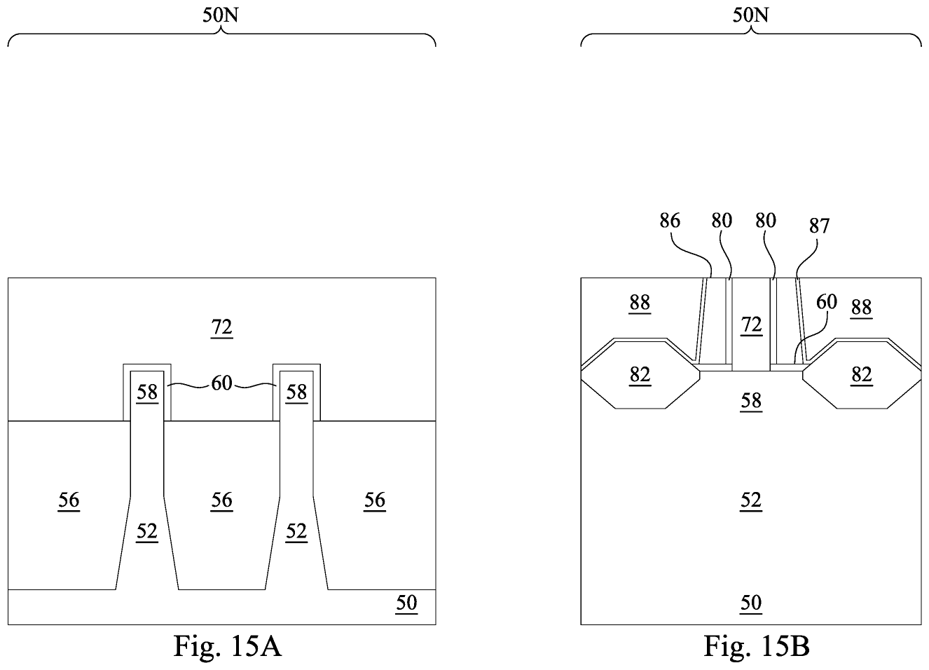

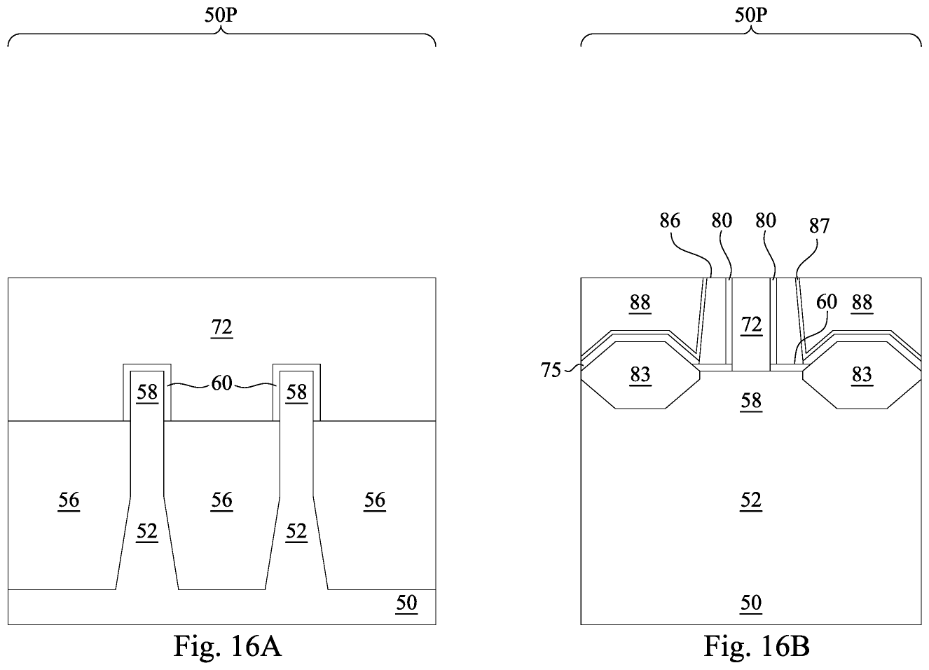

After the deposition of the first interlayer dielectric (ILD) 88 over the structure illustrated in FIGS. 10A, 10B, 11A, and 11B, a planarization process, such as that shown in FIGS. 15A and 15B for the n-type region 50N, and that shown in FIGS. 16A and 16B for the p-type region 50P is performed. The planarization process may be a CMP, and may be performed to level the top surface of the first ILD 88 with the top surfaces of the dummy gates 72 or the masks 74. The planarization process may also remove the masks 74 on the dummy gates 72, and portions of the gate seal spacers 80 and the gate spacers 86 along sidewalls of the masks 74. After the planarization process, top surfaces of the dummy gates 72, the gate seal spacers 80, the gate spacers 86, and the first ILD 88 are level. Accordingly, the top surfaces of the dummy gates 72 are exposed through the first ILD 88. In some embodiments, the masks 74 may remain, in which case the planarization process levels the top surface of the first ILD 88 with the top surfaces of the top surface of the masks 74.

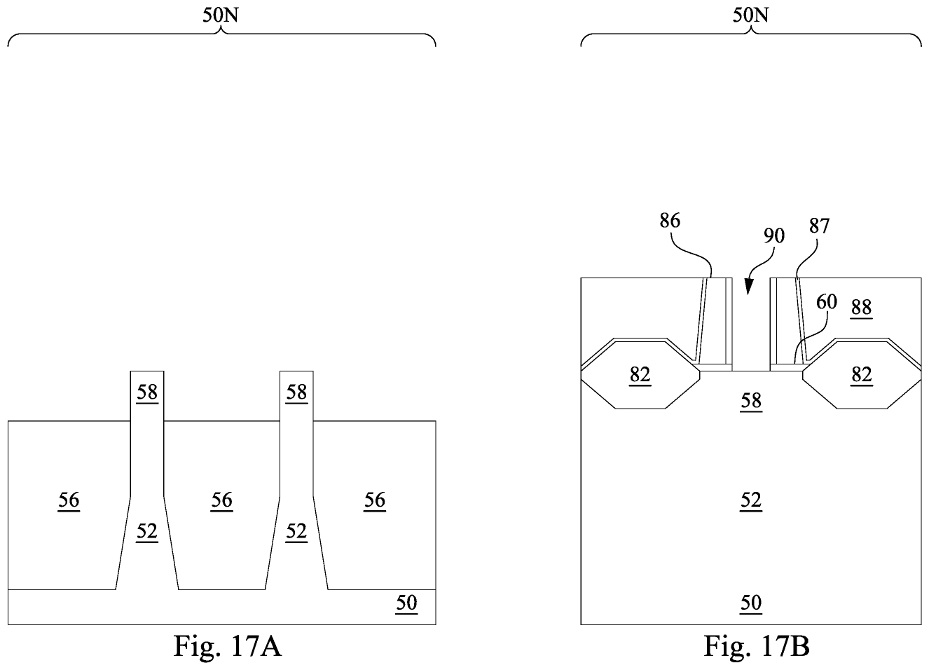

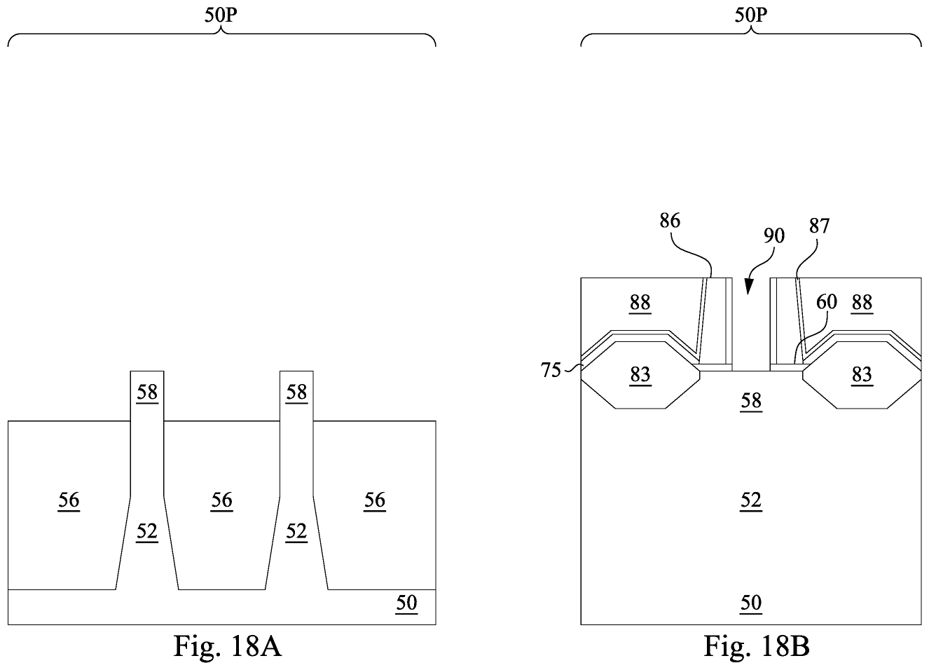

In FIGS. 17A and 17B, and FIGS. 18A and 18B, the dummy gates 72, and the masks 74 if present, are removed from the n-type region 50N and the p-type region, respectively, through an etching step(s), so that recesses 90 are formed. Portions of the dummy dielectric layer 60 in the recesses 90 may also be removed. In some embodiments, only the dummy gates 72 are removed and the dummy dielectric layer 60 remains and is exposed by the recesses 90. In some embodiments, the dummy dielectric layer 60 is removed from recesses 90 in a first region of a die (e.g., a core logic region) and remains in recesses 90 in a second region of the die (e.g., an input/output region). In some embodiments, the dummy gates 72 are removed by an anisotropic dry etch process. For example, the etching process may include a dry etch process using reaction gas(es) that selectively etch the dummy gates 72 with little or no etching of the first ILD 88 or the gate spacers 86. Each recess 90 exposes and/or overlies a channel region 58 of a respective fin 52. Each channel region 58 is disposed between neighboring pairs of the epitaxial source/drain regions 82/83. During the removal, the dummy dielectric layer 60 may be used as an etch stop layer when the dummy gates 72 are etched. The dummy dielectric layer 60 may then be optionally removed after the removal of the dummy gates 72.

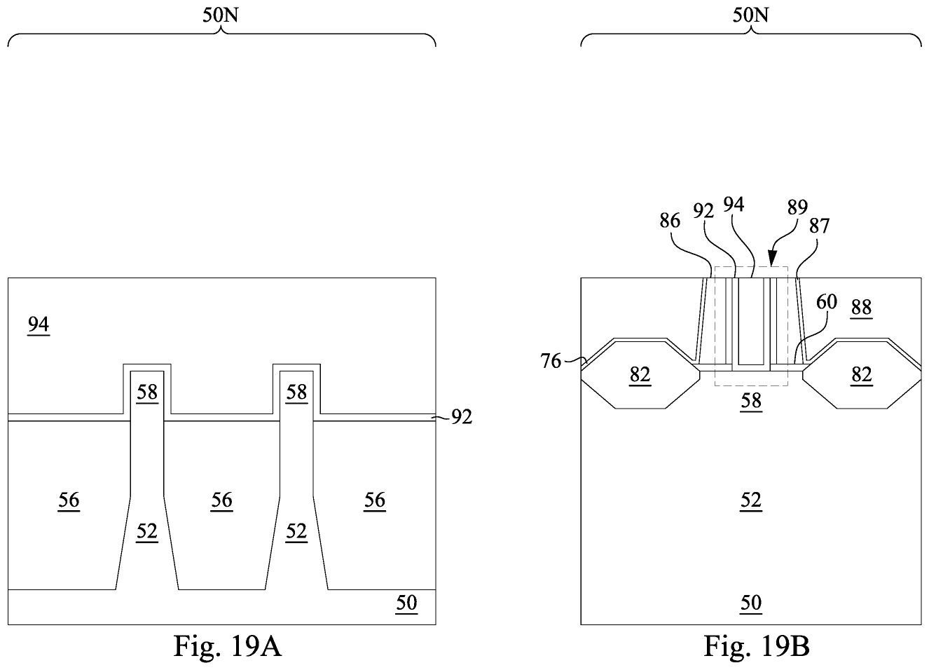

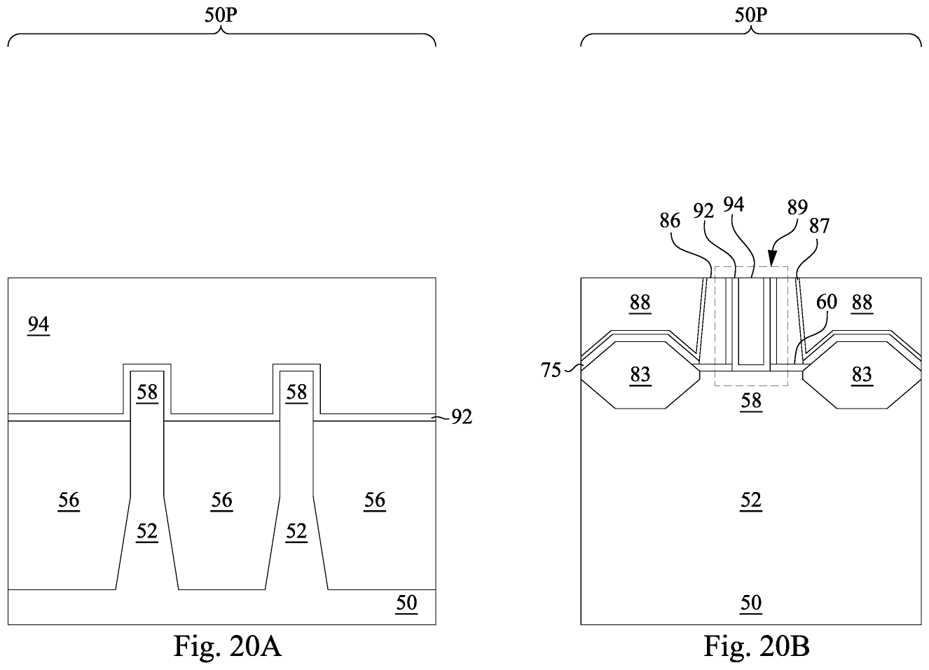

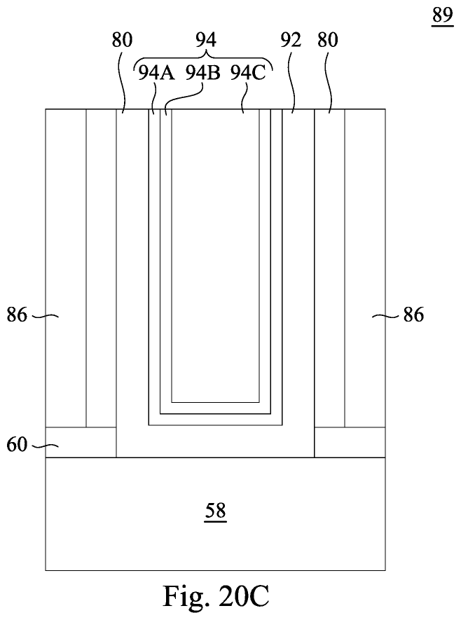

In FIGS. 19A and 19B, gate dielectric layers 92 and gate electrodes 94 are formed for replacement gates in the n-type region 50N, and in FIGS. 20A and 20B, gate dielectric layers 92 and gate electrodes 94 are formed for replacement gates in the p-type region 50P. FIG. 20C illustrates a detailed view of region 89 of FIGS. 19B and 20B. Gate dielectric layers 92 one or more layers deposited in the recesses 90, such as on the top surfaces and the sidewalls of the fins 52 and on sidewalls of the gate seal spacers 80/gate spacers 86. The gate dielectric layers 92 may also be formed on the top surface of the first ILD 88. In some embodiments, the gate dielectric layers 92 comprise one or more dielectric layers, such as one or more layers of silicon oxide, silicon nitride, metal oxide, metal silicate, or the like. For example, in some embodiments, the gate dielectric layers 92 include an interfacial layer of silicon oxide formed by thermal or chemical oxidation and an overlying high-k dielectric material, such as a metal oxide or a silicate of hafnium, aluminum, zirconium, lanthanum, manganese, barium, titanium, lead, and combinations thereof. The gate dielectric layers 92 may include a dielectric layer having a k value greater than about 7.0. The formation methods of the gate dielectric layers 92 may include Molecular-Beam Deposition (MBD), ALD, PECVD, and the like. In embodiments where portions of the dummy gate dielectric 60 remains in the recesses 90, the gate dielectric layers 92 include a material of the dummy gate dielectric 60 (e.g., SiO₂).

The gate electrodes 94 are deposited over the gate dielectric layers 92, respectively, and fill the remaining portions of the recesses 90. The gate electrodes 94 may include a metal-containing material such as titanium nitride, titanium oxide, tantalum nitride, tantalum carbide, cobalt, ruthenium, aluminum, tungsten, combinations thereof, or multi-layers thereof. For example, although a single layer gate electrode 94 is illustrated in FIGS. 19B and 20B, the gate electrode 94 may comprise any number of liner layers 94A, any number of work function tuning layers 94B, and a fill material 94C as illustrated by FIG. 20C. After the filling of the recesses 90, a planarization process, such as a CMP, may be performed to remove the excess portions of the gate dielectric layers 92 and the material of the gate electrodes 94, which excess portions are over the top surface of the ILD 88. The remaining portions of material of the gate electrodes 94 and the gate dielectric layers 92 thus form replacement gates of the resulting FinFETs. The gate electrodes 94 and the gate dielectric layers 92 may be collectively referred to as a “gate stack.” The gate and the gate stacks may extend along sidewalls of a channel region 58 of the fins 52.

The formation of the gate dielectric layers 92 in the n-type region 50N and the p-type region 50P may occur simultaneously such that the gate dielectric layers 92 in each region are formed from the same materials, and the formation of the gate electrodes 94 may occur simultaneously such that the gate electrodes 94 in each region are formed from the same materials. In some embodiments, the gate dielectric layers 92 in each region may be formed by distinct processes, such that the gate dielectric layers 92 may be different materials, and/or the gate electrodes 94 in each region may be formed by distinct processes, such that the gate electrodes 94 may be different materials. Various masking steps may be used to mask and expose appropriate regions when using distinct processes.

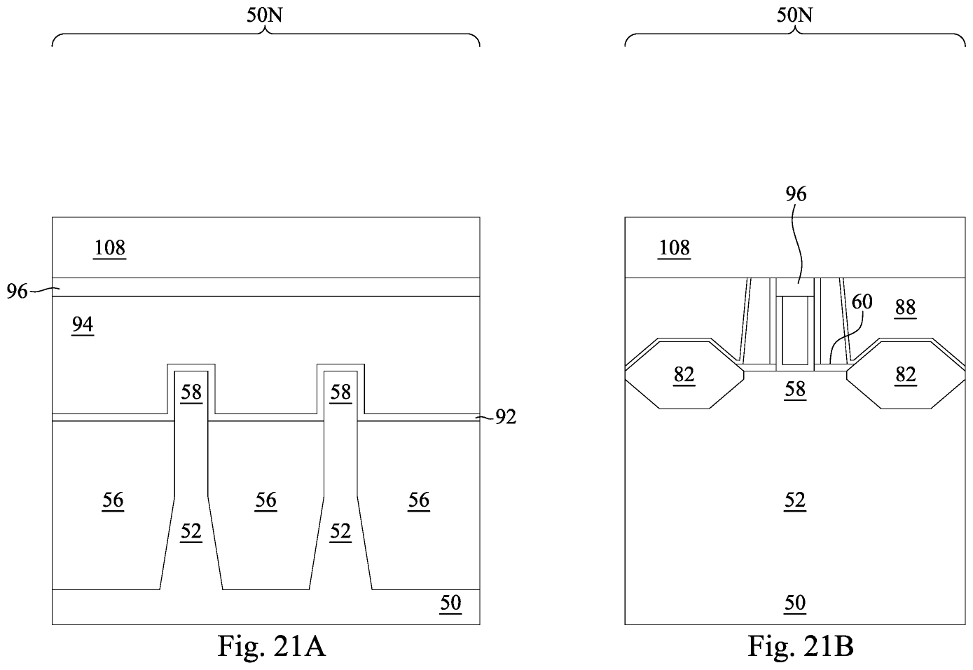

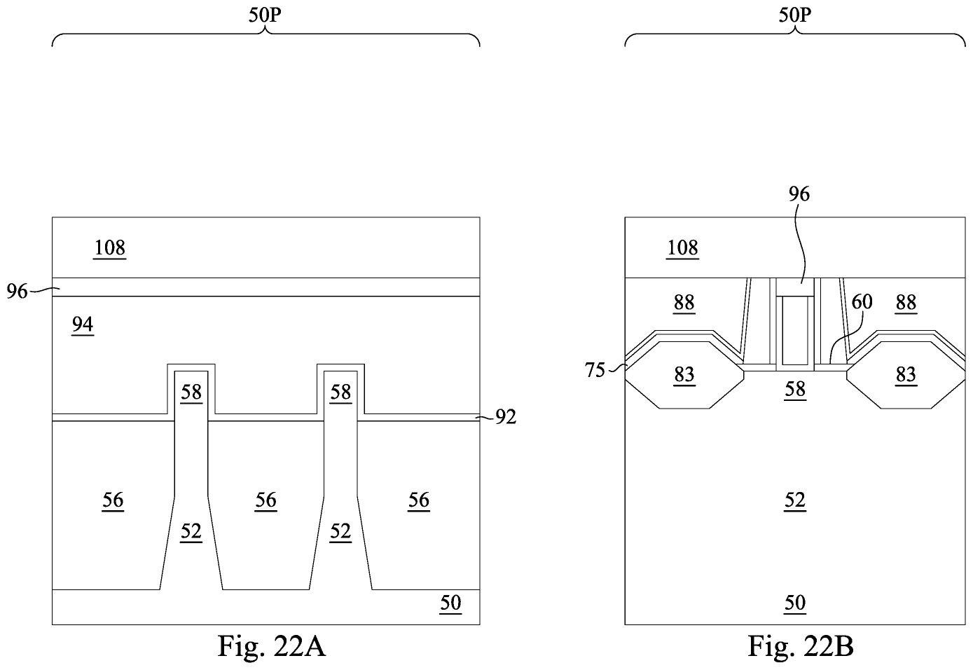

In FIGS. 21A and 21B, a gate mask 96 is formed over the gate stack (including a gate dielectric layer 92 and a corresponding gate electrode 94) in the n-type region 50N, and in FIGS. 22A and 22B, a gate mask 96 is formed over the gate stack (including a gate dielectric layer 92 and a corresponding gate electrode 94) in the p-type region 50P. Each of the gate masks 96 may be disposed between opposing portions of the gate spacers 86. In some embodiments, forming each of the gate masks 96 includes recessing the gate stack so that a recess is formed directly over the gate stack and between opposing portions of gate spacers 86. A gate mask 96 comprising one or more layers of dielectric material, such as silicon nitride, silicon oxynitride, or the like, is filled in the recess, followed by a planarization process to remove excess portions of the dielectric material extending over the first ILD 88.

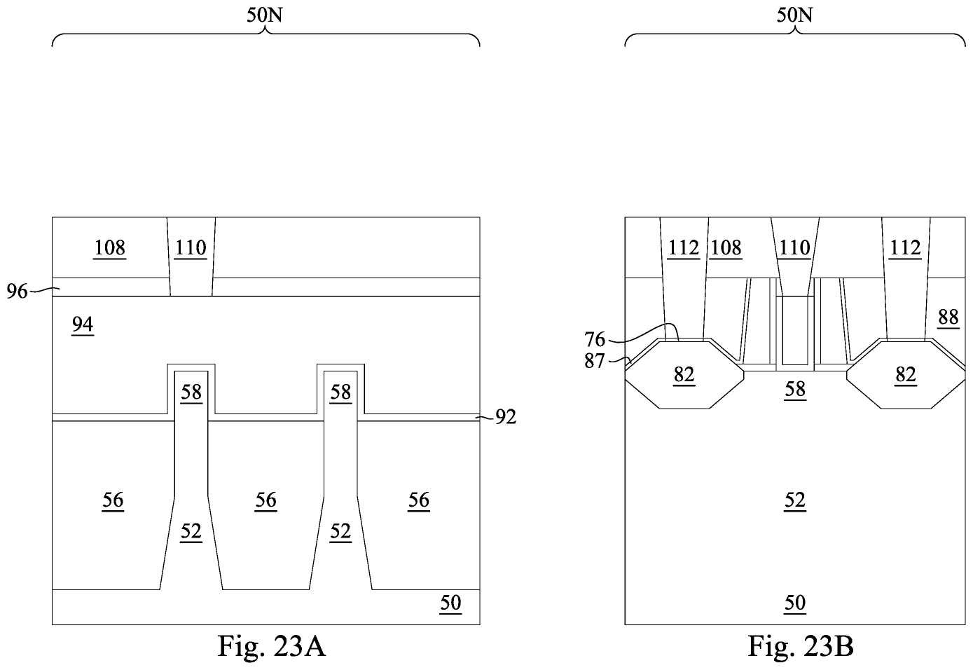

As also illustrated in FIGS. 21A and 21B, and FIGS. 22A and 22B, second ILD 108 is deposited over the first ILD 88. In some embodiments, the second ILD 108 is a flowable film formed by a flowable CVD method. In some embodiments, the second ILD 108 is formed of a dielectric material such as PSG, BSG, BPSG, USG, or the like, and may be deposited by any suitable method, such as CVD and PECVD. In an embodiment, the second ILD 108 may comprise silicon oxide. The subsequently formed gate contacts 110 (FIGS. 23A through 24B) penetrate through the second ILD 108 and the gate mask 96 of each of the n-type region 50N and the p-type region 50P to contact the top surface of the recessed gate electrode 94.

In FIGS. 23A and 23B, source/drain contacts 112 are formed through the second ILD 108, the first ILD 88, and the CESL 87 in the n-type region 50N, and in FIGS. 24A through 24D, source/drain contacts 112 are formed through the second ILD 108, the first ILD 88, the CESL 87, and the second capping layer 75 in the p-type region 50P, in accordance with some embodiments. Also in FIGS. 23A through 24D, gate contacts 110 are formed through the second ILD 108 and the gate mask 96 in both the n-type region 50N, and the p-type region 50P. Openings for the source/drain contacts 112 in the n-type region 50N are formed through the CESL 87, the first ILD 88 and the second ILD 108, and openings for the gate contact 110 are formed through the second ILD 108 and the gate mask 96. Openings for the source/drain contacts 112 in the p-type region 50N are formed through the CESL 87, the first ILD 88, the second ILD 108, and the second capping layer 75, and openings for the gate contact 110 are formed through the second ILD 108 and the gate mask 96. The openings may be formed using acceptable photolithography and etching techniques. As an example to form the openings, a mask may be formed over the second ILD 108, and the mask may be patterned using acceptable photolithography techniques. The CESL 87, first ILD 88 and the second ILD 108 in the n-type region 50N may then be etched using the mask as an etching mask to form the openings for the source/drain contacts 112, and the second ILD 108 may be etched using the mask as an etching mask to form the openings for gate contacts 110. The CESL 87, the first ILD 88, the second ILD 108, and the second capping layer 75 in the p-type region 50P may also be etched using the mask as an etching mask to form the openings for the source/drain contacts 112, and the second ILD 108 may be etched using the mask as an etching mask to form the openings for gate contacts 110.

In some embodiments, the etching process is a dry etch process. For example, when the first ILD 88 and the second ILD 108 are formed of silicon oxide, the dry etch process may comprise an etching gas solution that includes hydrogen fluoride (HF). In an embodiment, the dry etch process may comprise a fluorine based plasma etch process. After the etching process, the mask is removed, such as by any acceptable ashing process. During the etching process, the etch selectivity of the capping layer 75 is high as compared to materials of the epitaxial source/drain regions 83. As a result, the capping layer 75 serves as a sacrificial layer and retards the etching of the epitaxial source/drain regions 83 and reduces epitaxial source/drain region loss during the etching process. This may result in a lower resistance between the epitaxial source/drain region 83 and subsequently formed source/drain contacts 112.

After forming the openings, a liner may be formed in the openings. The liner may include a metal such as cobalt, titanium, nickel, or the like. The liner may be deposited by a deposition process such as ALD, CVD, PVD, or the like. An anneal process may be performed on the liner to form a silicide 76 on the epitaxial source/drain regions 82/83, and any remaining un-reacted liner material is removed by an etching process. In an embodiment, the silicide 76 may comprise a metal silicide such as titanium silicide, cobalt silicide, nickel silicide, or the like. Subsequently, a diffusion barrier layer, an adhesion layer, or the like, is formed in the openings. The liner may include titanium, titanium nitride, tantalum, tantalum nitride, or the like. The diffusion barrier layer may be deposited by a deposition process such as ALD, CVD, PVD, or the like. Next, a conductive material is formed in the openings. The conductive material may be copper, a copper alloy, silver, gold, tungsten, cobalt, aluminum, nickel, or the like. A planarization process, such as a CMP, may be performed to remove excess material from a surface of the ILD 108. The remaining conductive material forms the source/drain contacts 112 and gate contacts 110 in the openings. The source/drain contacts 112 are physically and electrically coupled to the epitaxial source/drain regions 82/83, and the gate contacts 110 are physically and electrically coupled to the gate electrodes 106. The source/drain contacts 112 and gate contacts 110 may be formed in different processes, or may be formed in the same process. Although shown as being formed in the same cross-sections, it should be appreciated that each of the source/drain contacts 112 and gate contacts 110 may be formed in different cross-sections, which may avoid shorting of the contacts.

FIG. 24C shows the region 100 of the merged epitaxial source/drain regions 83 in the p-type region 50P after the formation of the source/drain contacts 112. The region 116 shows the position of the top surface of the second capping layer 75 prior to the forming of openings for the source/drain contacts 112. The channel regions 58 are shown in ghost. In an embodiment, during the etching process to form the openings for the source/drain contacts 112 in the p-type region 50P, the epitaxial source/drain regions 83 and the second capping layer 75 may be recessed by a sixth height H6, where the sixth height H6 is in a range from 5 nm to 25 nm. In an embodiment, at a center point between inner sidewalls of adjacent recessed fins 52, the epitaxial source/drain regions 83 have a seventh height H7, where the seventh height H7 may be in a range from 5 nm to 30 nm. In an embodiment, an eighth height H8 of the merged epitaxial source/drain regions 83 from a first point at the center of the topmost surface of recessed fin 52 to a second point on the bottom surface of the silicide layer 76 that is vertically above the first point is in a range from 5 nm to 50 nm. In an embodiment, the seventh height H7 and the eighth height H8 may be larger than 20 nm. In an embodiment, a difference in height between a bottommost point of the silicide layer 76 and a topmost point of the channel regions 58 is a ninth height H9, where the ninth height H9 may be up to 15 nm. In an embodiment, a fifth width W5 from a first point on a first outer sidewall of the second capping layer 75 to a second point on a second outer sidewall of the second capping layer 75 is in a range from 20 nm to 50 nm, where a bottommost point of the silicide layer 76 is at the same height as the first point and the second point. In an embodiment in which the merged epitaxial source/drain regions 83 comprise an N number of adjacent recessed fins 52, a sixth width W6 between outermost points of the second capping layer 75 is a product of N and any value of the range from 30 nm to 50 nm. In an embodiment, a first portion of the second capping layer 75 has a fifth thickness T5 that is in a range from 0.5 nm to 2 nm, where the first portion of the second capping layer 75 is above the outermost points of the second capping layer 75. In an embodiment, a second portion of the second capping layer 75 has a second thickness T6 that may be up to 2 nm, where the second portion is below the outermost points of the second capping layer 75. In an embodiment, the fifth thickness T5 is larger than the sixth thickness T6.

FIG. 24D shows the region 200 of the epitaxial source/drain region 83 in the p-type region 50P, after the formation of the source/drain contacts 112. The epitaxial source/drain region 83 is separate from adjacent epitaxial source/drain regions. The region 118 shows the position of the top surface of the second capping layer 75 prior to the forming of openings for the source/drain contacts 112. The channel regions 58 are shown in ghost. In an embodiment, during the etching process to form the openings for the source/drain contacts 112 in the p-type region 50P, the epitaxial source/drain region 83 and the second capping layer 75 may be recessed by a tenth height H10, where the tenth height H10 is in a range from 5 nm to 25 nm. In an embodiment, a difference in height between a bottommost point of the silicide layer 76 and a topmost point of the channel region 58 is an eleventh height H11, where the eleventh height H11 may be in a range from 3 nm to 25 nm. In an embodiment, a twelfth height H12 of the epitaxial source/drain region 83 from a first point at the center of the topmost surface of recessed fin 52 to a second point on the bottom surface of the silicide layer 76 that is vertically above the first point is in a range from 20 nm to 45 nm. In an embodiment, the twelfth height H12 may be larger than 40 nm. In an embodiment, a seventh width W7 from a first point on a first outer sidewall of the second capping layer 75 to a second point on a second outer sidewall of the second capping layer 75 is in a range from 10 nm to 30 nm, where a bottommost point of the silicide layer 76 is at the same height as the first point and the second point. In an embodiment, an eighth width W8 between outermost points of the second capping layer 75 is in a range from 25 nm to 45 nm. In an embodiment, a first portion of the second capping layer 75 has a seventh thickness T7 that is in a range from 0.5 nm to 2 nm, where the first portion of the second capping layer 75 extends from a topmost point of the second capping layer 75 to an outermost point of the second capping layer. In an embodiment, a second portion of the second capping layer 75 has an eighth thickness T8 that may be up to 2 nm, where the second portion extends from a bottommost portion of the second capping layer 75 to an outermost point of the second capping layer 75. In an embodiment, the seventh thickness T7 is larger than the eighth thickness T8.

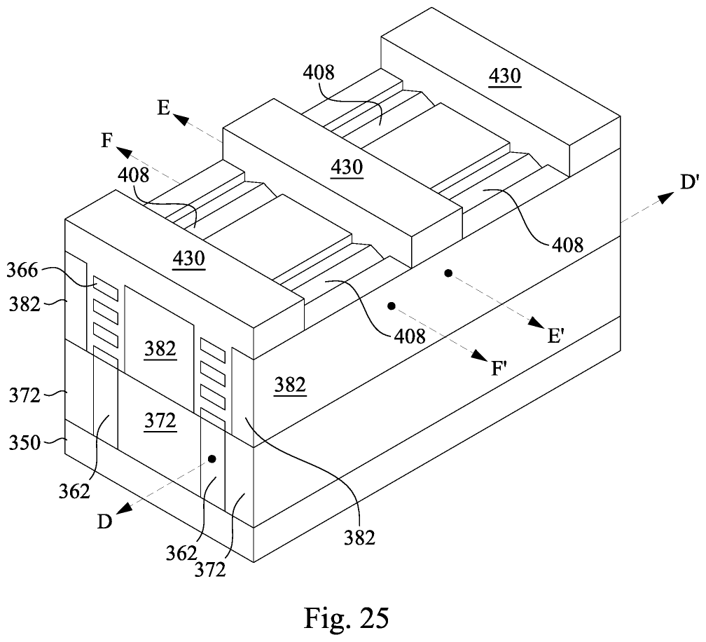

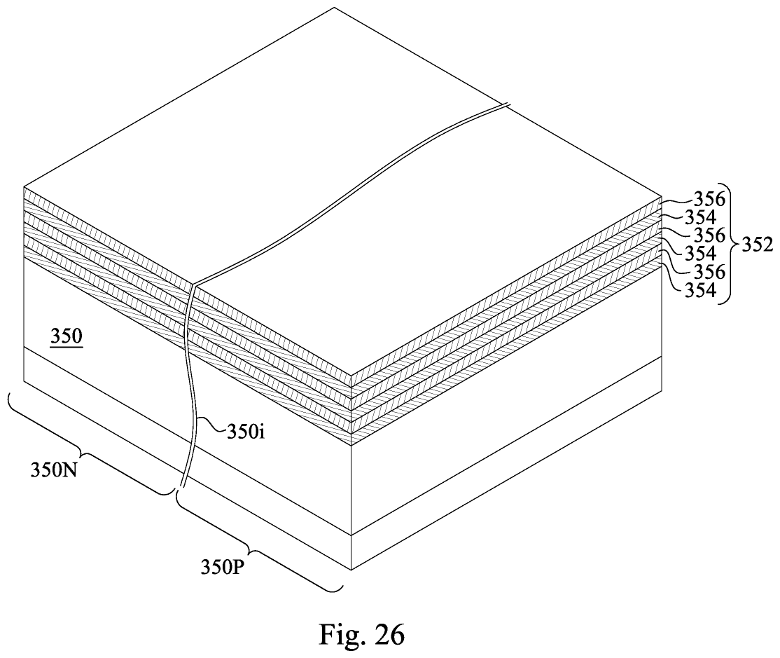

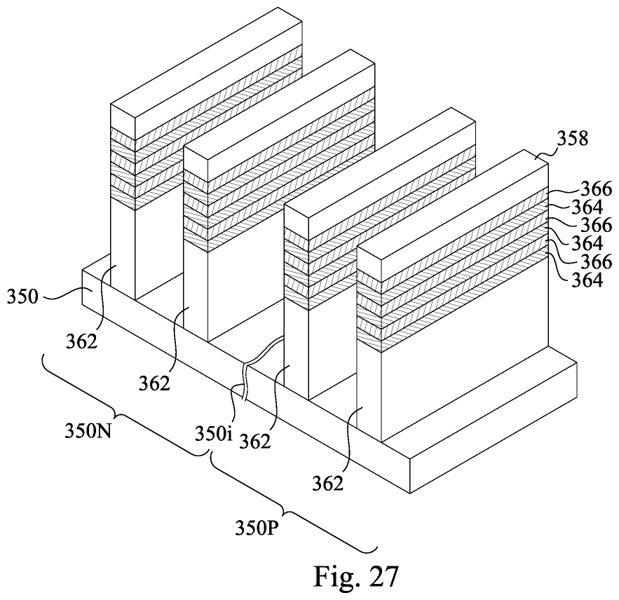

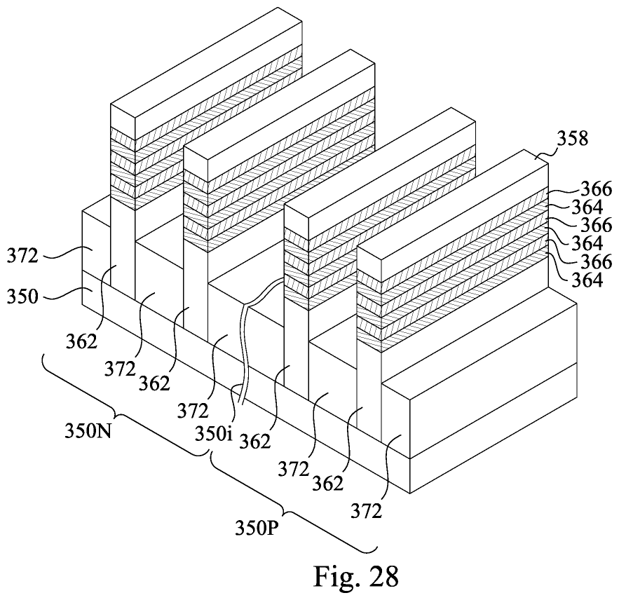

Various embodiments may also be applied to dies comprising other types of transistors (e.g., planar transistors, gate-all-around (GAA) transistors, or the like) in lieu of or in combination with the finFETs described above. For example, in FIGS. 25 through 47D, embodiments are described with respect to a specific context, namely, a die comprising nano-FETs, In some embodiments, p-type source/drain regions are epitaxially grown having boron-rich capping layers. Boron-rich capping layers allow for reducing or avoiding loss of the epitaxial material of the source/drain regions due to an etch process for forming openings for respective source/drain contacts, and allows for landing the source/drain contacts on high germanium (Ge) content regions of the respective source/drain regions. Various embodiments discussed herein allow for reducing the contact resistance of the source/drain contacts and enhancing the electrical performance of a resulting semiconductor device.

FIG. 25 illustrates an example of nano-FETs (e.g., nanowire FETs, nanosheet FETs, or the like), in accordance with some embodiments. FIG. 25 is a three-dimensional view, where some features of the nano-FETs are omitted for illustration clarity. The nano-FETs may be nanosheet field-effect transistors (NSFETs), nanowire field-effect transistors (NWFETs), gate-all-around field-effect transistors (GAAFETs), or the like.

The nano-FETs include nanostructures 366 (e.g., nanosheets, nanowires, or the like) over semiconductor fins 362 on a substrate 350 (e.g., a semiconductor substrate), with the nanostructures 366 acting as channel regions for the nano-FETs. The nanostructures 366 may include p-type nanostructures, n-type nanostructures, or a combination thereof. Isolation regions 372, such as shallow trench isolation (STI) regions, are disposed between adjacent semiconductor fins 362, which may protrude above and from between adjacent isolation regions 372. Although the isolation regions 372 are described/illustrated as being separate from the substrate 350, as used herein, the term “substrate” may refer to the semiconductor substrate alone or a combination of the semiconductor substrate and the isolation regions. Additionally, although the bottom portions of the semiconductor fins 362 are illustrated as being separate from the substrate 350, the bottom portions of the semiconductor fins 362 may be single, continuous materials with the substrate 350. In this context, the semiconductor fins 362 refer to the portion extending above and from between the adjacent isolation regions 372.

Gate structures 430 comprising gate dielectric layers and gate electrode layers (not individually illustrated) are over top surfaces of the semiconductor fins 362 and along top surfaces, sidewalls, and bottom surfaces of the nanostructures 366. Epitaxial source/drain regions 408 are disposed on the semiconductor fins 362 at opposing sides of the gate structures 430. The epitaxial source/drain regions 408 may be shared between various semiconductor fins 362. For example, adjacent epitaxial source/drain regions 408 may be electrically connected, such as through coupling the epitaxial source/drain regions 408 with a same source/drain contact.

Insulating fins 382, also referred to as hybrid fins or dielectric fins, are disposed over the isolation regions 372, and between adjacent epitaxial source/drain regions 408. The insulating fins 382 block epitaxial growth to prevent coalescing of some of the epitaxial source/drain regions 408 during epitaxial growth. For example, the insulating fins 382 may be formed at memory cell boundaries of a memory device to separate the epitaxial source/drain regions 408 of adjacent memory cells.

FIG. 25 further illustrates reference cross-sections that are used in later figures. Cross-section D-D′ is along a longitudinal axis of a semiconductor fin 362 and in a direction of, for example, a current flow between the epitaxial source/drain regions 408 of the nano-FET. Cross-section E-E′ is along a longitudinal axis of a gate structure 430 and in a direction, for example, perpendicular to a direction of current flow between the epitaxial source/drain regions 408 of a nano-FET. Cross-section F-F′ is parallel to cross-section E-E′ and extends through epitaxial source/drain regions 408 of the nano-FETs. Subsequent figures refer to these reference cross-sections for clarity.

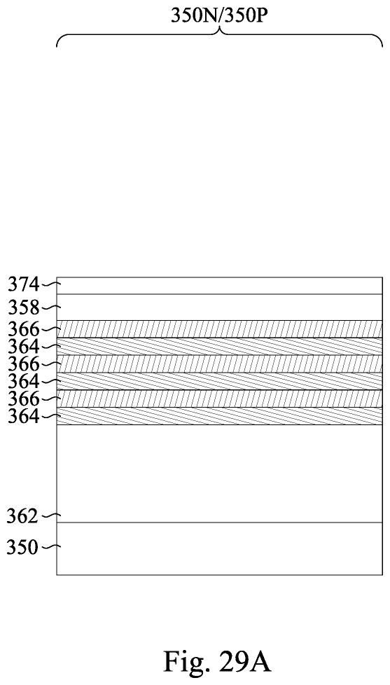

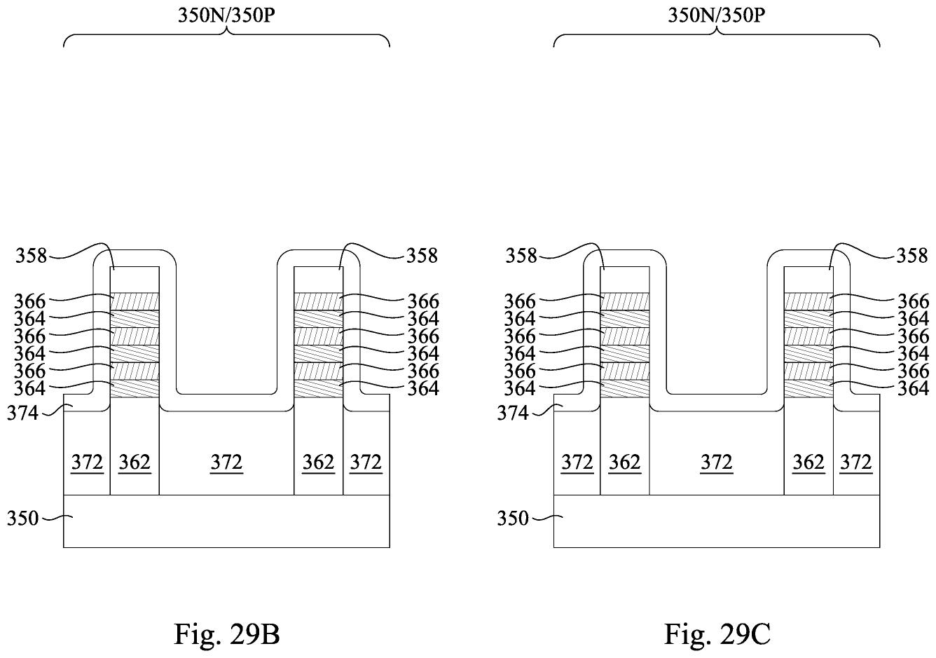

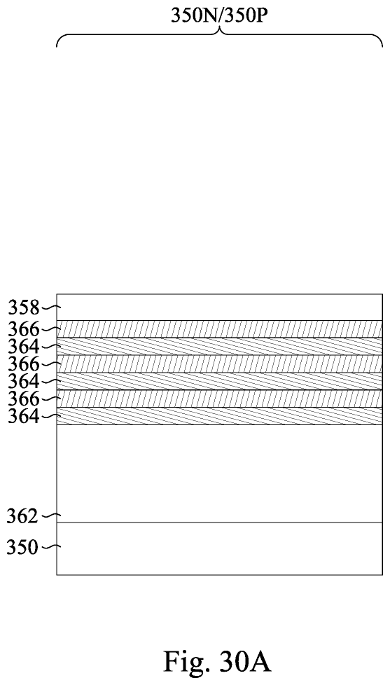

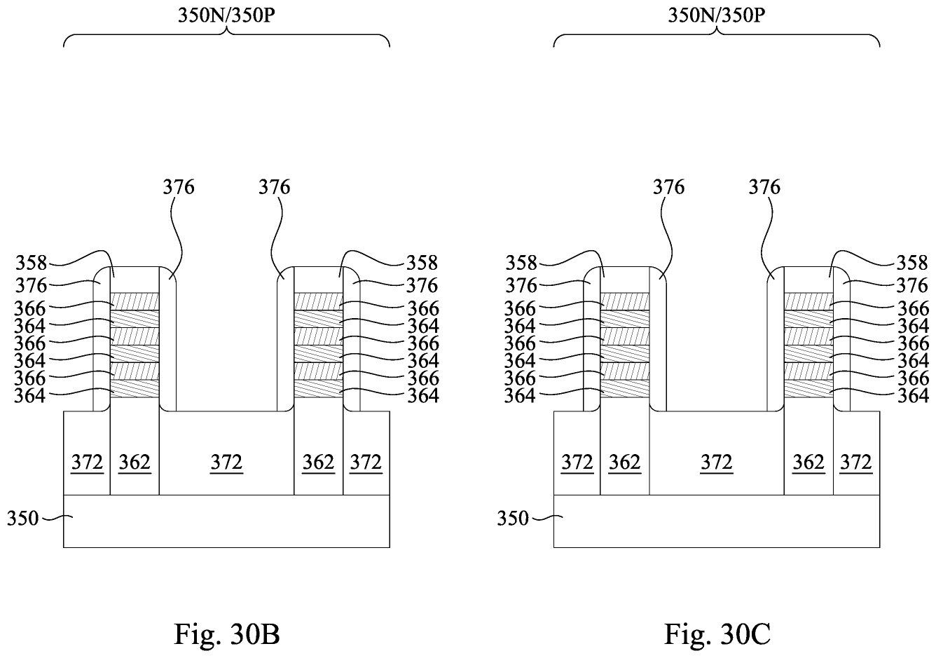

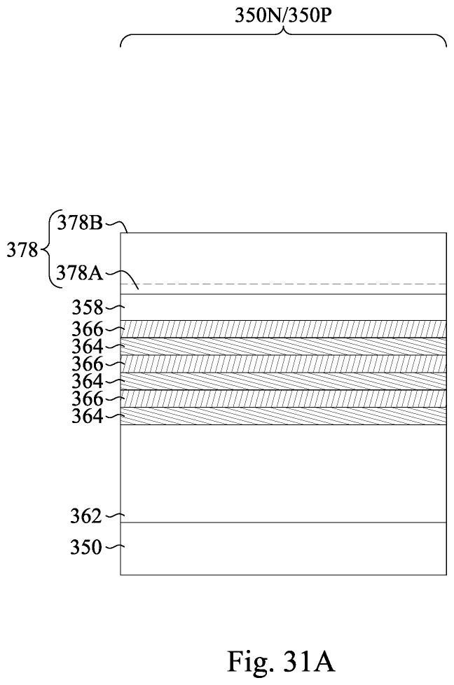

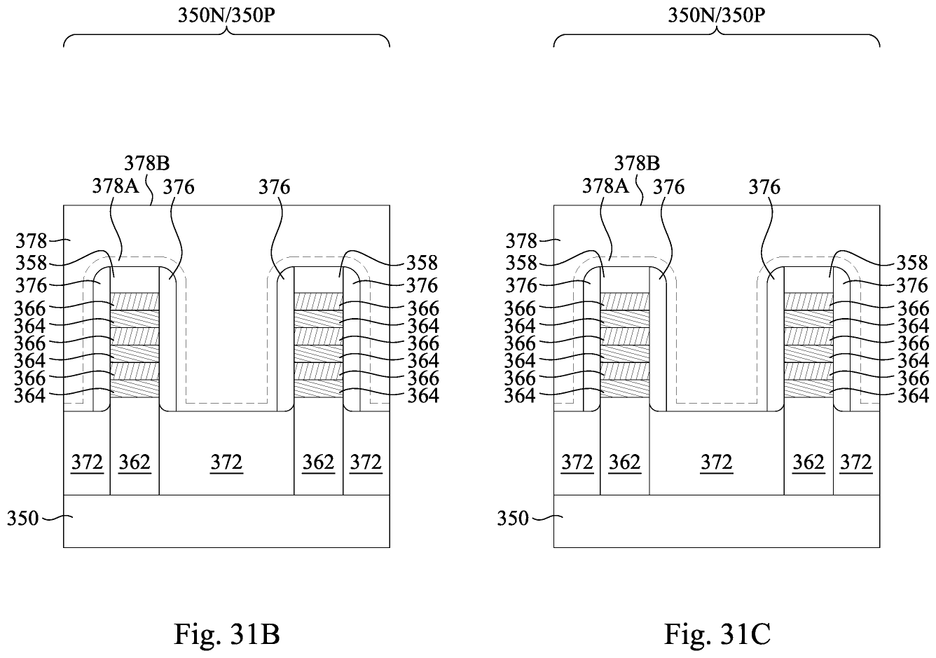

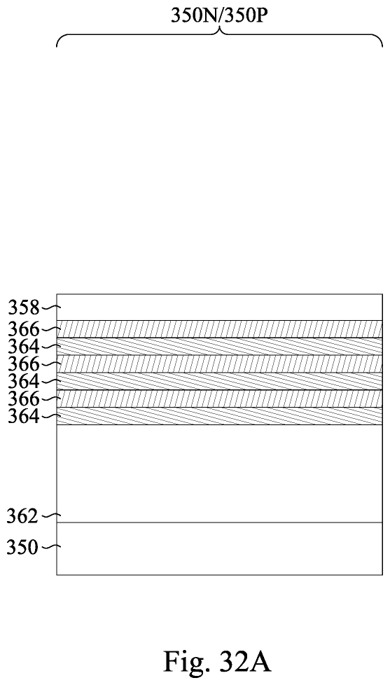

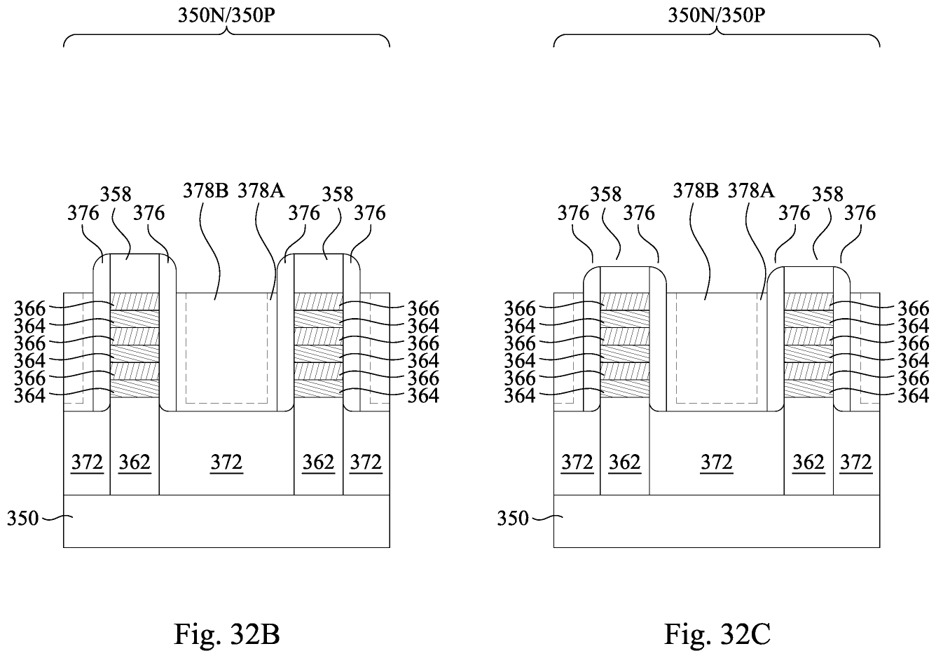

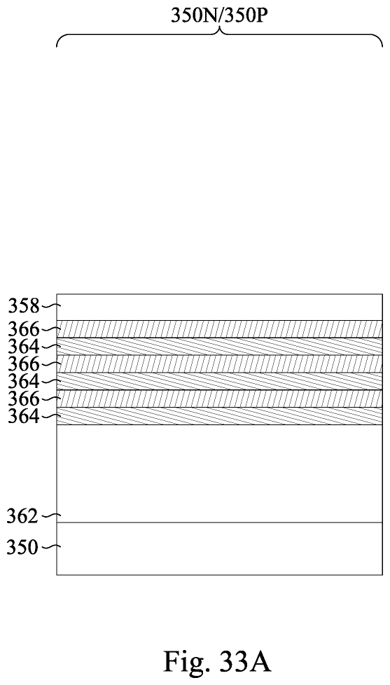

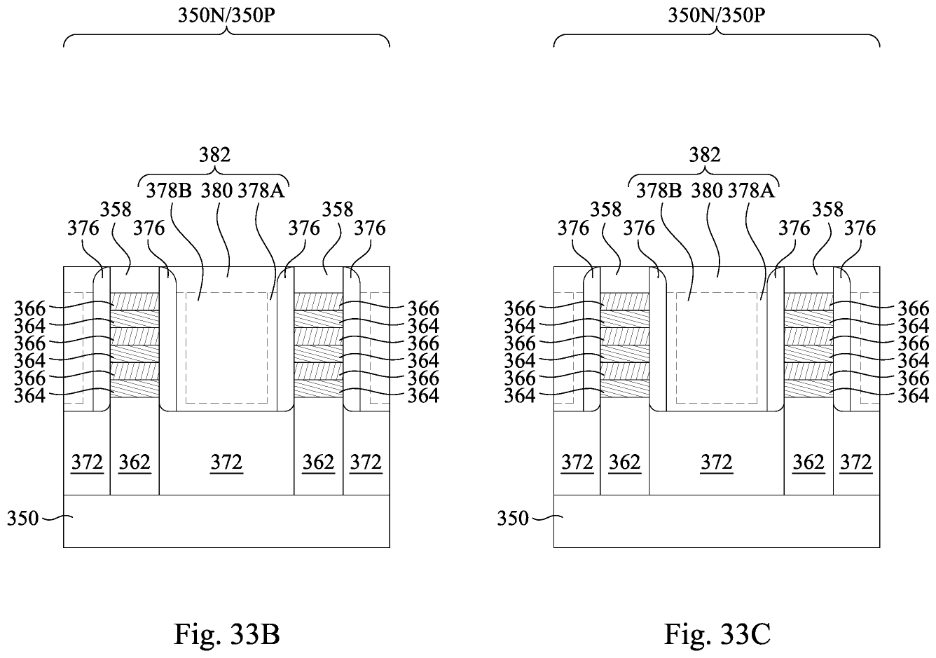

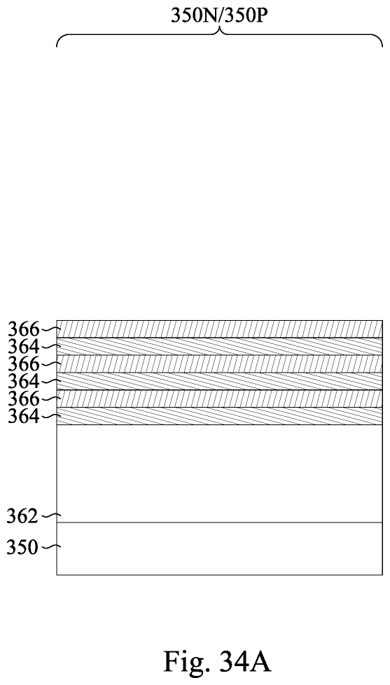

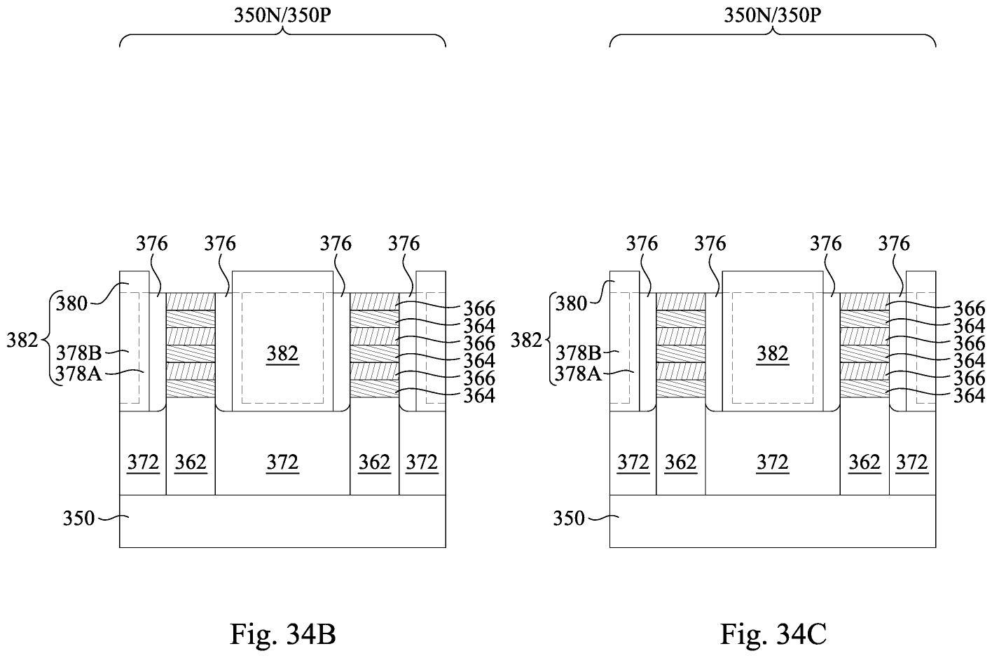

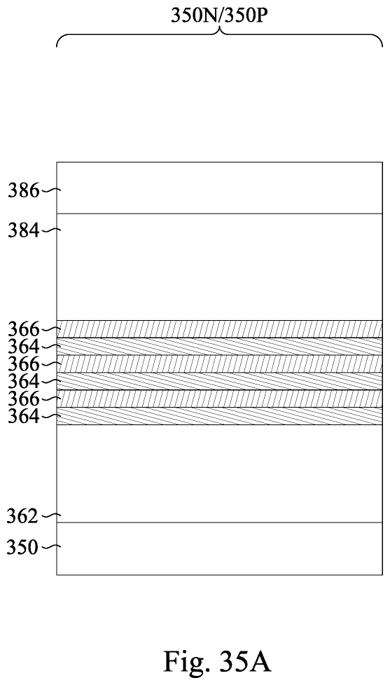

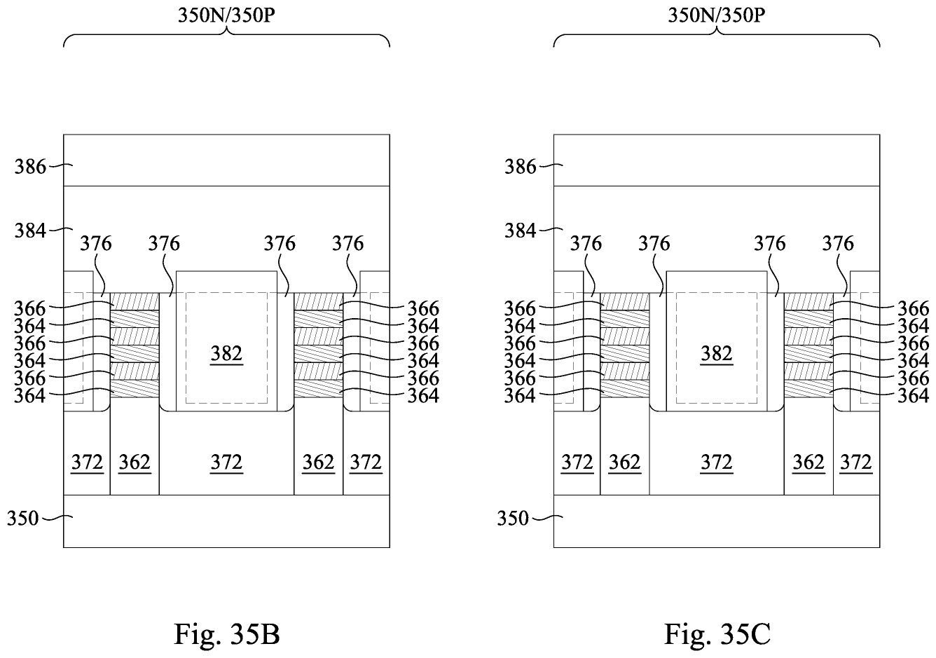

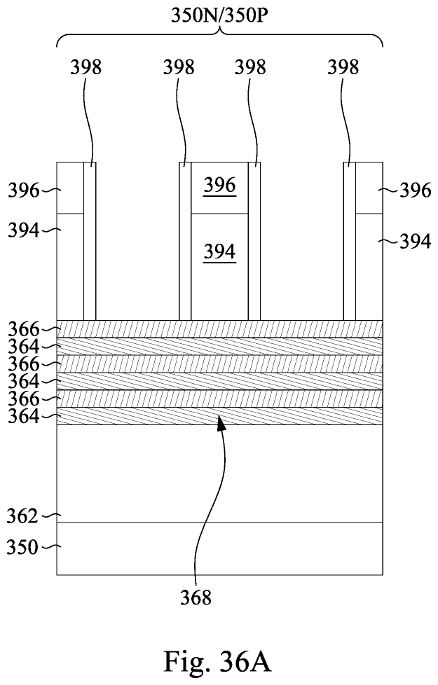

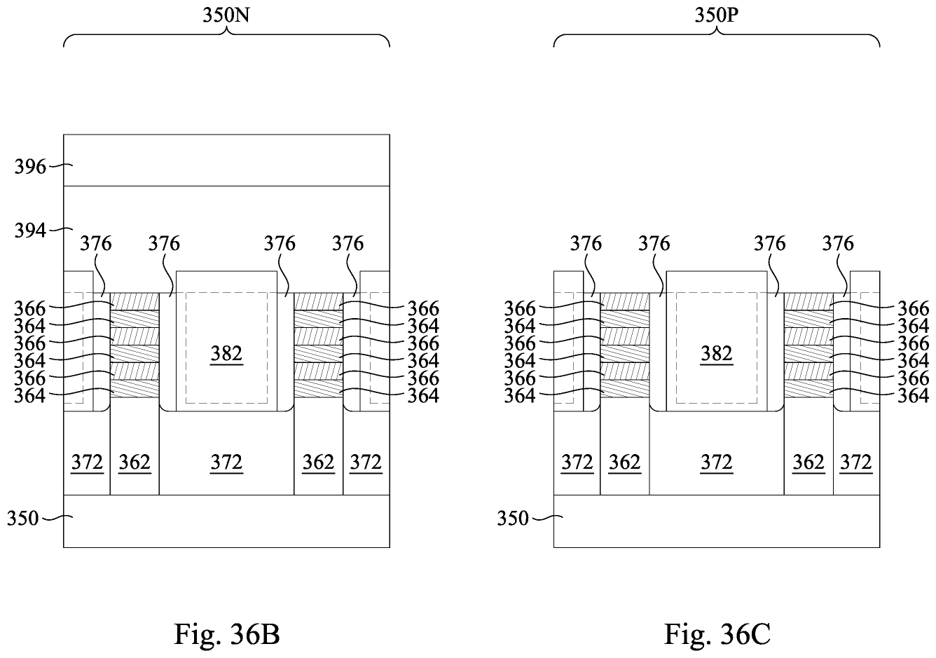

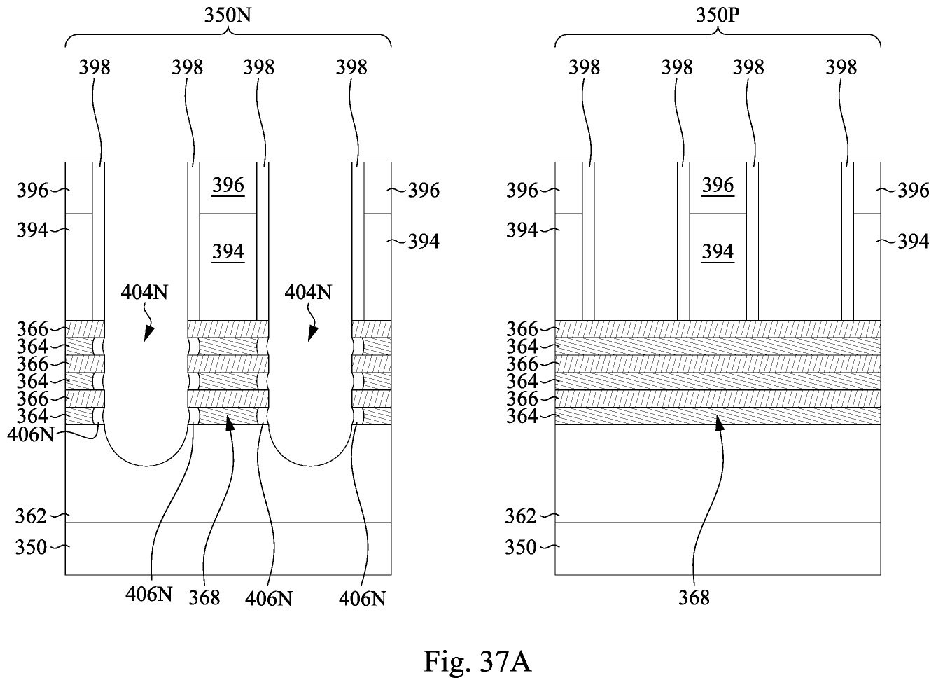

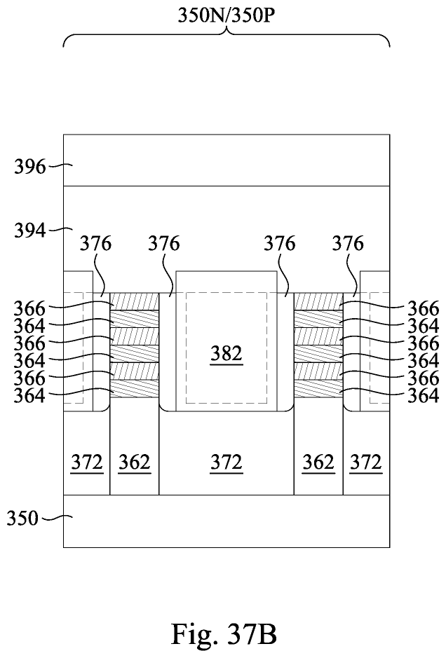

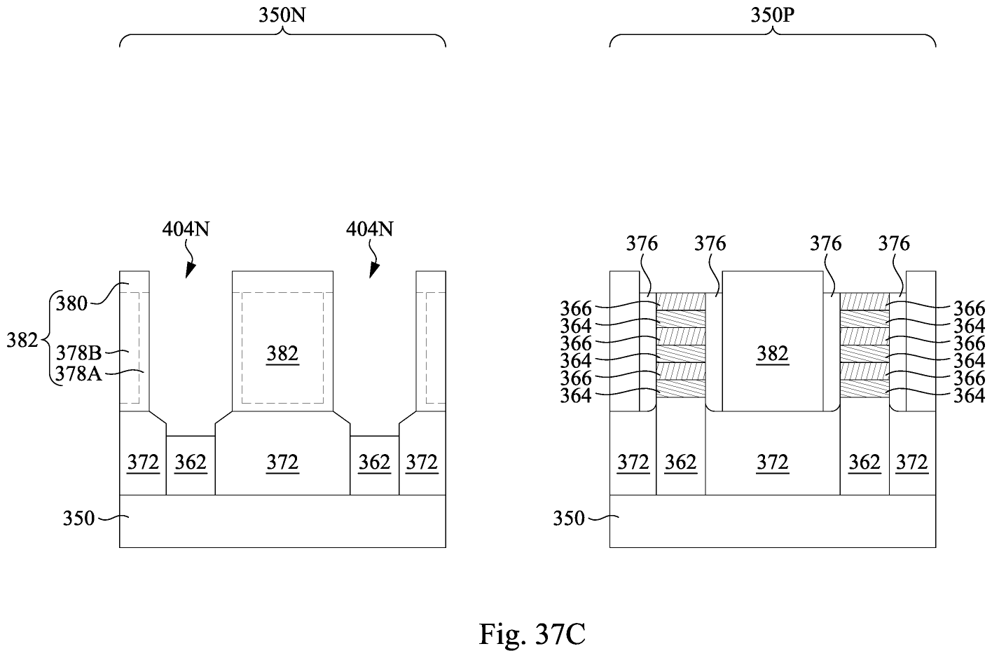

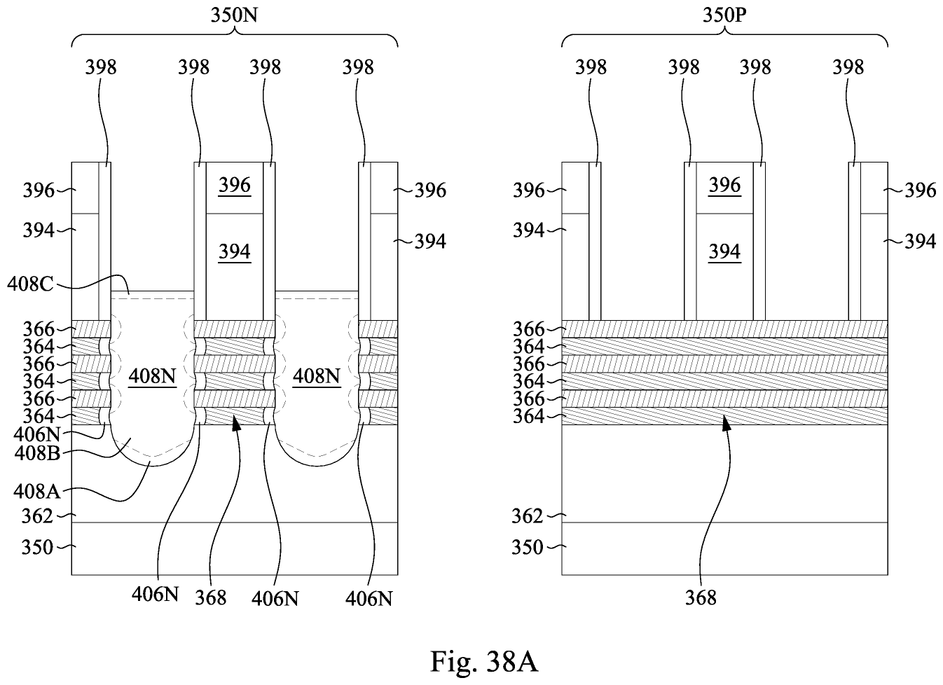

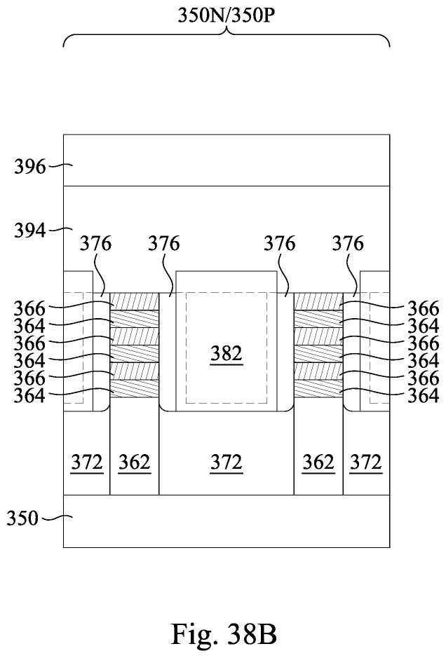

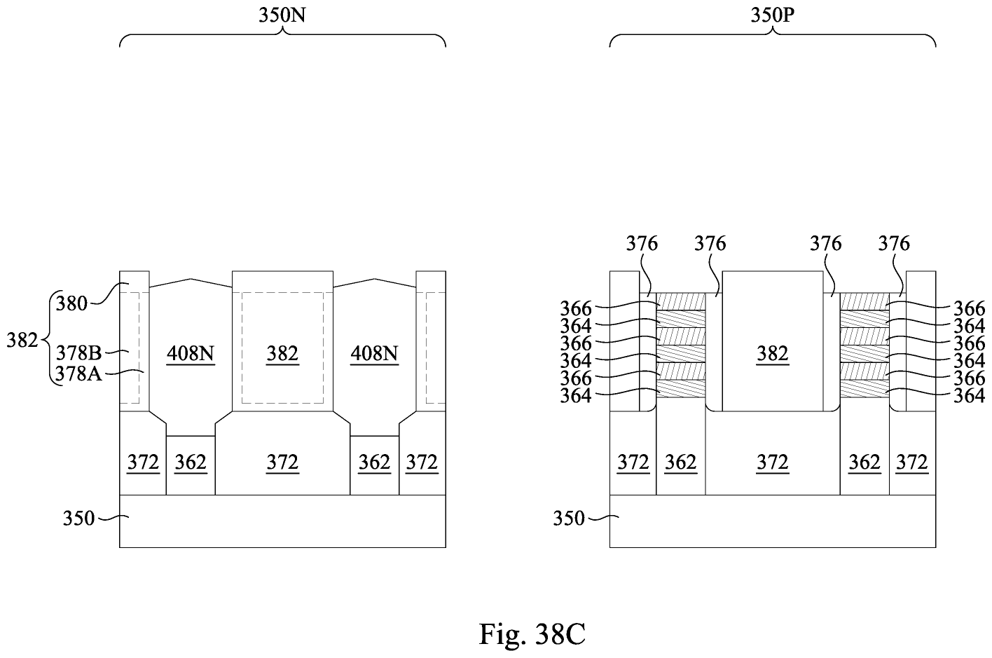

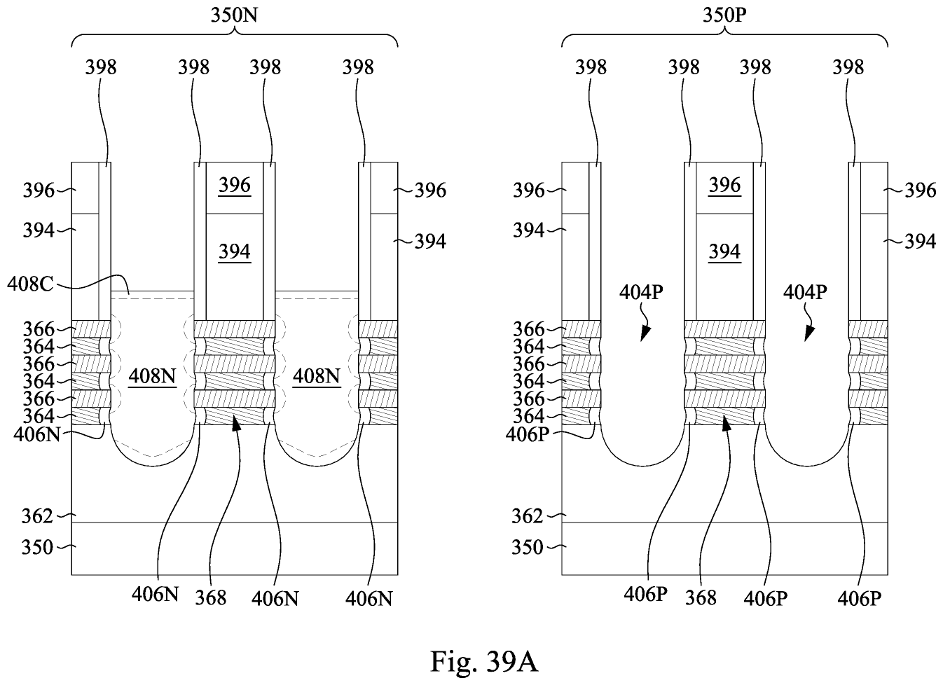

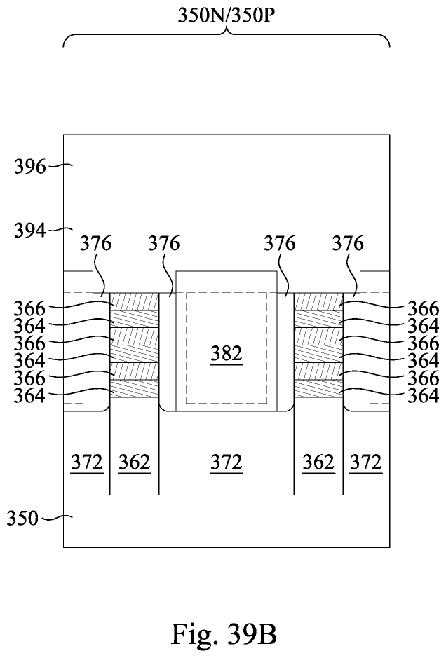

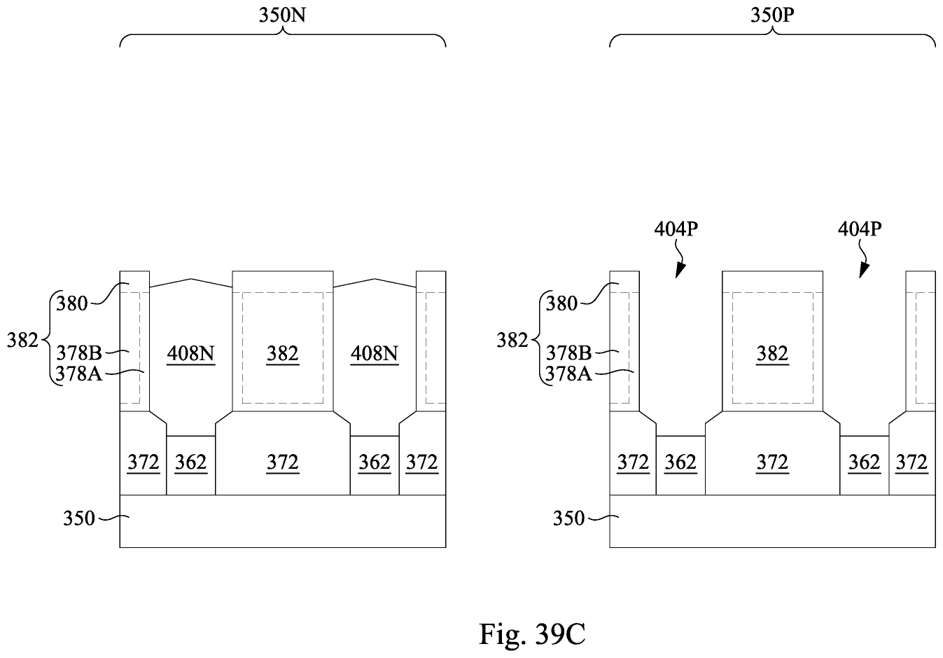

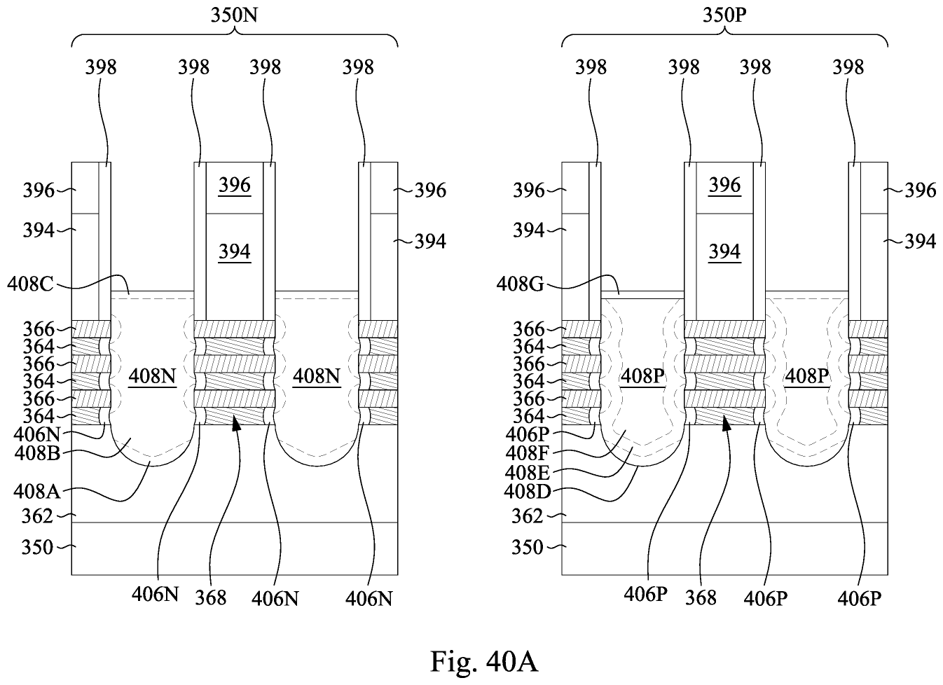

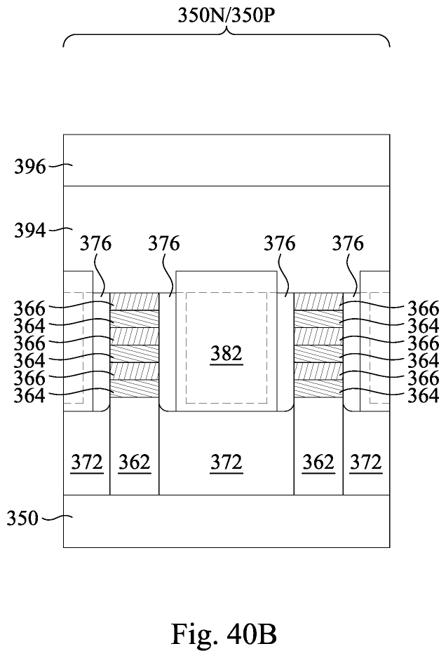

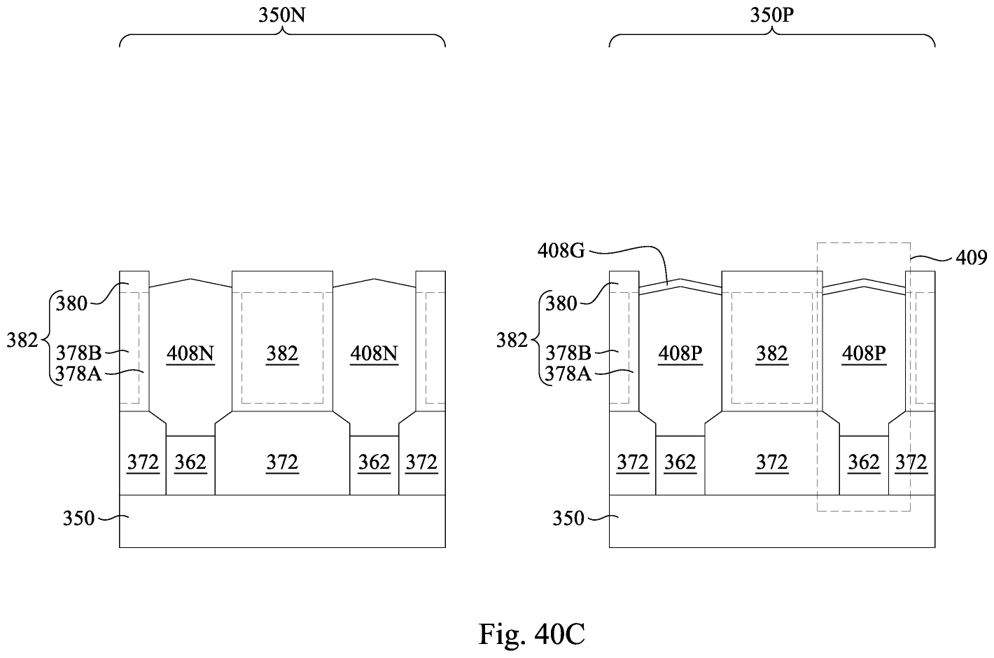

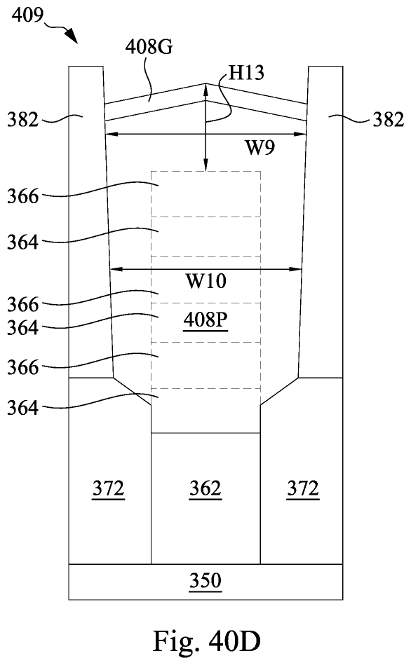

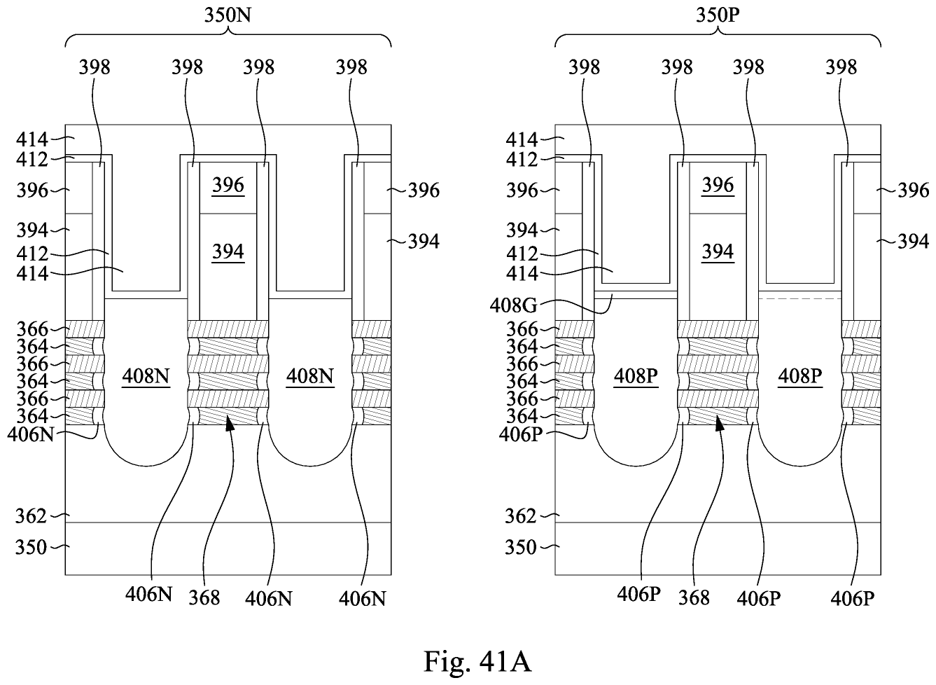

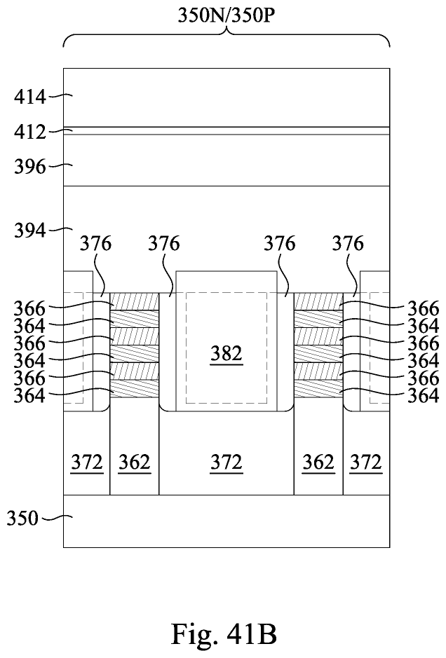

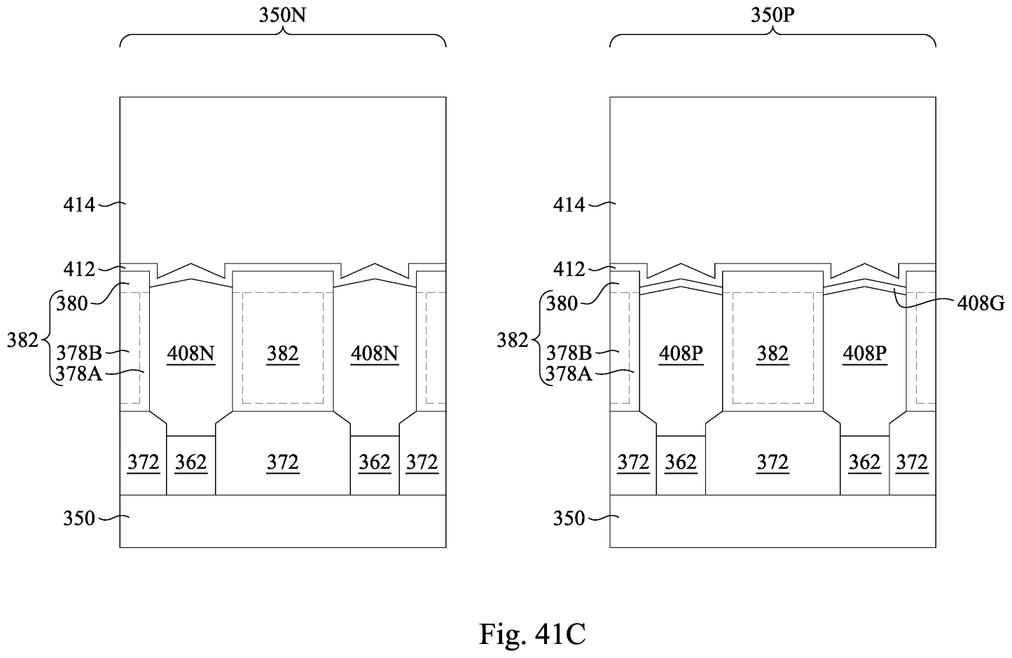

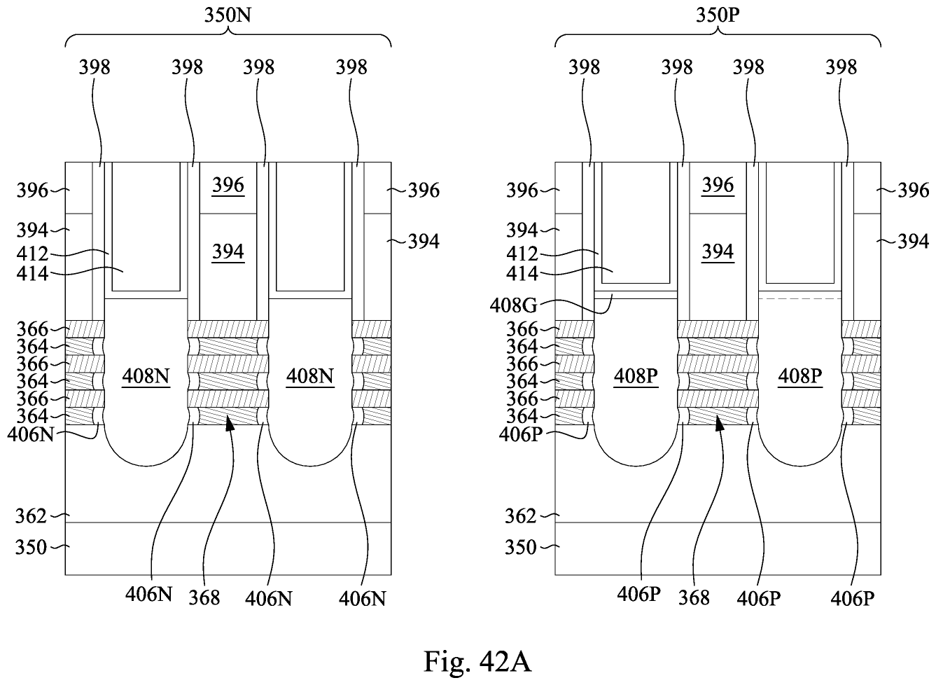

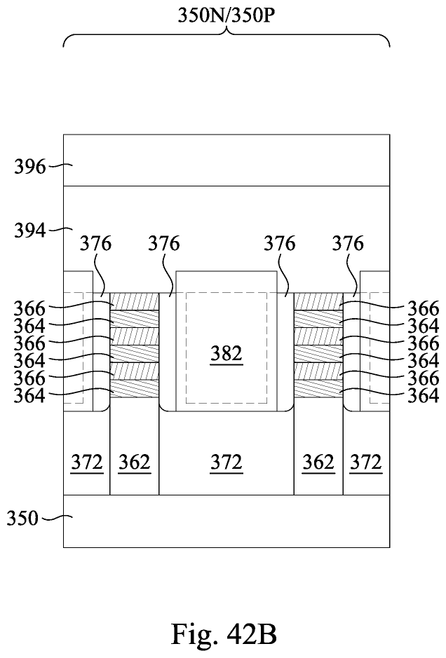

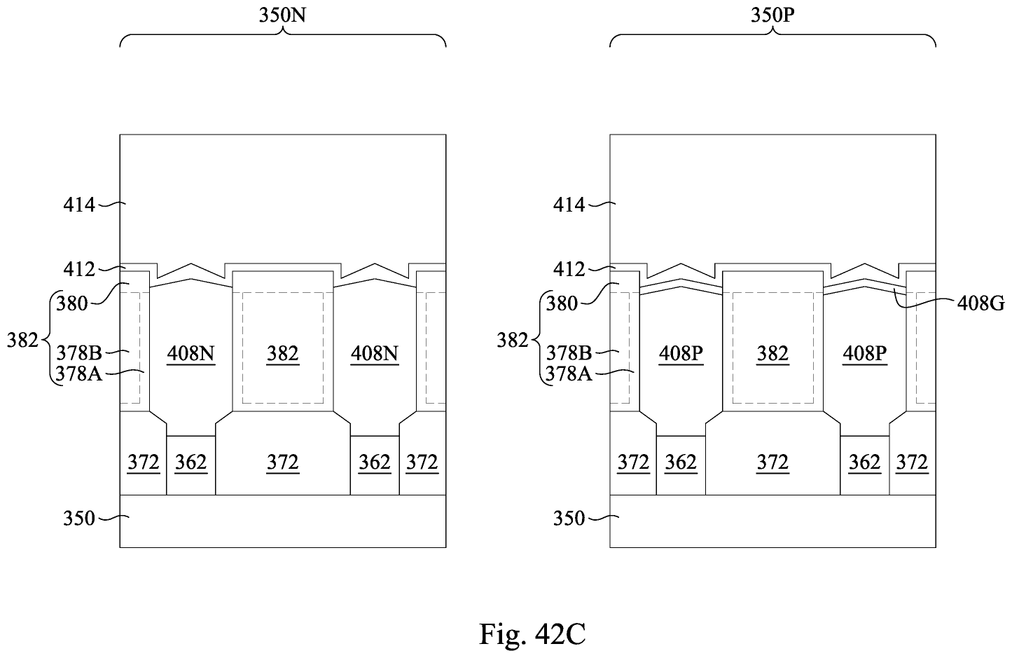

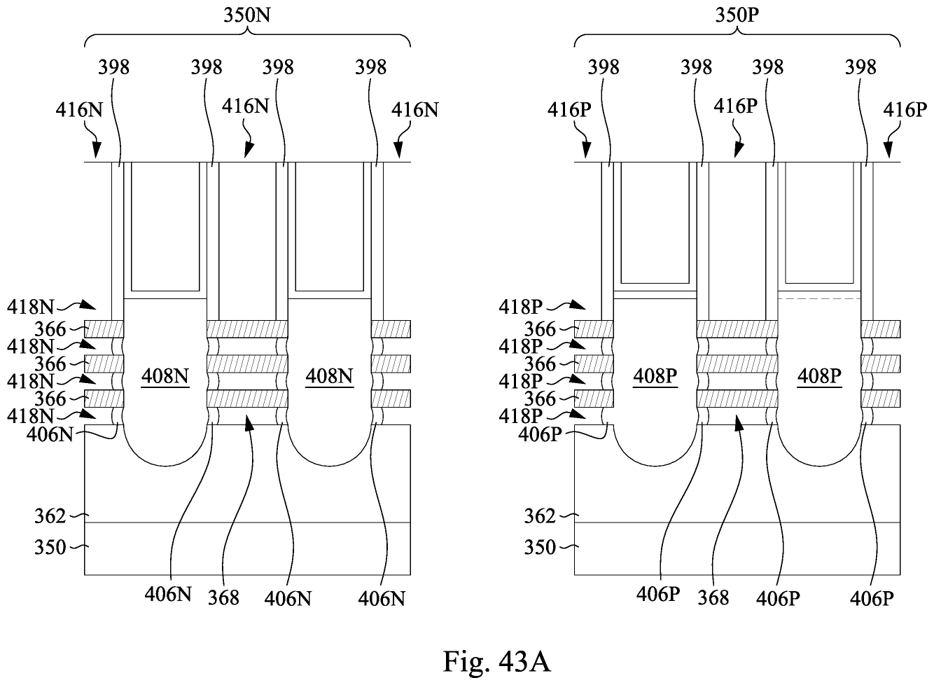

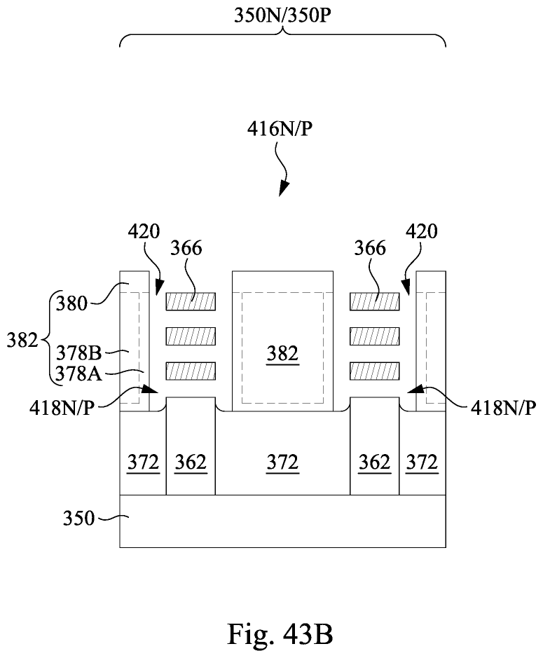

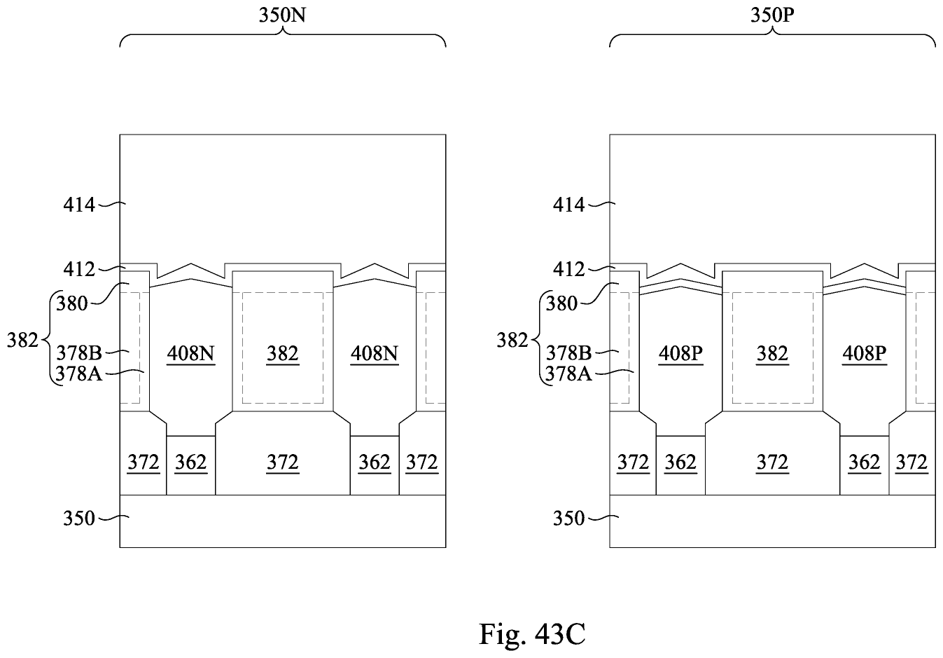

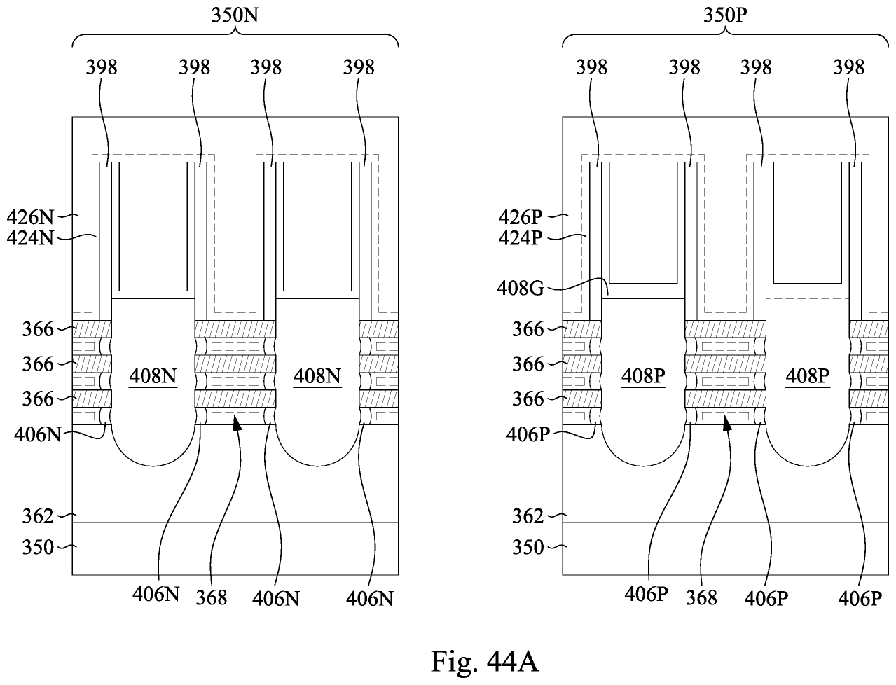

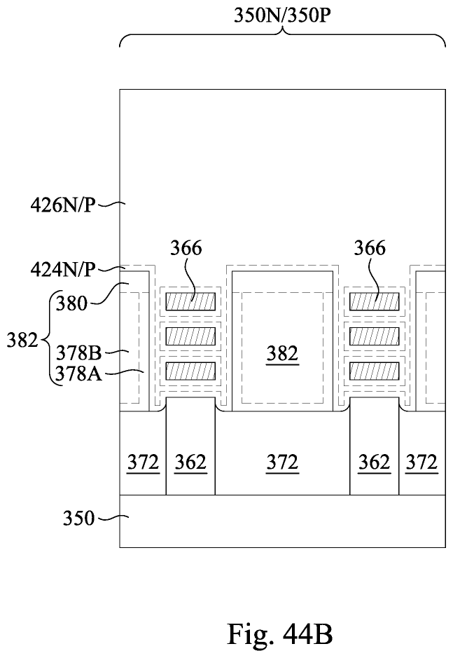

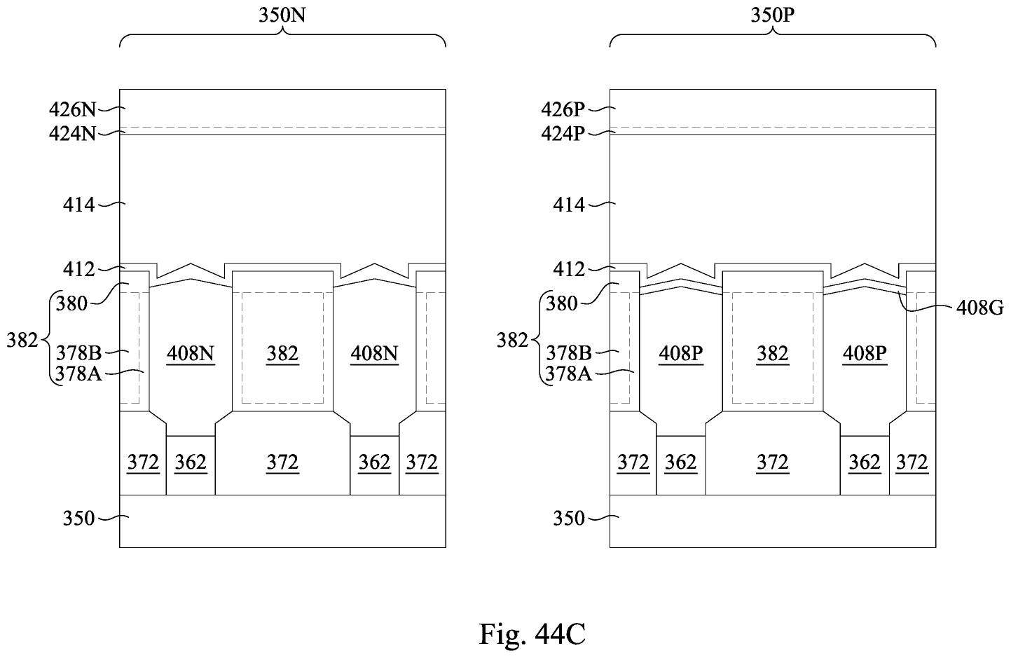

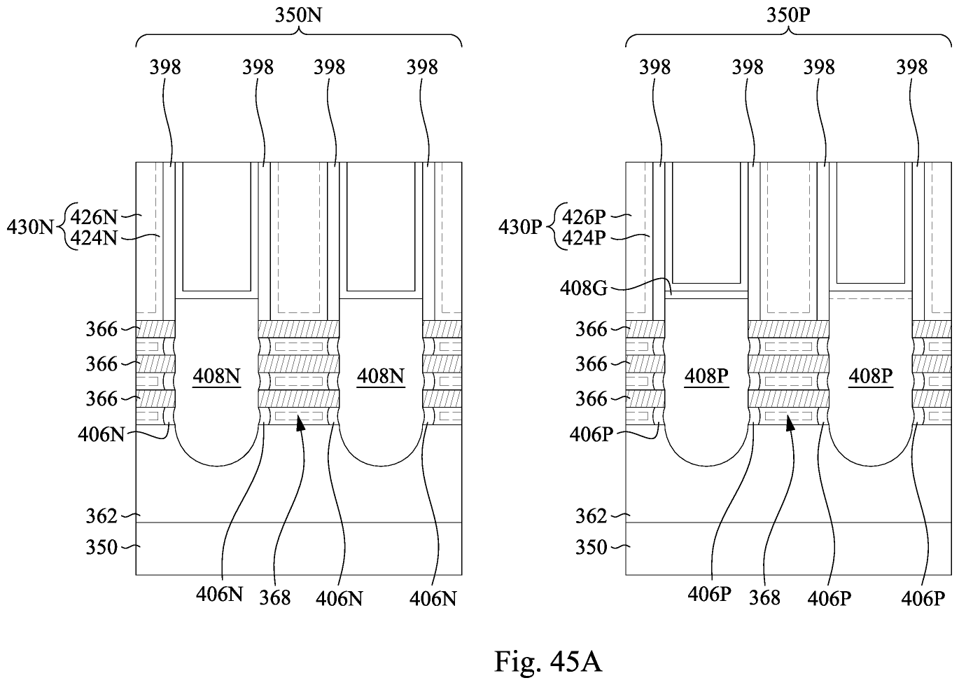

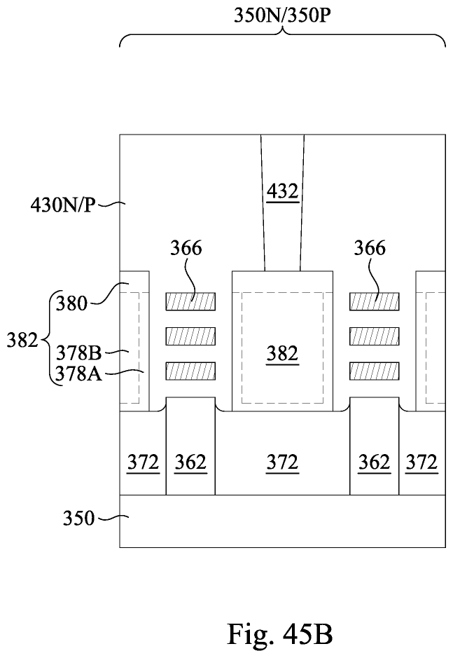

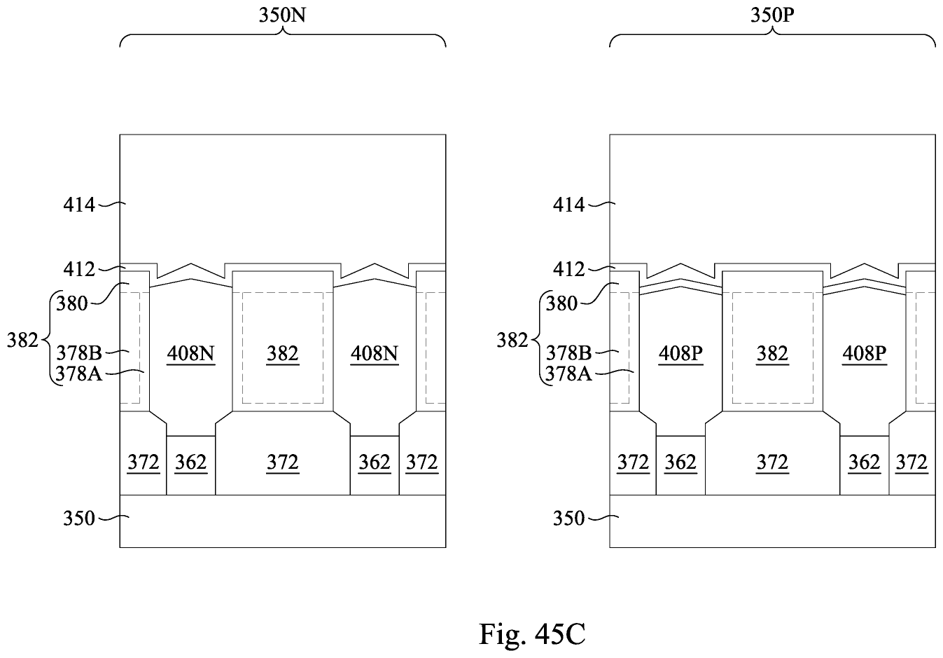

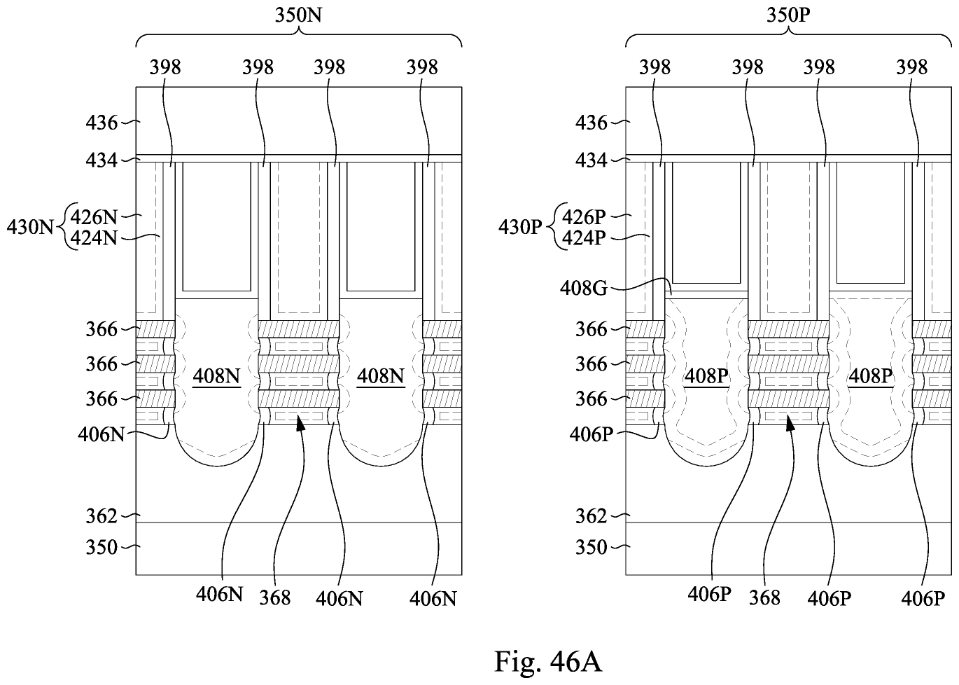

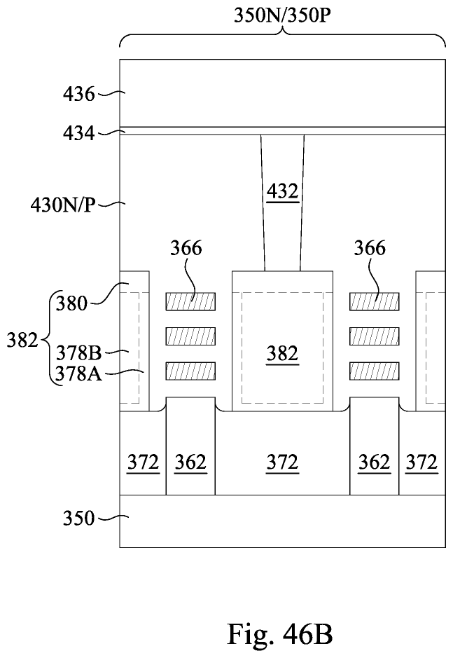

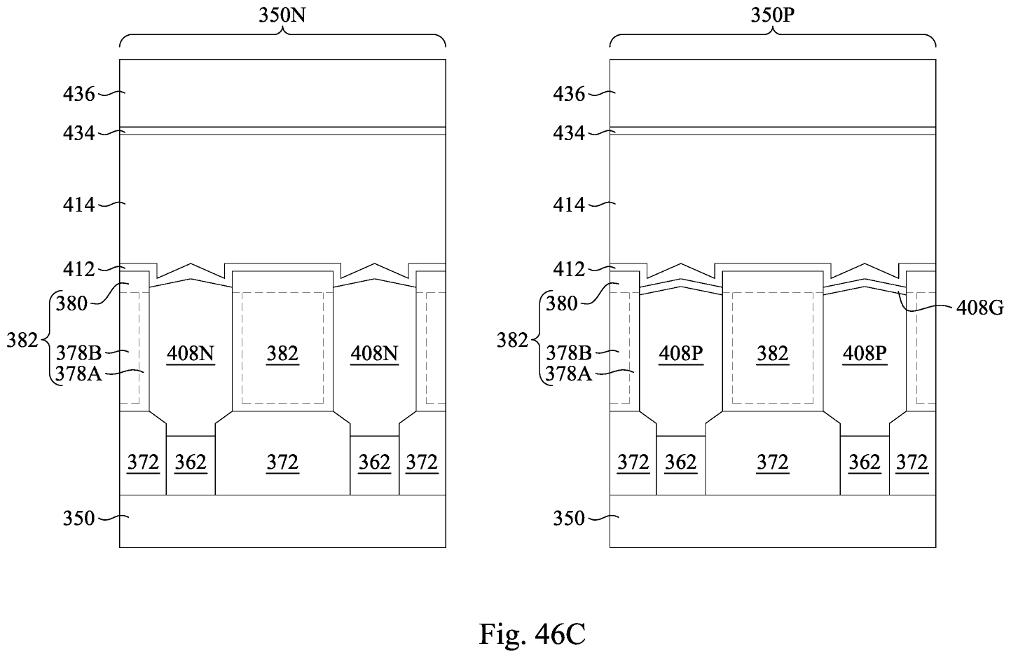

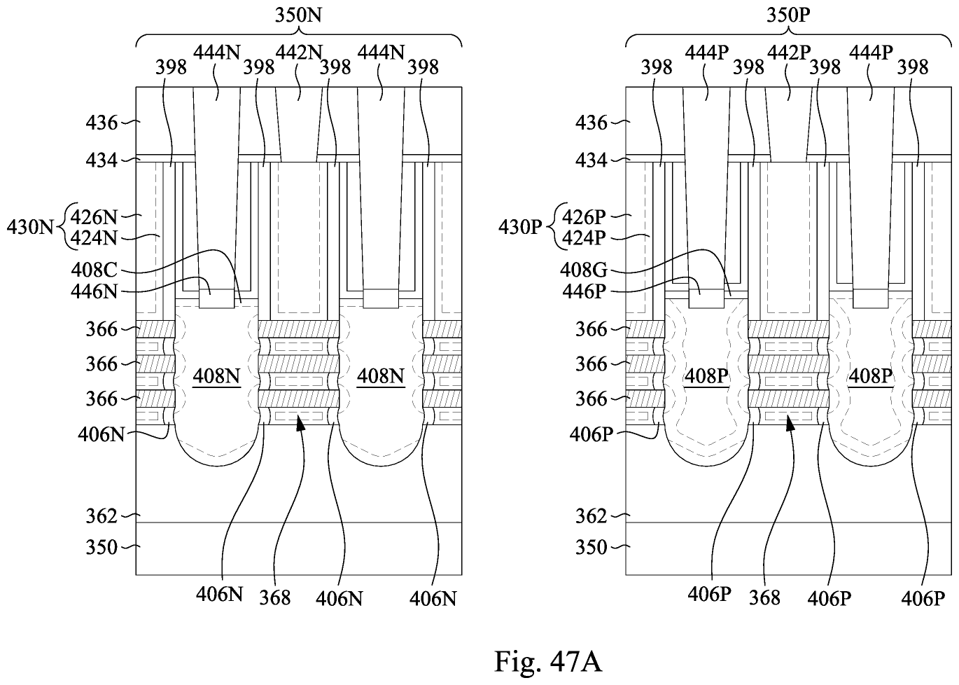

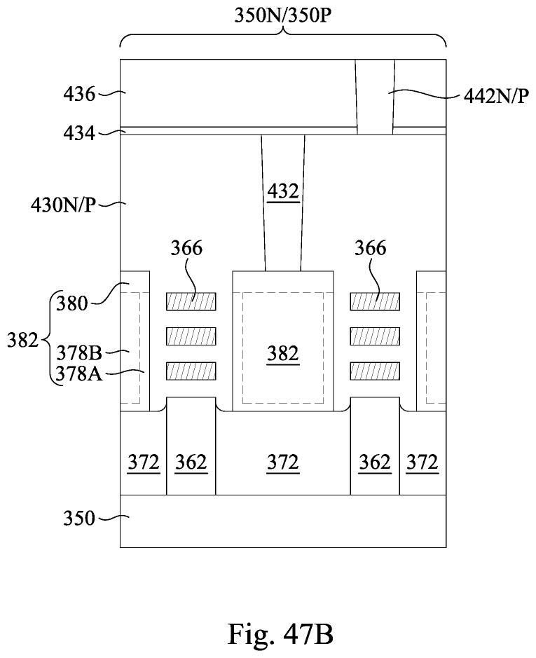

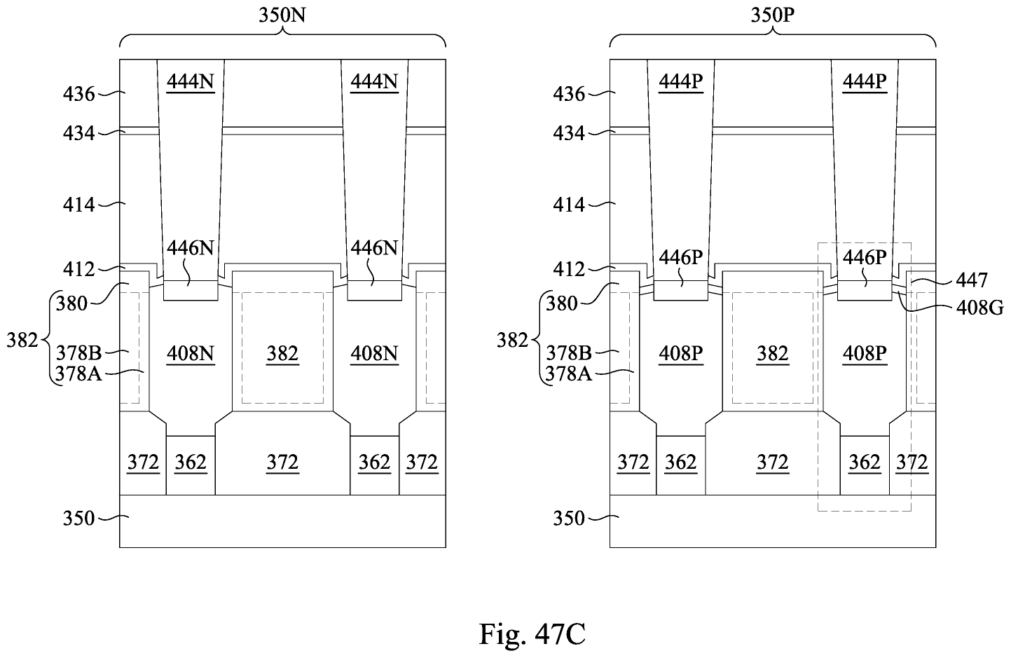

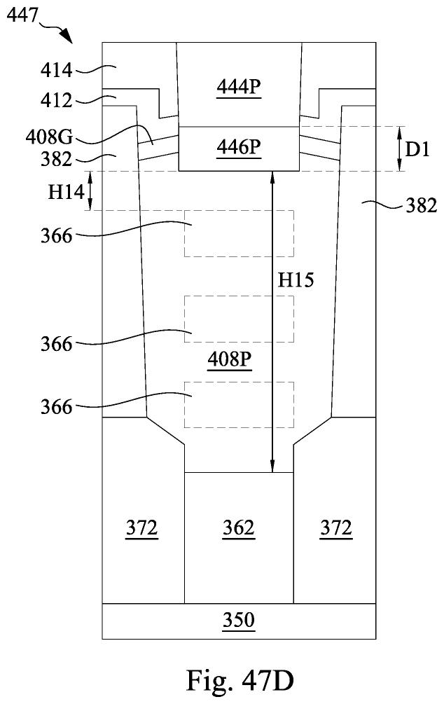

FIGS. 26, 27, 28, 29A-C, 30A-C, 31A-C, 32A-C, 33A-C, 34A-C, 35A-C, 36A-C, 37A-C, 38A-C, 39A-C, 40A-D, 41A-41C, 42A-C, 43A-C, 44A-C, 45A-C, 46A-C, and 47A-D are views of intermediate stages in the manufacturing of nano-FETs, in accordance with some embodiments. FIGS. 26, 27, and 28 are three-dimensional views. FIGS. 29A-47A are cross-sectional views illustrated along a similar cross-section as reference cross-section D-D′ in FIG. 25. FIGS. 29B-47B are cross-sectional views illustrated along a similar cross-section as reference cross-section E-E′ in FIG. 25. FIGS. 29C-47C, 40D, and 47D are cross-sectional views illustrated along a similar cross-section as reference cross-section F-F′ in FIG. 25.

In FIG. 26, a substrate 350 is provided for forming nano-FETs. The substrate 350 may be a semiconductor substrate, such as a bulk semiconductor, a semiconductor-on-insulator (SOI) substrate, or the like, which may be doped (e.g., with a p-type or an n-type impurity) or undoped. The substrate 350 may be a wafer, such as a silicon wafer. Generally, a SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 350 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like.

The substrate 350 has an n-type region 350N and a p-type region 350P. The n-type region 350N can be for forming n-type devices, such as NMOS transistors, e.g., n-type nano-FETs, and the p-type region 350P can be for forming p-type devices, such as PMOS transistors, e.g., p-type nano-FETs. The n-type region 350N may be physically separated from the p-type region 350P (as illustrated by a divider 350i), and any number of device features (e.g., other active devices, doped regions, isolation structures, etc.) may be disposed between the n-type region 350N and the p-type region 350P. Although one n-type region 350N and one p-type region 350P are illustrated, any number of n-type regions 350N and p-type regions 350P may be provided.

The substrate 350 may be lightly doped with a p-type or an n-type impurity. An anti-punch-through (APT) implantation may be performed on an upper portion of the substrate 350 to form an APT region. During the APT implantation, impurities may be implanted in the substrate 350. The impurities may have a conductivity type opposite from a conductivity type of source/drain regions that will be subsequently formed in each of the n-type region 350N and the p-type region 350P. The APT region may extend under the source/drain regions in the nano-FETs. The APT region may be used to reduce the leakage from the source/drain regions to the substrate 350. In some embodiments, the doping concentration in the APT region is in the range of 10¹⁸ cm⁻³ to 10¹⁹ cm⁻³.

A multi-layer stack 352 is formed over the substrate 350. The multi-layer stack 352 includes alternating first semiconductor layers 354 and second semiconductor layers 356. The first semiconductor layers 354 are formed of a first semiconductor material, and the second semiconductor layers 356 are formed of a second semiconductor material. The semiconductor materials may each be selected from the candidate semiconductor materials of the substrate 350. In the illustrated embodiment, the multi-layer stack 352 includes three layers of each of the first semiconductor layers 354 and the second semiconductor layers 356. It should be appreciated that the multi-layer stack 352 may include any number of the first semiconductor layers 354 and the second semiconductor layers 356. For example, the multi-layer stack 352 may include from one to ten layers of each of the first semiconductor layers 354 and the second semiconductor layers 356.

In the illustrated embodiment, and as will be subsequently described in greater detail, the first semiconductor layers 354 will be removed and the second semiconductor layers 356 will be patterned to form channel regions for the nano-FETs in both the n-type region 350N and the p-type region 350P. The first semiconductor layers 354 are sacrificial layers (or dummy layers), which will be removed in subsequent processing to expose the top surfaces and the bottom surfaces of the second semiconductor layers 356. The first semiconductor material of the first semiconductor layers 354 is a material that has a high etching selectivity from the etching of the second semiconductor layers 356, such as silicon germanium. The second semiconductor material of the second semiconductor layers 356 is a material suitable for both n-type and p-type devices, such as silicon. Each of the first semiconductor layers 354 may have a thickness in a range of 5 nm to 30 nm. Each of the second semiconductor layers 356 may have a thickness in a range of 5 nm to 30 nm.

In another embodiment (not separately illustrated), the first semiconductor layers 354 will be patterned to form channel regions for nano-FETs in one region (e.g., the p-type region 350P), and the second semiconductor layers 356 will be patterned to form channel regions for nano-FETs in another region (e.g., the n-type region 350N). The first semiconductor material of the first semiconductor layers 354 may be a material suitable for p-type devices, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 356 may be a material suitable for n-type devices, such as silicon, silicon carbide, a III-V compound semiconductor, a II-VI compound semiconductor, or the like. The first semiconductor material and the second semiconductor material may have a high etching selectivity from the etching of one another, so that the first semiconductor layers 354 may be removed without removing the second semiconductor layers 356 in the n-type region 350N, and the second semiconductor layers 356 may be removed without removing the first semiconductor layers 354 in the p-type region 350P.

In FIG. 27, trenches are patterned in the substrate 350 and the multi-layer stack 352 (see FIG. 26) to form semiconductor fins 362, nanostructures 364, and nanostructures 366. The semiconductor fins 362 are semiconductor strips patterned in the substrate 350. The nanostructures 364 and the nanostructures 366 include the remaining portions of the first semiconductor layers 354 and the second semiconductor layers 356, respectively. The trenches may be patterned by any acceptable etch process, such as a reactive ion etch (RIE), neutral beam etch (NBE), the like, or a combination thereof. The etching may be anisotropic.

The semiconductor fins 362 and the nanostructures 364, 366 may be patterned by any suitable method. For example, the semiconductor fins 362 and the nanostructures 364, 366 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as a mask 358 to pattern the semiconductor fins 362 and the nanostructures 364, 366.

In some embodiments, the semiconductor fins 362 and the nanostructures 364, 366 each have widths in a range of 8 nm to 40 nm. In the illustrated embodiment, the semiconductor fins 362 and the nanostructures 364, 366 have substantially equal widths in the n-type region 350N and the p-type region 350P. In another embodiment, the semiconductor fins 362 and the nanostructures 364, 366 in one region (e.g., the n-type region 350N) are wider or narrower than the semiconductor fins 362 and the nanostructures 364, 366 in another region (e.g., the p-type region 350P). Further, while each of the semiconductor fins 362 and the nanostructures 364, 366 are illustrated as having a consistent width throughout, in other embodiments, the semiconductor fins 362 and/or the nanostructures 364, 366 may have tapered sidewalls such that a width of each of the semiconductor fins 362 and/or the nanostructures 364, 366 continuously increases in a direction towards the substrate 350. In such embodiments, each of the nanostructures 364, 366 may have a different width and be trapezoidal in shape.

In FIG. 28, STI regions 372 are formed over the substrate 350 and between adjacent semiconductor fins 362. The STI regions 372 are disposed around at least a portion of the semiconductor fins 362 such that at least a portion of the nanostructures 364, 366 protrude from between adjacent STI regions 372. In the illustrated embodiment, the top surfaces of the STI regions 372 are below the top surfaces of the semiconductor fins 362. In some embodiments, the top surfaces of the STI regions 372 are above or coplanar (within process variations) with the top surfaces of the semiconductor fins 362.

The STI regions 372 may be formed by any suitable method. For example, an insulation material can be formed over the substrate 350 and the nanostructures 364, 366, and between adjacent semiconductor fins 362. The insulation material may be an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof. Other insulation materials formed by any acceptable process may be used. In some embodiments, the insulation material is silicon oxide formed by FCVD. An anneal process may be performed once the insulation material is formed. In an embodiment, the insulation material is formed such that excess insulation material covers the nanostructures 364, 366. Although the STI regions 372 are each illustrated as a single layer, some embodiments may utilize multiple layers. For example, in some embodiments a liner (not separately illustrated) may first be formed along surfaces of the substrate 350, the semiconductor fins 362, and the nanostructures 364, 366. Thereafter, an insulation material, such as those previously described may be formed over the liner.

A removal process is then applied to the insulation material to remove excess insulation material over the nanostructures 364, 366. In some embodiments, a planarization process such as a chemical mechanical polish (CMP), an etch-back process, combinations thereof, or the like may be utilized. In some embodiments, the planarization process may expose the mask 358 or remove the mask 358. After the planarization process, the top surfaces of the insulation material and the mask 358 or the nanostructures 364, 366 are coplanar (within process variations). Accordingly, the top surfaces of the mask 358 (if present) or the nanostructures 364, 366 are exposed through the insulation material. In the illustrated embodiment, the mask 358 remains on the nanostructures 364, 366. The insulation material is then recessed to form the STI regions 372. The insulation material is recessed such that at least a portion of the nanostructures 364, 366 protrude from between adjacent portions of the insulation material. Further, the top surfaces of the STI regions 372 may have a flat surface as illustrated, a convex surface, a concave surface (such as dishing), or a combination thereof by applying an appropriate etch. The insulation material may be recessed using any acceptable etching process, such as one that is selective to the material of the insulation material (e.g., selectively etches the insulation material of the STI regions 372 at a faster rate than the materials of the semiconductor fins 362 and the nanostructures 364, 366). For example, an oxide removal may be performed using dilute hydrofluoric (dHF) acid as an etchant.

The process previously described is just one example of how the semiconductor fins 362 and the nanostructures 364, 366 may be formed. In some embodiments, the semiconductor fins 362 and/or the nanostructures 364, 366 may be formed using a mask and an epitaxial growth process. For example, a dielectric layer can be formed over a top surface of the substrate 350, and trenches can be etched through the dielectric layer to expose the underlying substrate 350. Epitaxial structures can be epitaxially grown in the trenches, and the dielectric layer can be recessed such that the epitaxial structures protrude from the dielectric layer to form the semiconductor fins 362 and/or the nanostructures 364, 366. The epitaxial structures may include the alternating semiconductor materials previously described, such as the first semiconductor material and the second semiconductor material. In some embodiments where epitaxial structures are epitaxially grown, the epitaxially grown materials may be in situ doped during growth, which may obviate prior and/or subsequent implantations, although in situ and implantation doping may be used together.

Further, appropriate wells (not separately illustrated) may be formed in the nanostructures 364, 366, the semiconductor fins 362, and/or the substrate 350. The wells may have a conductivity type opposite from a conductivity type of source/drain regions that will be subsequently formed in each of the n-type region 350N and the p-type region 350P. In some embodiments, a p-type well is formed in the n-type region 350N, and an n-type well is formed in the p-type region 350P. In some embodiments, a p-type well or an n-type well is formed in both the n-type region 350N and the p-type region 350P.

In embodiments with different well types, different implant steps for the n-type region 350N and the p-type region 350P may be achieved using mask (not separately illustrated) such as a photoresist. For example, a photoresist may be formed over the semiconductor fins 362, the nanostructures 364, 366, and the STI regions 372 in the n-type region 350N. The photoresist is patterned to expose the p-type region 350P. The photoresist can be formed by using a spin-on technique and can be patterned using acceptable photolithography techniques. Once the photoresist is patterned, an n-type impurity implant is performed in the p-type region 350P, and the photoresist may act as a mask to substantially prevent n-type impurities from being implanted into the n-type region 350N. The n-type impurities may be phosphorus, arsenic, antimony, or the like implanted in the region to a concentration in the range of 10¹³ cm⁻³ to 10¹⁴ cm⁻³. After the implant, the photoresist may be removed, such as by any acceptable ashing process.

Following or prior to the implanting of the p-type region 350P, a mask (not separately illustrated) such as a photoresist is formed over the semiconductor fins 362, the nanostructures 364, 366, and the STI regions 372 in the p-type region 350P. The photoresist is patterned to expose the n-type region 350N. The photoresist can be formed by using a spin-on technique and can be patterned using acceptable photolithography techniques. Once the photoresist is patterned, a p-type impurity implant may be performed in the n-type region 350N, and the photoresist may act as a mask to substantially prevent p-type impurities from being implanted into the p-type region 350P. The p-type impurities may be boron, boron fluoride, indium, or the like implanted in the region to a concentration in the range of 10¹³ cm⁻³ to 10¹⁴ cm⁻³. After the implant, the photoresist may be removed, such as by any acceptable ashing process.

After implanting the n-type region 350N and the p-type region 350P, an anneal may be performed to repair implant damage and to activate the p-type and/or n-type impurities that were implanted. In some embodiments where epitaxial structures are epitaxially grown for the semiconductor fins 362 and/or the nanostructures 364, 366, the grown materials may be in situ doped during growth, which may obviate the implantations, although in situ and implantation doping may be used together.

FIGS. 29A-C, 30A-C, 31A-C, 32A-C, 33A-C, 34A-C, 35A-C, 36A-C, 37A-C, 38A-C, 39A-C, 40A-D, 41A-C, 42A-C, 43A-C, 44A-C, 45A-C, 46A-C, and 47A-D illustrate various additional steps in the manufacturing of embodiment devices. FIGS. 29A-C, 30A-C, 31A-C, 32A-C, 33A-C, 34A-C, 35A-C and 37B-47B illustrate features in either of the n-type region 350N and the p-type region 350P. For example, the structures illustrated may be applicable to both the n-type region 350N and the p-type region 350P. Differences (if any) in the structures of the n-type region 350N and the p-type region 350P are described in the text accompanying each figure. FIGS. 37A-47A and 37C-47C illustrate features in both the n-type region 350N and the p-type region 350P. FIGS. 40D and 47D illustrate features in the p-type region 350P.

As will be subsequently described in greater detail, insulating fins 382 will be formed between the semiconductor fins 362. FIGS. 29A-47A illustrate a semiconductor fin 362 and structures formed on it. FIGS. 29B-47B and 29C-47C each illustrate two semiconductor fins 362 and portions of the insulating fins 382 and the STI regions 372 that are disposed between the two semiconductor fins 362 in the respective cross-sections.

In FIGS. 29A-C, a sacrificial layer 374 is conformally formed over the mask 358, the semiconductor fins 362, the nanostructures 364, 366, and the STI regions 372. The sacrificial layer 374 may be formed of a semiconductor material (such as one selected from the candidate semiconductor materials of the substrate 350), which may be grown by a process such as vapor phase epitaxy (VPE) or molecular beam epitaxy (MBE), deposited by a process such as chemical vapor deposition (CVD) or atomic layer deposition (ALD), or the like. For example, the sacrificial layer 374 may be formed of silicon or silicon germanium.

In FIGS. 30A-C, the sacrificial layer 374 is patterned to form sacrificial spacers 376 using an etching process, such as a dry etch, a wet etch, or a combination thereof. The etching process may be anisotropic. As a result of the etching process, the portions of the sacrificial layer 374 over the mask 358 and the nanostructures 364, 366 are removed, and the STI regions 372 between the nanostructures 364, 366 are partially exposed. The sacrificial spacers 376 are disposed over the STI regions 372 and are further disposed on the sidewalls of the mask 358, the semiconductor fins 362, and the nanostructures 364, 366.

In subsequent process steps, a dummy gate layer 384 may be deposited over portions of the sacrificial spacers 376 (see below, FIGS. 35A-C), and the dummy gate layer 384 may be patterned to provide dummy gates 394 (see below, FIGS. 36A-C). These dummy gates 394 (e.g., patterned portions of the dummy gate layer 384) and the sacrificial spacers 376 may then be replaced with a functional gate stack. Specifically, the sacrificial spacers 376 are used as temporary spacers during processing to delineate boundaries of insulating fins, and the sacrificial spacers 376 and the nanostructures 364 will be subsequently removed and replaced with gate structures that are wrapped around the nanostructures 366. The sacrificial spacers 376 are formed of a material that has a high etching selectivity from the etching of the material of the nanostructures 366. For example, the sacrificial spacers 376 may be formed of the same semiconductor material as the nanostructures 364 so that the sacrificial spacers 376 and the nanostructures 364 may be removed in a single process step. Alternatively, the sacrificial spacers 376 and the nanostructures 364 may be formed of different materials.

FIGS. 31A-C, 32A-C, and 33A-C illustrate a formation of insulating fins 382 (also referred to as hybrid fins or dielectric fins) between the sacrificial spacers 376 adjacent to the semiconductor fins 362 and nanostructures 364, 366. The insulating fins 382 may insulate and physically separate subsequently formed source/drain regions (see below, FIGS. 40A-C) from each other.

In FIGS. 31A-C, a liner 378A and a fill material 378B are formed over the structure. The liner 378A is conformally deposited over exposed surfaces of the STI regions 72, the masks 358, the semiconductor fins 362, the nanostructures 364, 366, and the sacrificial spacers 376 by an acceptable deposition process such as ALD, CVD, physical vapor deposition (PVD), or the like. The liner 378A may be formed of one or more dielectric material(s) having a high etching selectivity from the etching of the semiconductor fins 362, the nanostructures 364, 366, and the sacrificial spacers 376, e.g. a nitride such as silicon nitride, silicon carbonitride, silicon oxycarbonitride, or the like. The liner 378A may reduce oxidation of the sacrificial spacers 376 during the subsequent formation of the fill material 378B, which may be useful for a subsequent removal of the sacrificial spacers 376.

Next, a fill material 378B is formed over the liner 378A, filling the remaining area between the semiconductor fins 362 and the nanostructures 364, 366 that is not filled by the sacrificial spacers 376 or the liner 378A. The fill material 378B may form the bulk of the lower portions of the insulating fins 382 (see FIGS. 33A-C) to insulate subsequently formed source/drain regions (see FIG. 40C) from each other. The fill material 378B may be formed by an acceptable deposition process such as ALD, CVD, PVD, or the like. The fill material 378B may be formed of one or more dielectric material(s) having a high etching selectivity from the etching of the semiconductor fins 362, the nanostructures 364, 366, the sacrificial spacers 376, and the liner 378A, e.g. an oxide such as silicon oxide, silicon oxynitride, silicon oxycarbonitride, silicon oxycarbide, the like, or combinations thereof.

In FIGS. 32A-C, upper portions of the liner 378A and the fill material 378B above top surfaces of the masks 358 may be removed using one or more acceptable planarization and/or etching processes. The etching process may be selective to the liner 378A and to the fill material 378B (e.g., selectively etches the liner 378A and the fill material 378B at a faster rate than the sacrificial spacers 376 and/or the mask 358). After etching, top surfaces of the liner 378A and the fill material 378B may be below top surfaces of the mask 358. In other embodiments, the fill material 378 may be recessed below top surfaces of the mask 358 while the liner 378A is maintained at a same level as the mask 358.

FIGS. 33A-C illustrate the forming of a dielectric capping layer 380 on the liner 378A and the fill material 378B, thereby forming the insulating fins 382. The dielectric capping layer 380 may fill a remaining area over the liner 378A, over the fill material 378B, and between sidewalls of the mask 358. The dielectric capping layer 380 may be formed by an acceptable deposition process such as ALD, CVD, PVD, or the like. The dielectric capping layer 380 may be formed of one or more dielectric material(s) having a high etching selectivity from the etching of the semiconductor fins 362, the nanostructures 364, 366, the sacrificial spacers 376, the liner 378A, and the fill material 378B. For example, the dielectric capping layer 380 may comprise a high-k material such as hafnium oxide, zirconium oxide, zirconium aluminum oxide, hafnium aluminum oxide, hafnium silicon oxide, aluminum oxide, the like, or combinations thereof.

The dielectric capping layer 380 may be formed to initially cover the mask 358 and the nanostructures 364, 366. Subsequently, a removal process is applied to remove excess material(s) of the dielectric capping layer 380. In some embodiments, a planarization process such as a CMP, an etch-back process, combinations thereof, or the like may be utilized. The planarization process exposes the masks 358 such that top surfaces of the masks 358, the sacrificial spacers 376, and the dielectric capping layer 380 are coplanar (within process variations). In the illustrated embodiment, the masks 358 remain after the planarization process. In another embodiment, portions of or the entirety of the masks 358 may also be removed by the planarization process.

As a result, insulating fins 382 are formed between and contacting the sacrificial spacers 376. The insulating fins 382 comprise the liner 378A, the fill material 378B, and the dielectric capping layer 380. The sacrificial spacers 376 space the insulating fins 382 apart from the nanostructures 364, 366, and a size of the insulating fins 382 may be adjusted by adjusting a thickness of the sacrificial spacers 376.

In FIGS. 34A-C, the mask 358 is removed using an etching process, for example. The etching process may be a wet etch that selective removes the mask 358 without significantly etching the insulating fins 382. Further, the etching process (or a separate, selective etching process) may also be applied to reduce a height of the sacrificial spacers 376 to a similar level (e.g., same within processing variations) as the stacked nanostructures 364, 366. After the etching process(es), topmost surfaces of the stacked nanostructures 364, 366 and the sacrificial spacers 376 may be exposed and may be lower than topmost surfaces of the insulating fins 382.

In FIG. 35A-C, a dummy gate layer 384 is formed on the insulating fins 382, the sacrificial spacers 376, and the nanostructures 364, 366. Because the nanostructures 364, 366 and the sacrificial spacers 376 extend lower than the insulating fins 382, the dummy gate layer 384 may be disposed along exposed sidewalls of the insulating fins 382. The dummy gate layer 384 may be deposited and then planarized, such as, for example, by a CMP. The dummy gate layer 384 may be formed of a conductive or non-conductive material, such as amorphous silicon, polycrystalline-silicon (polysilicon), poly-crystalline silicon-germanium (poly-SiGe), a metal, a metallic nitride, a metallic silicide, a metallic oxide, or the like, which may be deposited by PVD, CVD, or the like. The dummy gate layer 384 may also be formed of a semiconductor material (such as one selected from the candidate semiconductor materials of the substrate 350), which may be grown by a process such as VPE or MBE, deposited by a process such as CVD or ALD, or the like. The dummy gate layer 384 may be formed of material(s) that have a high etching selectivity from the etching of insulation materials, e.g., the insulating fins 382. A mask layer 386 may be deposited over the dummy gate layer 384. The mask layer 386 may comprise a dielectric material such as silicon nitride, silicon oxynitride, or the like, and may be formed using CVD, ALD, or the like. In this example, a single dummy gate layer 384 and a single mask layer 386 are formed across the n-type region 350N and the p-type region 350P.

In FIGS. 36A-C, the mask layer 386 (see FIGS. 35A-C) is patterned using acceptable photolithography and etching techniques to form masks 396. The pattern of the masks 396 is then transferred to the dummy gate layer 384 (see FIGS. 35A-C) by any acceptable etching technique to form dummy gates 394. The dummy gates 394 cover the top surface of the nanostructures 364, 366 that will be exposed in subsequent processing to form channel regions. The pattern of the masks 396 may be used to physically separate adjacent dummy gates 394. The dummy gates 394 may also have lengthwise directions substantially perpendicular (within process variations) to the lengthwise directions of the semiconductor fins 362. The masks 396 can optionally be removed after patterning, such as by any acceptable etching technique.

The sacrificial spacers 376 and the dummy gates 394 collectively extend along the portions of the nanostructures 366 that will be patterned to form channel regions 368. Subsequently formed gate structures will replace the sacrificial spacers 376 and the dummy gates 394. Forming the dummy gates 394 over the sacrificial spacers 376 allows the subsequently formed gate structures to have a greater height.

As noted above, the dummy gates 394 may be formed of a semiconductor material. In such embodiments, the nanostructures 364, the sacrificial spacers 376, and the dummy gates 394 are each formed of semiconductor materials. In some embodiments, the nanostructures 364 and the sacrificial spacers 376 are formed of a first semiconductor material (e.g., silicon germanium) and the dummy gates 394 are formed of a second semiconductor material (e.g., silicon), so that during a replacement gate process, the dummy gates 394 may be removed in a first etching step, and the nanostructures 364 and the sacrificial spacers 376 may be removed together in a second etching step. When the nanostructures 364 and the sacrificial spacers 376 are formed of silicon germanium: the nanostructures 364 and the sacrificial spacers 376 may have similar germanium concentrations, the nanostructures 364 may have a greater germanium concentration than the sacrificial spacers 376, or the sacrificial spacers 376 may have a greater germanium concentration than the nanostructures 364. In some embodiments, the nanostructures 364 are formed of a first semiconductor material (e.g., silicon germanium) and the sacrificial spacers 376 and the dummy gates 394 are formed of a second semiconductor material (e.g., silicon), so that during a replacement gate process, the sacrificial spacers 376 and the dummy gates 394 may be removed together in a first etching step, and the nanostructures 364 may be removed in a second etching step.

After forming the dummy gates 394, gate spacers 398 are formed over the nanostructures 364, 366, and on exposed sidewalls of the masks 396 (if present) and the dummy gates 394. The gate spacers 398 may be formed by conformally depositing one or more dielectric material(s) on the dummy gates 394 and subsequently etching the dielectric material(s). Acceptable dielectric materials may include silicon oxide, silicon nitride, silicon oxynitride, silicon oxycarbonitride, or the like, which may be formed by a conformal deposition process such as CVD, plasma-enhanced chemical vapor deposition (PECVD), ALD, plasma-enhanced atomic layer deposition (PEALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 394 (thus forming the gate spacers 398). After etching, the gate spacers 398 can have curved sidewalls or can have straight sidewalls.

Further, implants may be performed to form lightly doped source/drain (LDD) regions (not separately illustrated). In the embodiments with different device types, similar to the implants for the wells previously described, a mask (not separately illustrated) such as a photoresist may be formed over the n-type region 350N, while exposing the p-type region 350P, and appropriate type (e.g., p-type) impurities may be implanted into the semiconductor fins 362 and/or the nanostructures 364, 366 exposed in the p-type region 350P. The mask may then be removed. Subsequently, a mask (not separately illustrated) such as a photoresist may be formed over the p-type region 350P while exposing the n-type region 350N, and appropriate type impurities (e.g., n-type) may be implanted into the semiconductor fins 362 and/or the nano structures 364, 366 exposed in the n-type region 350N. The mask may then be removed. The n-type impurities may be any of the n-type impurities previously described, and the p-type impurities may be any of the p-type impurities previously described. During the implanting, the channel regions 368 remain covered by the dummy gates 394, so that the channel regions 368 remain substantially free of the impurity implanted to form the LDD regions. The LDD regions may have a concentration of impurities in the range of 10¹⁵ cm⁻³ to 10¹⁹ cm⁻³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

In FIGS. 37A-C and 38A-C, source/drain regions 408N are formed over the fins 362 in the n-type region 350N. In some embodiments, a mask such as, for example, a photoresist (not shown) is formed over the p-type region 350P to protect the p-type region 350P from process steps performed on the n-type region 350N to form the source/drain regions 408N.

In FIGS. 37A-C, source/drain recesses 404N are formed in the nano structures 364, 366 and the sacrificial spacers 376 in the n-type region 350N. In the illustrated embodiment, the source/drain recesses 404N extend through the nanostructures 364, 366 and the sacrificial spacers 376 into the semiconductor fins 362. The source/drain recesses 404N may also extend into the substrate 350. In various embodiments, the source/drain recesses 404N may extend to a top surface of the substrate 350 without etching the substrate 350; the semiconductor fins 362 may be etched such that bottom surfaces of the source/drain recesses 404N are disposed below the top surfaces of the STI regions 372; or the like. The source/drain recesses 404N may be formed by etching the nanostructures 364, 366 and the sacrificial spacers 376 using an anisotropic etching processes, such as a RIE, a NBE, or the like. The gate spacers 398 and the dummy gates 394 collectively mask portions of the semiconductor fins 362 and/or the nanostructures 364, 366 during the etching processes used to form the source/drain recesses 404N. A single etch process may be used to etch each of the nanostructures 364, 366 and the sacrificial spacers 376, or multiple etch processes may be used to etch the nanostructures 364, 366 and the sacrificial spacers 376. Timed etch processes may be used to stop the etching of the source/drain recesses 404 after the source/drain recesses 404N reach a desired depth.

Optionally, inner spacers 406N are formed on the sidewalls of the nanostructures 364 in the n-type region 350N, e.g., those sidewalls exposed by the source/drain recesses 404N. As will be subsequently described in greater detail, source/drain regions will be subsequently formed in the source/drain recesses 404N, and the nanostructures 364 will be subsequently replaced with corresponding gate structures. The inner spacers 406N act as isolation features between the subsequently formed source/drain regions and the subsequently formed gate structures. Further, the inner spacers 406N may be used to substantially prevent damage to the subsequently formed source/drain regions by subsequent etching processes, such as etching processes used to subsequently remove the nanostructures 364.

As an example to form the inner spacers 406N, the source/drain recesses 404N can be laterally expanded. Specifically, portions of the sidewalls of the nanostructures 364 exposed by the source/drain recesses 404N may be recessed. Although sidewalls of the nanostructures 364 are illustrated as being concave, the sidewalls may be straight or convex. The sidewalls may be recessed by any acceptable etching process, such as one that is selective to the nanostructures 364 (e.g., selectively etches the materials of the nanostructures 364 at a faster rate than the material of the nanostructures 366). The etching may be isotropic. For example, when the nanostructures 366 are formed of silicon and the nanostructures 364 are formed of silicon germanium, the etching process may be a wet etch using tetramethylammonium hydroxide (TMAH), ammonium hydroxide (NH₄OH), or the like. In another embodiment, the etching process may be a dry etch using a fluorine-based gas such as hydrogen fluoride (HF) gas. In some embodiments, the same etching process may be continually performed to both form the source/drain recesses 404N and recess the sidewalls of the nanostructures 364. The inner spacers 406N are then formed on the recessed sidewalls of the nanostructures 364. The inner spacers 406N can be formed by conformally forming an insulating material and subsequently etching the insulating material. The insulating material may be silicon nitride or silicon oxynitride, although any suitable material, such as a low-k dielectric material, may be utilized. The insulating material may be deposited by a conformal deposition process, such as ALD, CVD, or the like. The etching of the insulating material may be anisotropic. For example, the etching process may be a dry etch such as a RIE, a NBE, or the like. Although outer sidewalls of the inner spacers 406N are illustrated as being recessed with respect to the sidewalls of the gate spacers 398, the outer sidewalls of the inner spacers 406N may extend beyond or be flush with the sidewalls of the gate spacers 398. In other words, the inner spacers 406N may partially fill, completely fill, or overfill the sidewall recesses. Moreover, although the sidewalls of the inner spacers 406N are illustrated as being concave, the sidewalls of the inner spacers 406N may be straight or convex.

In FIGS. 38A-C, epitaxial source/drain regions 408N are formed in the source/drain recesses 404N (see FIGS. 37A-C). The epitaxial source/drain regions 408N are formed in the source/drain recesses 404N such that each dummy gate 394 (and corresponding channel region 368) is disposed between respective adjacent pairs of the epitaxial source/drain regions 408N. In some embodiments, the gate spacers 398 and the inner spacers 406N are used to separate the epitaxial source/drain regions 408N from, respectively, the dummy gates 394 and the nanostructures 364 by an appropriate lateral distance so that the epitaxial source/drain regions 408N do not short out with subsequently formed gates of the resulting nano-FETs. A material of the epitaxial source/drain regions 408N may be selected to exert stress in the respective channel regions 368, thereby improving performance.

In some embodiments, the epitaxial source/drain regions 408N are epitaxially grown in the source/drain recesses 404N (see FIGS. 37A-C) in the n-type region 350N. The epitaxial source/drain regions 408N may include any acceptable material appropriate for n-type devices. For example, if the nanostructures 366 are silicon, the epitaxial source/drain regions 408N may include materials exerting a tensile strain on the channel regions 368, such as silicon, silicon carbide, phosphorous doped silicon carbide, silicon arsenide, silicon phosphide, or the like. The epitaxial source/drain regions 408N may be referred to as “n-type source/drain regions.” The epitaxial source/drain regions 408N may have surfaces raised from respective surfaces of the semiconductor fins 362 and the nanostructures 364, 366, and may have facets.

The epitaxial source/drain regions 408N, the nanostructures 364, 366, and/or the semiconductor fins 362 may be implanted with impurities to form source/drain regions, similar to the process previously described for forming LDD regions, followed by an anneal. The epitaxial source/drain regions 408N may have an impurity concentration in the range of 10¹⁹ cm⁻³ to 10²¹ cm⁻³. The n-type impurities for source/drain regions may be any of the impurities previously described. In some embodiments, the epitaxial source/drain regions 408N may be in situ doped during growth.

The epitaxial source/drain regions 408N may include one or more semiconductor material layers. For example, the epitaxial source/drain regions 408N may each include one or more liner layers 408A, a main layer 408B, and a capping layer 408C (or more generally, a first semiconductor material layer, a second semiconductor material layer, and a third semiconductor material layer). Any number of semiconductor material layers may be used for the epitaxial source/drain regions 408N. Each of the liner layer 408A, the main layer 408B, and the capping layer 408C may be formed of different semiconductor materials and may be doped to different impurity concentrations. In some embodiments, the liner layer 408A may have a lesser concentration of impurities than the main layer 408B, and the capping layer 408C may have a greater concentration of impurities than the liner layer 408A and a lesser concentration of impurities than the main layer 408B. In embodiments in which the epitaxial source/drain regions 408N include three semiconductor material layers, the liner layers 408A may be grown in the source/drain recesses 404N (see FIG. 37A-C), the main layers 408B may be grown on the liner layers 408A, and the capping layers 408C may be grown on the main layers 408B.

As a result of the epitaxy processes used to form the epitaxial source/drain regions 408N, upper surfaces of the epitaxial source/drain regions 408N have facets which expand laterally outward beyond sidewalls of the semiconductor fins 362 and the nanostructures 364, 366. However, the insulating fins 382 block the lateral epitaxial growth. Therefore, adjacent epitaxial source/drain regions 408N remain separated after the epitaxy process is completed as illustrated by FIG. 38C. The epitaxial source/drain regions 408N contact the sidewalls of the insulating fins 382. In the illustrated embodiment, the epitaxial source/drain regions 408N are grown so that the upper surfaces of the epitaxial source/drain regions 408N are disposed below the top surfaces of the insulating fins 382. In various embodiments, the upper surfaces of the epitaxial source/drain regions 408N are disposed above the top surfaces of the insulating fins 382; the upper surfaces of the epitaxial source/drain regions 408N have portions disposed above and below the top surfaces of the insulating fins 382; or the like. After forming the epitaxial source/drain regions 408N in the n-type region 350N, the mask layer formed over the p-type region 350P is removed using any suitable removal process.

In FIGS. 39A-C and 40A-C, source/drain regions 408P are formed over the fins 362 in the p-type region 350P. In some embodiments, a mask such as, for example, a photoresist (not shown) is formed over the n-type region 350N to protect the n-type region 350N from process steps performed on the p-type region 350P to form the source/drain regions 408P.

In FIGS. 39A-C, source/drain recesses 404P are formed in the nanostructures 364, 366 and the sacrificial spacers 376 in the p-type region 350P. In the illustrated embodiment, the source/drain recesses 404P extend through the nanostructures 364, 366 and the sacrificial spacers 376 into the semiconductor fins 362. The source/drain recesses 404P may also extend into the substrate 350. In various embodiments, the source/drain recesses 404P may extend to a top surface of the substrate 350 without etching the substrate 350; the semiconductor fins 362 may be etched such that bottom surfaces of the source/drain recesses 404P are disposed below the top surfaces of the STI regions 372; or the like. In some embodiments, the source/drain recesses 404P may be formed in a similar manner as the source/drain recesses 404N described above with reference to FIGS. 37A-C, and the description is not repeated herein.

Optionally, inner spacers 406P are formed on the sidewalls of the nanostructures 364 in the p-type region 350P, e.g., those sidewalls exposed by the source/drain recesses 404P. As will be subsequently described in greater detail, source/drain regions will be subsequently formed in the source/drain recesses 404P, and the nanostructures 364 will be subsequently replaced with corresponding gate structures. The inner spacers 406P act as isolation features between the subsequently formed source/drain regions and the subsequently formed gate structures. Further, the inner spacers 406P may be used to substantially prevent damage to the subsequently formed source/drain regions by subsequent etching processes, such as etching processes used to subsequently remove the nanostructures 364.

In some embodiments, the inner spacers 406P may be formed using similar materials and methods as the inner spacers 406N described above with reference to FIGS. 37A-C, and the description is not repeated herein. Although outer sidewalls of the inner spacers 406P are illustrated as being recessed with respect to the sidewalls of the gate spacers 398, the outer sidewalls of the inner spacers 406P may extend beyond or be flush with the sidewalls of the gate spacers 398. In other words, the inner spacers 406P may partially fill, completely fill, or overfill the sidewall recesses. Moreover, although the sidewalls of the inner spacers 406P are illustrated as being concave, the sidewalls of the inner spacers 406P may be straight or convex. In some embodiments, the inner spacers 406P and the inner spacers 406N comprise a same material. In other embodiments, the inner spacers 406P and the inner spacers 406N comprise different materials.

In FIGS. 40A-C, epitaxial source/drain regions 408P are formed in the source/drain recesses 404P (see FIGS. 39A-C). The epitaxial source/drain regions 408P are formed in the source/drain recesses 404P such that each dummy gate 394 (and corresponding channel region 368) is disposed between respective adjacent pairs of the epitaxial source/drain regions 408P. In some embodiments, the gate spacers 398 and the inner spacers 406P are used to separate the epitaxial source/drain regions 408P from, respectively, the dummy gates 394 and the nanostructures 364 by an appropriate lateral distance so that the epitaxial source/drain regions 408P do not short out with subsequently formed gates of the resulting nano-FETs. A material of the epitaxial source/drain regions 408P may be selected to exert stress in the respective channel regions 368, thereby improving performance.

In some embodiments, the epitaxial source/drain regions 408P are epitaxially grown in the source/drain recesses 404P (see FIGS. 39A-C) in the p-type region 350P. The epitaxial source/drain regions 408P may include any acceptable material appropriate for p-type devices. For example, if the nanostructures 366 are silicon, the epitaxial source/drain regions 408P may include materials exerting a compressive strain on the channel regions 368, such as silicon germanium, boron doped silicon germanium, silicon germanium phosphide, germanium, germanium tin, or the like. The epitaxial source/drain regions 408P may be referred to as “p-type source/drain regions.” The epitaxial source/drain regions 408P may have surfaces raised from respective surfaces of the semiconductor fins 362 and the nanostructures 364, 366, and may have facets.

The epitaxial source/drain regions 408P, the nanostructures 364, 366, and/or the semiconductor fins 362 may be implanted with impurities to form source/drain regions, similar to the process previously described for forming LDD regions, followed by an anneal. The epitaxial source/drain regions 408P may have an impurity concentration in the range of 10¹⁹ cm⁻³ to 10²¹ cm⁻³. The p-type impurities for the source/drain regions may be any of the impurities previously described. In some embodiments, the epitaxial source/drain regions 408P may be in situ doped during growth.

The epitaxial source/drain regions 408P may include one or more semiconductor material layers. For example, the epitaxial source/drain regions 408P may each include one or more liner layers (such as a first liner layer 408D and a second liner layer 408E), a main layer 408F, and a capping layer 408G (or more generally, a first semiconductor material layer, a second semiconductor material layer, a third semiconductor material layer, and a fourth semiconductor material layer). Any number of semiconductor material layers may be used for the epitaxial source/drain regions 408P. Each of the liner layers 408D and 408E, the main layer 408F, and the capping layer 408G may be formed of different semiconductor materials and may be doped to different impurity concentrations. In some embodiments, the liner layers 408D and 408E may have a lesser concentration of impurities than the main layer 408F, and the capping layer 408G may have a greater concentration of impurities than the than the main layer 408F. In embodiments in which the epitaxial source/drain regions 408P include four semiconductor material layers, the first liner layers 408D may be grown in the source/drain recesses 404P (see FIGS. 39A-C), the second liner layers 408E may be grown on the first liner layers 408D, the main layers 408F may be grown on the second liner layers 408E, and the capping layers 408G may be grown on the main layers 408F.

Further in FIGS. 40A-40C, in some embodiments, the liner layers 408D and 408E and the main layers 408F comprise a boron-doped silicon germanium (SiGe:B), and the capping layers 408G comprises a boron-rich layer. The boron-rich layer may comprise boron (B), oxygen (O), a combination thereof, or the like. In some embodiments, the liner layers 408D and 408E, the main layers 408F, and the capping layer 408G are epitaxially grown using, for example, VPE, MBE, a selective epitaxial growth, or the like. In some embodiments, germanium contents of the liner layers 408D and 408E is less than germanium contents of the main layers 408F.

In some embodiments when the liner layers 408D and 408E and the main layers 408F comprise a boron-doped silicon germanium (SiGe:B), the liner layers 408D and 408E, and the main layers 408F may be epitaxially grown using reactants such as silicon-containing precursors (such as silane, dichlorosilane, or the like), germanium-containing precursors (germane, dichlorogermane, or the like), boron-containing precursors (borane or the like), etchants (such as hydrochloric acid or the like), combinations thereof, or the like, at a process temperature between about 550° C. and 850° C., and at a process pressure between about 20 Torr and about 300 Torr.

In some embodiments when the capping layers 408G comprise boron-rich layers, the capping layers 408G may be epitaxially grown using reactants such as boron-containing precursors (borane, diborane, boron trichloride, or the like), etchants (such as hydrochloric acid or the like), combinations thereof, or the like, at a process temperature between about 500° C. and 700° C., and at a process pressure between about 20 Torr and about 60 Torr.

As a result of the epitaxy processes used to form the epitaxial source/drain regions 408P, upper surfaces of the epitaxial source/drain regions 408P have facets which expand laterally outward beyond sidewalls of the semiconductor fins 362 and the nanostructures 364, 366. However, the insulating fins 382 block the lateral epitaxial growth. Therefore, adjacent epitaxial source/drain regions 408P remain separated after the epitaxy process is completed as illustrated by FIG. 40C. The epitaxial source/drain regions 408P contact the sidewalls of the insulating fins 382. In the illustrated embodiment, the epitaxial source/drain regions 408P are grown so that the upper surfaces of the epitaxial source/drain regions 408P are disposed below the top surfaces of the insulating fins 382. In various embodiments, the upper surfaces of the epitaxial source/drain regions 408P are disposed above the top surfaces of the insulating fins 382; the upper surfaces of the epitaxial source/drain regions 408P have portions disposed above and below the top surfaces of the insulating fins 382; or the like. After forming the epitaxial source/drain regions 408P in the p-type region 350P, the mask layer formed over the n-type region 350N is removed using any suitable removal process.

FIG. 40D illustrates a magnified view of a region 409 shown in FIG. 40C, in accordance with some embodiments. In some embodiments, interfaces between the epitaxial source/drain regions 408P and the respective insulating fins 382 are substantially vertical (within process variations) to a top surface of the substrate 350 as illustrated in FIG. 40C. In other embodiments, the interfaces between the epitaxial source/drain regions 408P and the respective insulating fins 382 are sloped as illustrated in FIG. 40D. In some embodiments, the capping layer 408G has a thickness that may be up to 3 nm. The epitaxial source/drain regions 408P have a thirteenth height H13 as measured from topmost surfaces of the topmost nanostructures 366. In some embodiments, the thirteenth height H13 may be up to 10 nm. The epitaxial source/drain regions 408P have a ninth width W9 as measured at a depth of about 5 nm from topmost surfaces of the epitaxial source/drain regions 408P. In some embodiments, the ninth width W9 is between about 5 nm and about 25 nm. The epitaxial source/drain regions 408P have a tenth width W10 that is measured below topmost surfaces of the epitaxial source/drain regions 408P. In some embodiments, the tenth width W10 is between about 20 nm and about 40 nm.

In FIGS. 41A-C, a first inter-layer dielectric (ILD) 414 is deposited over the epitaxial source/drain regions 408N and 408P, the gate spacers 398, the masks 396 (if present) or the dummy gates 394. The first ILD 414 may be formed of a dielectric material, which may be deposited by any suitable method, such as CVD, PECVD, FCVD, or the like. Acceptable dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used.

In some embodiments, a contact etch stop layer (CESL) 412 is formed between the first ILD 414 and the epitaxial source/drain regions 408N and 408P, the gate spacers 398, and the masks 396 (if present) or the dummy gates 394. The CESL 412 may be formed of a dielectric material, such as silicon nitride, silicon oxide, silicon oxynitride, or the like, having a high etching selectivity from the etching of the first ILD 414. The CESL 412 may be formed by any suitable method, such as CVD, ALD, or the like.

In FIGS. 42A-C, a removal process is performed to level the top surfaces of the first ILD 414 with the top surfaces of the masks 396 (if present) or the dummy gates 394. In some embodiments, a planarization process such as a CMP, an etch-back process, combinations thereof, or the like may be utilized. The planarization process may also remove the masks 396 on the dummy gates 394, and portions of the gate spacers 398 along sidewalls of the masks 396. After the planarization process, the top surfaces of the gate spacers 398, the first ILD 414, the CESL 412, and the masks 396 (if present) or the dummy gates 394 are coplanar (within process variations). Accordingly, the top surfaces of the masks 396 (if present) or the dummy gates 394 are exposed through the first ILD 414. In the illustrated embodiment, the masks 396 remain, and the planarization process levels the top surfaces of the first ILD 414 with the top surfaces of the masks 396.

In FIGS. 43A-C, the masks 396 (if present) and the dummy gates 394 are removed in an etching process, so that recesses 416N and 416P are formed in the n-type region 350N and the p-type region 350P, respectively. In some embodiments, the dummy gates 394 are removed by an anisotropic dry etch process. For example, the etching process may include a dry etch process using reaction gas(es) that selectively etch the dummy gates 394 at a faster rate than the first ILD 414 or the gate spacers 398. Each of recesses 416N and 416P exposes and/or overlies portions of the respective channel region 368. Portions of the nanostructures 366 which act as the channel regions 368 are disposed between adjacent pairs of the epitaxial source/drain regions 408N and 408P in the n-type region 350N and the p-type region 350P, respectively.

The remaining portions of the nanostructures 364 are then removed to expand the recesses 416N and 416P, such that openings 418N and 418P are formed in regions between the nanostructures 366 in the n-type region 350N and the p-type region 350P, respectively. The remaining portions of the sacrificial spacers 376 are also removed to expand the recesses 416N and 416P, such that openings 420 are formed in regions between semiconductor fins 362 and the insulating fins 382 in both the n-type region 350N and the p-type region 350P. The remaining portions of the nanostructures 364 and the sacrificial spacers 376 can be removed by any acceptable etching process that selectively etches the material(s) of the nanostructures 364 and the sacrificial spacers 376 at a faster rate than the material of the nanostructures 366. The etching may be isotropic. For example, when the nanostructures 364 and the sacrificial spacers 376 are formed of silicon germanium and the nanostructures 366 are formed of silicon, the etching process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the nanostructures 366.

In FIGS. 44A-C, gate dielectric layers 424N and 424P are formed in the openings 418N and 418N, in the openings 420, and in the recesses 416N and 416P (see FIGS. 43A-C), respectively. Gate electrode layers 426N and 426P are formed on the gate dielectric layers 424N and 424P, respectively. The gate dielectric layer 424N and the gate electrode layer 426N are layers for replacement gates in the n-type region 350N, and each wrap around all (e.g., four) sides of the nanostructures 366 in the n-type region 350N. The gate dielectric layer 424P and the gate electrode layer 426P are layers for replacement gates in the p-type region 350P, and each wrap around all (e.g., four) sides of the nanostructures 366 in the p-type region 350P.

The gate dielectric layer 424N is disposed on the sidewalls and/or the top surfaces of the semiconductor fins 362; on the top surfaces, the sidewalls, and the bottom surfaces of the nanostructures 366; on the sidewalls of the inner spacers 406N adjacent to the epitaxial source/drain regions 408N and the sidewalls of the gate spacers 398; and on the top surfaces and the sidewalls of the insulating fins 382. The gate dielectric layer 424N may also be formed on the top surfaces of the first ILD 414 and the gate spacers 398 in the n-type region 350N. The gate dielectric layer 424P is disposed on the sidewalls and/or the top surfaces of the semiconductor fins 362; on the top surfaces, the sidewalls, and the bottom surfaces of the nanostructures 366; on the sidewalls of the inner spacers 406P adjacent to the epitaxial source/drain regions 408P and the sidewalls of the gate spacers 398; and on the top surfaces and the sidewalls of the insulating fins 382. The gate dielectric layer 424P may also be formed on the top surfaces of the first ILD 414 and the gate spacers 398 in the p-type region 350P.

The gate dielectric layers 424N and 424P may include an oxide such as silicon oxide or a metal oxide, a silicate such as a metal silicate, combinations thereof, multi-layers thereof, or the like. The gate dielectric layers 424N and 424P may include a high-k dielectric material (e.g., a dielectric material having a k-value greater than about 7.0), such as a metal oxide or a silicate of hafnium, aluminum, zirconium, lanthanum, manganese, barium, titanium, lead, and combinations thereof. The formation methods of the gate dielectric layers 424N and 424P may include Molecular-Beam Deposition (MBD), ALD, PECVD, a combination thereof, or the like. Although a single-layered gate dielectric layer 424N and a single-layered gate dielectric layer 424P are illustrated in FIGS. 44A-C, each of the gate dielectric layers 424N and 424P may include any number of interfacial layers and any number of main layers.

Although a single-layered gate electrode layer 426N is illustrated in FIGS. 44A-C, the gate electrode layer 426N may include any number liner layers, any number work function tuning layers, and a conductive fill material. The liner layers may include TiN, TiO, TaN, TaC, combinations thereof, multi-layers thereof, or the like, and may be formed using PVD, CVD, ALD, a combination thereof, or the like. The work function tuning layers may include Ti, Ag, Al, TiAl, TiAlN, TiAlC, TaC, TaCN, TaSiN, TaAlC, Mn, Zr, combinations thereof, multi-layers thereof, or the like, and may be formed using PVD, CVD, ALD, a combination thereof, or the like. The conductive fill material may comprise Co, Ru, Al, Ag, Au, W, Ni, Ti, Cu, Mn, Pd, Re, Ir, Pt, Zr, alloys thereof, combinations thereof, multi-layers thereof, or the like, and may be formed using PVD, CVD, ALD, plating, a combination thereof, or the like.

Although a single-layered gate electrode layer 426P is illustrated in FIGS. 44A-C, the gate electrode layer 426P may include any number liner layers, any number work function tuning layers, and a conductive fill material. The liner layers may include TiN, TiO, TaN, TaC, combinations thereof, multi-layers thereof, or the like, and may be formed using PVD, CVD, ALD, a combination thereof, or the like. The work function tuning layers may include TiN, WN, TaN, Ru, Co, combinations thereof, multi-layers thereof, or the like, and may be formed using PVD, CVD, ALD, a combination thereof, or the like. The conductive fill material may comprise Co, Ru, Al, Ag, Au, W, Ni, Ti, Cu, Mn, Pd, Re, Ir, Pt, Zr, alloys thereof, combinations thereof, multi-layers thereof, or the like, and may be formed using PVD, CVD, ALD, plating, a combination thereof, or the like.

In some embodiments, the formation of the gate dielectric layer 424N in the n-type region 350N and the gate dielectric layer 424P in the p-type region 350P may occur simultaneously such that the gate dielectric layers 424N and 424P are formed of the same materials. In other embodiments, the gate dielectric layer 424N in the n-type region 350N and the gate dielectric layer 424P in the p-type region 350P may be formed by distinct processes, such that the gate dielectric layers 424N and 424P may comprise different materials and/or have a different number of layers. In some embodiments, the formation of the gate electrode layer 426N in the n-type region 350N and the gate electrode layer 426P in the p-type region 350P may occur simultaneously such that the gate electrode layer 426N and 426P are formed of the same materials. In other embodiments, the gate electrode layer 426N in the n-type region 350N and the gate electrode layer 426P in the p-type region 350P may be formed by distinct processes, such that the gate electrode layers 426N and 426P may comprise different materials and/or have a different number of layers. Various masking steps may be used to mask and expose appropriate regions when using distinct processes.

In FIGS. 45A-C, a removal process is performed to remove the excess portions of the materials of the gate dielectric layers 424N and 424P, and the gate electrode layers 426N and 426P, which excess portions are over the top surfaces of the first ILD 414 and the gate spacers 398, thereby forming gate structures 430N and 430P in the n-type region 350N and the p-type region 350P, respectively. In some embodiments, a planarization process such as a CMP, an etch-back process, combinations thereof, or the like may be utilized. The gate dielectric layers 424N and 424P, when planarized, have portions left in the recesses 416N and 416P (see FIGS. 43A-C), thus forming gate dielectrics for the gate structures 430N and 430P, respectively. The gate electrode layers 426N and 426P, when planarized, have portions left in the recesses 416N and 416P (see FIGS. 43A-C), thus forming gate electrodes for the gate structures 430N and 430P, respectively. The top surfaces of the gate spacers 398; the CESL 412; the first ILD 414; and the gate structures 430N and 430P are coplanar (within process variations). The gate structures 430N and 430P are replacement gates of the resulting nano-FETs, and may be referred to as “metal gates.” The gate structures 430N and 430P each extend along top surfaces, sidewalls, and bottom surfaces of a channel region 368 of the nanostructures 366 in the n-type region 350N and the p-type region 350P, respectively. The gate structures 430N and 430P fill the area previously occupied by the nanostructures 364, the sacrificial spacers 376, and the dummy gates 394.

In some embodiments, isolation regions 432 are formed extending through some of the gate structures 430N and 430P. An isolation region 432 is formed to divide (or “cut”) a gate structure 430N and/or a gate structure 430P into multiple gate structures. The isolation region 432 may be formed of a dielectric material, such as silicon nitride, silicon oxide, silicon oxynitride, or the like, which may be formed by a deposition process such as CVD, ALD, or the like. As an example to form the isolation regions 432, openings can be patterned in the desired gate structures 430N and 430P. Any acceptable etch process, such as a dry etch, a wet etch, the like, or a combination thereof, may be performed to pattern the openings. The etching may be anisotropic. One or more layers of dielectric material may be deposited in the openings. A removal process may be performed to remove the excess portions of the dielectric material, which excess portions are over the top surfaces of the gate structures 430N and 430P, thereby forming the isolation regions 432.

In FIGS. 46A-C, a second ILD 436 is deposited over the gate spacers 398, the CESL 412, the first ILD 414, and the gate structures 430N and 430P. In some embodiments, the second ILD 436 is a flowable film formed by a flowable CVD method. In some embodiments, the second ILD 436 is formed of a dielectric material such as PSG, BSG, BPSG, USG, or the like, which may be deposited by any suitable method, such as CVD, PECVD, or the like. In some embodiments, the first ILD 414 and the second ILD 436 comprise a same material. In other embodiments, the first ILD 414 and the second ILD 436 comprise different materials.

In some embodiments, an etch stop layer (ESL) 434 is formed between the second ILD 436 and the gate spacers 398, the CESL 412, the first ILD 414, and the gate structures 430N and 430P. The ESL 434 may include a dielectric material, such as silicon nitride, silicon oxide, silicon oxynitride, or the like, having a high etching selectivity from the etching of the second ILD 436.

In FIGS. 47A-C, gate contacts 442N and source/drain contacts 444N are formed in the n-type region 350N to contact, respectively, the gate structures 430N and the epitaxial source/drain regions 408N, and gate contacts 442P and source/drain contacts 444P are formed in the p-type region 350P to contact, respectively, the gate structures 430P and the epitaxial source/drain regions 408P. The gate contacts 442N and 442P are physically and electrically coupled to the gate structures 430N and 430P, respectively. The source/drain contacts 444N and 444P are physically and electrically coupled to the epitaxial source/drain regions 408N and 408P, respectively.

As an example to form the gate contacts 442N and 442P and the source/drain contacts 444N and 444P, openings for the gate contacts 442N and 442P are formed through the second ILD 436 and the ESL 434, and openings for the source/drain contacts 444N and 444P are formed through the second ILD 436, the ESL 434, the first ILD 414, and the CESL 412. In some embodiments, the openings for the source/drain contacts 444P are also formed through the capping layers 408G of the epitaxial source/drain regions 408P. The openings may be formed using acceptable photolithography and etching techniques. After forming the openings, a liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 436. The remaining liner and conductive material form the gate contacts 442N and 442P, and the source/drain contacts 444N and 444P in the respective openings. The gate contacts 442N and the source/drain contacts 444N may be formed in distinct processes, or may be formed in the same process. The gate contacts 442P and the source/drain contacts 444P may be formed in distinct processes, or may be formed in the same process. Although shown as being formed in the same cross-sections, it should be appreciated that each of the gate contacts 442N and the source/drain contacts 444N may be formed in different cross-sections, which may avoid shorting of the contacts. Although shown as being formed in the same cross-sections, it should be appreciated that each of the gate contacts 442P and the source/drain contacts 444P may be formed in different cross-sections, which may avoid shorting of the contacts.

Optionally, metal-semiconductor alloy regions 446N and 446P are formed at the interfaces between the epitaxial source/drain regions 408N and 408P, and the source/drain contacts 444N and 444P, respectively. The metal-semiconductor alloy regions 446N and 446P can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 446N and 446P can be formed before the formation of the source/drain contacts 444N and 444P by depositing a metal in the openings for the source/drain contacts 444N and 444P, respectively, and then performing a thermal anneal process. The metal can be any metal capable of reacting with the semiconductor materials (e.g., silicon, silicon-germanium, germanium, etc.) of the epitaxial source/drain regions 408N and 408P to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 444N and 444P, such as from surfaces of the metal-semiconductor alloy regions 446N and 446P, respectively. The material(s) of the source/drain contacts 444N and 444P can then be formed on the metal-semiconductor alloy regions 446N and 446P, respectively.

FIG. 47D illustrates a magnified view of a region 447 shown in FIG. 47C, in accordance with some embodiments. In some embodiments, by implementing the boron-rich layers as the capping layers 408G of the epitaxial source/drain regions 408P, germanium-containing portions of the epitaxial source/drain regions 408P may be protected from the etching process for forming the openings for the source/drain contacts 444P, such that loss of the germanium-containing portions of the epitaxial source/drain regions 408P is reduced or avoided. Accordingly, the source/drain contacts 444P land on the high-germanium-content portions of the epitaxial source/drain regions 408P, which allows for the reduction of the contact resistance for the source/drain contacts 444P. In some embodiments, due to the loss of the germanium-containing portions of the epitaxial source/drain regions 408P, top surfaces of the epitaxial source/drain regions 408P (as illustrated in FIG. 47D) extend below top surfaces of the original epitaxial source/drain regions 408P (as illustrated in FIG. 40D) to a depth D1. In some embodiments, the depth D1 may be up to 20 nm. The epitaxial source/drain regions 408P have a fourteenth height H14 as measured from topmost surfaces of the topmost nanostructures 366 to bottom surfaces of the metal-semiconductor alloy regions 446P. In some embodiments, the fourteenth height H14 may be up to 15 nm. The epitaxial source/drain regions 408P have a fifteenth height H15 as measured from topmost surfaces of the fins 362 to bottom surfaces of the metal-semiconductor alloy regions 446P. In some embodiments, the fifteenth height H15 is between about 10 nm and about 15 nm.

The embodiments of the present disclosure have some advantageous features. The embodiments include the formation of a boron-rich capping layer over top surfaces and sidewalls of an epitaxial source/drain region. The boron-rich capping layer acts as a sacrificial layer and retards epitaxial source/drain region loss during a fluorine based etching process used to form source/drain contact openings in an inter-layer dielectric (ILD) over the source/drain region. One or more embodiments disclosed herein may include the boron-rich capping layer acting as a dopant donor to slightly dope a channel region which results in lower channel resistance and improved electrical performance. In addition, the use of the boron-rich capping layer results in decreased epitaxial source/drain region loss during the fluorine based etching process allowing the source/drain region to retain a larger volume of high percentage germanium epitaxial material, as well as allowing for landing a source/drain contact on high germanium (Ge) content regions of the source/drain region. This may result in a lower resistance between the source/drain region and the subsequently formed source/drain contact that physically contacts this high percentage germanium epitaxial material. Further, the decreased epitaxial source/drain region loss during the fluorine based etching process due to the use of the boron-rich capping layer results in the source/drain region having a higher raised height.

In accordance with an embodiment, a method includes forming a first semiconductor fin on a substrate; forming a source/drain region in the first semiconductor fin; depositing a capping layer on the source/drain region, where the capping layer includes a first boron concentration higher than a second boron concentration of the source/drain region; etching an opening through the capping layer, the opening exposing the source/drain region; forming a silicide layer on the exposed source/drain region; and forming a source/drain contact on the silicide layer. In an embodiment, etching the opening through the capping layer includes a dry etch process that includes using fluorine-comprising etchant. In an embodiment, the first boron concentration is in a range from 3×10²¹/cm³ to 1×10²²/cm³, and the second boron concentration is in a range from 1×10²⁰/cm³ to about 2×10²¹/cm³. In an embodiment, the method further includes forming a second semiconductor fin on the substrate, the first semiconductor fin being adjacent to the first semiconductor fin; forming a second source/drain region in the second semiconductor fin, where the source/drain region and the second source/drain region are merged; and depositing the capping layer on the second source/drain region. In an embodiment, a method further includes depositing a dielectric layer over the capping layer, where during the depositing of the dielectric layer, the capping layer is oxidized. In an embodiment, depositing the capping layer includes depositing the capping layer at a process temperature in a range from 500° C. to 700° C. and at a process pressure in a range from 20 torr to 60 torr.

In accordance with an embodiment, a method includes depositing a capping layer on a source/drain region, where a first thickness of the capping layer on a first sidewall of the source/drain region is larger than a second thickness of the capping layer on a second sidewall of the source/drain region, where the first sidewall is above the second sidewall; depositing a contact etch stop layer (CESL) on the source/drain region; forming an inter-layer dielectric (ILD) on the CESL; forming a contact opening through the ILD, the CESL, and the capping layer, where the contact opening exposes the source/drain region; and forming a source/drain contact in the contact opening. In an embodiment, the method further includes forming a metal layer on the exposed source/drain region; and annealing the metal layer to form a silicide layer. In an embodiment, the first sidewall of the source/drain region is above outermost points of the capping layer, and the second sidewall of the source/drain region is below the outermost points of the capping layer. In an embodiment, the first thickness of the capping layer is in a range from 0.5 nm to 2 nm, and the second thickness of the capping layer is up to 2 nm. In an embodiment, depositing of the capping layer includes using borane, diborane, or boron trichloride as process reactants. In an embodiment, a first boron concentration of the capping layer is in a range from 3×10²¹/cm³ to 1×10²²/cm³, and a second boron concentration of the source/drain region is in a range from 1×10²⁰/cm³ to about 2×10²¹/cm³. In an embodiment, after forming the source/drain contact, a first height of the source/drain region from a first point on a bottom surface of the source/drain region to a second point on a top surface of the source/drain region is larger than 40 nm, the second point being vertically above the first point. In an embodiment, forming the contact opening through the ILD, the CESL, and the capping layer includes a fluorine based plasma etch process.

In accordance with an embodiment, a device includes a gate structure on a channel region of a substrate; a source/drain region adjoining the channel region; a capping layer on a first portion of the source/drain region, where a first boron concentration of the capping layer is higher than a second boron concentration of the source/drain region; a silicide on a second portion of the source/drain region; and a source/drain contact electrically connected to the source/drain region through the silicide. In an embodiment, a first portion of the capping layer has a first thickness that is larger than a second thickness of a second portion of the capping layer, where the first portion of the capping layer is higher than the second portion of the capping layer. In an embodiment, the first portion of capping layer is higher than the widest portion of the source/drain region. In an embodiment, the silicide is further disposed on a top surface of the capping layer. In an embodiment, the device further includes an inter-layer dielectric (ILD) over the capping layer, where the ILD includes silicon oxide, and the capping layer includes boron oxide. In an embodiment, a first height of a first sidewall of the source/drain region between a bottommost point of the capping layer and a bottommost surface of the source/drain region is larger than 10 nm.

In accordance with an embodiment, a device includes a nanosheet; a gate structure wrapping around the nanosheet; a source/drain region adjacent to a sidewall of the nanosheet, the source/drain region including a first liner layer comprising a first silicon germanium material, the first silicon germanium material having a first germanium concentration; a main layer over the first liner layer, the main layer including a second silicon germanium material, the second silicon germanium material having a second germanium concentration different from the first germanium concentration; and a capping layer over the first liner layer and the main layer, the capping layer including a boron-rich material; and a source/drain contact landing on the main layer of the source/drain region. In an embodiment, the second germanium concentration is greater than the first germanium concentration. In an embodiment, the boron-rich material includes boron (B) or oxygen (O). In an embodiment, the first liner layer and the main layer further includes boron (B). In an embodiment, the source/drain region has sloped sidewalls. In an embodiment, the device further includes a metal-semiconductor alloy region between the source/drain contact and the main layer of the source/drain region. In an embodiment, the device further includes an insulating fin in physical contact with a sidewall of the source/drain region.

In accordance with an embodiment, a device includes a plurality of nanosheets; a gate structure wrapping around each of the plurality of nanosheets; an epitaxial source/drain region adjacent to the plurality of nanosheets, the epitaxial source/drain region including a first silicon germanium layer having a first germanium concentration; a second silicon germanium layer over the first silicon germanium layer, the second silicon germanium layer having a second germanium concentration greater than the first germanium concentration; and a boron-rich capping layer over the first silicon germanium layer and second silicon germanium layer; a source/drain contact over and in electrical contact with the epitaxial source/drain region; and a metal-semiconductor alloy region between the source/drain contact and the epitaxial source/drain region, where an interface between the metal-semiconductor alloy region and the second silicon germanium layer of the epitaxial source/drain region is above a topmost surface of a topmost nanosheet of the plurality of nanosheets. In an embodiment, the metal-semiconductor alloy region extends through the boron-rich capping layer. In an embodiment, the device further includes a third silicon germanium layer between the first silicon germanium layer and the second silicon germanium layer, the third silicon germanium layer having a third germanium concentration less than the second germanium concentration. In an embodiment, the device further includes an insulating fin in physical contact with a sidewall of the epitaxial source/drain region. In an embodiment, an interface between the insulating fin and the epitaxial source/drain region is sloped. In an embodiment, a bottommost surface of the insulating fin is above a bottommost surface of the epitaxial source/drain region. In an embodiment, a topmost surface of the insulating fin is above a topmost surface of the epitaxial source/drain region.

In accordance with an embodiment, a method includes forming a stack including a plurality of first nanosheets and a plurality of second nanosheets over a substrate, the plurality of first nanosheets and the plurality of second nanosheets being arranged in an alternating manner in the stack; forming a dummy gate structure over the stack; patterning the stack to form a recess extending through the plurality of first nanosheets and the plurality of second nanosheets; and forming a source/drain region in the recess, where forming the source/drain region includes epitaxially growing a first silicon germanium layer in the recess, the first silicon germanium layer having a first germanium concentration; epitaxially growing a second silicon germanium layer over the first silicon germanium layer, the second silicon germanium layer having a second germanium concentration greater than the first germanium concentration; and epitaxially growing a boron-rich capping layer over the first silicon germanium layer and second silicon germanium layer. In an embodiment, the method further includes forming a metal-semiconductor alloy region over the source/drain region, where an interface between the metal-semiconductor alloy region and the second silicon germanium layer of the source/drain region is above a topmost surface of the stack. In an embodiment, the method further includes forming a source/drain contact over and in physical contact with the metal-semiconductor alloy region. In an embodiment, the method further includes an insulating fin over the substrate and extending along a sidewall of the stack. In an embodiment, the recess exposes a sidewall of the insulating fin and extends below a bottommost surface of the insulating fin. In an embodiment, the source/drain region is in physical contact with the sidewall of the insulating fin.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first semiconductor fin on a substrate;
forming a source/drain region in the first semiconductor fin;
depositing a capping layer on the source/drain region, wherein the capping layer comprises a first boron concentration higher than a second boron concentration of the source/drain region;
etching an opening through the capping layer, the opening exposing the source/drain region;
forming a silicide layer on the exposed source/drain region; and
forming a source/drain contact on the silicide layer.

2. The method of claim 1, wherein etching the opening through the capping layer comprises a dry etch process that includes using fluorine-comprising etchant.

3. The method of claim 1, wherein the first boron concentration is in a range from 3×10²¹/cm³ to 1×10²²/cm³, and the second boron concentration is in a range from 1×10²⁰/cm³ to about 2×10²¹/cm³.

4. The method of claim 1, further comprising:
forming a second semiconductor fin on the substrate, the first semiconductor fin being adjacent to the first semiconductor fin;
forming a second source/drain region in the second semiconductor fin, wherein the source/drain region and the second source/drain region are merged; and
depositing the capping layer on the second source/drain region.

5. The method of claim 1, further comprising depositing a dielectric layer over the capping layer, wherein during the depositing of the dielectric layer, the capping layer is oxidized.

6. The method of claim 1, wherein depositing the capping layer comprises depositing the capping layer at a process temperature in a range from 500° C. to 700° C. and at a process pressure in a range from 20 torr to 60 torr.

7. A method comprising:
depositing a capping layer on a source/drain region, wherein a first thickness of the capping layer on a first sidewall of the source/drain region is larger than a second thickness of the capping layer on a second sidewall of the source/drain region, wherein the first sidewall is above the second sidewall;
depositing a contact etch stop layer (CESL) on the source/drain region;
forming an inter-layer dielectric (ILD) on the CESL;
forming a contact opening through the ILD, the CESL, and the capping layer, wherein the contact opening exposes the source/drain region; and
forming a source/drain contact in the contact opening.

8. The method of claim 7, further comprising:
forming a metal layer on the exposed source/drain region; and
annealing the metal layer to form a silicide layer.

9. The method of claim 7, wherein the first sidewall of the source/drain region is above outermost points of the capping layer, and the second sidewall of the source/drain region is below the outermost points of the capping layer.

10. The method of claim 9, wherein the first thickness of the capping layer is in a range from 0.5 nm to 2 nm, and the second thickness of the capping layer is up to 2 nm.

11. The method of claim 7, wherein depositing of the capping layer comprises using borane, diborane, or boron trichloride as process reactants.

12. The method of claim 7, wherein a first boron concentration of the capping layer is in a range from 3×10²¹/cm³ to 1×10²²/cm³, and a second boron concentration of the source/drain region is in a range from 1×10²⁰/cm³ to about 2×10²¹/cm³.

13. The method of claim 7, wherein after forming the source/drain contact, a first height of the source/drain region from a first point on a bottom surface of the source/drain region to a second point on a top surface of the source/drain region is larger than 40 nm, the second point being vertically above the first point.

14. The method of claim 7, wherein forming the contact opening through the ILD, the CESL, and the capping layer comprises a fluorine based plasma etch process.

15. A device comprising:
a gate structure on a channel region of a substrate;
a source/drain region adjoining the channel region;
a capping layer on a first portion of the source/drain region, wherein a first boron concentration of the capping layer is higher than a second boron concentration of the source/drain region;
a silicide on a second portion of the source/drain region; and
a source/drain contact electrically connected to the source/drain region through the silicide.

16. The device of claim 15, wherein a first portion of the capping layer has a first thickness that is larger than a second thickness of a second portion of the capping layer, wherein the first portion of the capping layer is higher than the second portion of the capping layer.

17. The device of claim 16, wherein the first portion of capping layer is higher than the widest portion of the source/drain region.

18. The device of claim 15, where the silicide is further disposed on a top surface of the capping layer.

19. The device of claim 18 further comprising an inter-layer dielectric (ILD) over the capping layer, wherein the ILD comprises silicon oxide, and the capping layer comprises boron oxide.

20. The device of claim 15, wherein a first height of a first sidewall of the source/drain region between a bottommost point of the capping layer and a bottommost surface of the source/drain region is larger than 10 nm.
